(19) United States
(12) Patent Application Publication
(10) Pub. No.: US 2025/0031415 A1
(43) Pub. Date: Jan. 23, 2025

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Hitoshi KUNITAKE, Machida, Tokyo (JP); Ryota HODO, Atsugi-shi, Kanagawa (JP); Tatsuya ONUKI, Atsugi-shi, Kanagawa (JP)

(21) Appl. No.: 18/715,890

(22) PCT Filed: Nov. 25, 2022
(86) PCT No.: PCT/IB2022/061407

§ 371 Date: Jun. 3, 2024

(30) Foreign Application Priority Data
Dec. 10, 2021 (JP) 2021-201198

(51) Int. Cl. H01L 29/786; H01L 27/02; H01L 29/423; H01L 29/49

(52) U.S. Cl. CPC H01L 29/78693; H01L 27/0207; H01L 29/42376; H01L 29/4908

(57) ABSTRACT

A semiconductor device that can be miniaturized or highly integrated is provided. The semiconductor device includes a first transistor including a first oxide, a second transistor including a second oxide, and a third oxide. The first oxide includes a channel formation region of the first transistor. The second oxide includes a channel formation region of the second transistor. The third oxide contains the same material as the first oxide and the second oxide. The third oxide is separated from the first oxide and the second oxide. In a top view, the third oxide is positioned between the first oxide and the second oxide. The third oxide is placed in the same layer as the first oxide and the second oxide.

### TECHNICAL FIELD

One embodiment of the present invention relates to a transistor, a semiconductor device, a display device, and an electronic appliance. Another embodiment of the present invention relates to a method for manufacturing a semiconductor device and a method for manufacturing a display device. Another embodiment of the present invention relates to a semiconductor wafer and a module.

In this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic appliance, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, semiconductor devices have been developed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique in which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor including an oxide semiconductor has an extremely low leakage current in a non-conduction state. For example, Patent Document 1 discloses a low-power-consumption CPU utilizing a feature of a low leakage current of the transistor including an oxide semiconductor. Furthermore, for example, Patent Document 2 discloses a storage device that can retain stored contents for a long time by utilizing a feature of a low leakage current of the transistor including an oxide semiconductor.

In recent years, demand for an integrated circuit with higher density has risen with reductions in size and weight of electronic appliances. Therefore, a technique for miniaturizing transistors has been required. Non-Patent Document 1 and Non-Patent Document 2 each disclose a transistor without p/n junction (Junctionless-FET) including silicon in its channel and having a channel length of 3 nm. Non-Patent Document 3 discloses a transistor including an oxide semiconductor in its channel and having a gate length of 12 nm or less.

### REFERENCES

### Patent Documents

[Patent Document 1] Japanese Published Patent Application No. 2012-257187
[Patent Document 2] Japanese Published Patent Application No. 2011-151383

### Non-Patent Documents

[Non-Patent Document 1] S. Migita, et al, “Electrical Performances of Junctionless-FETs at the Scaling Limit (L_{CH}=3 nm)”, IEDM Tech. Dig., pp. 191-194, 2012.
[Non-Patent Document 2] S. Migita, et al, “Experimental Demonstration of Ultrashort-Channel (3 nm) Junctionless FETs Utilizing Atomically Sharp V-Grooves on SOI”, IEEE Trans. Nanotechnol., 13, pp. 208-215, 2014.
[Non-Patent Document 3] S. Subhechha, et al, “First demonstration of sub-12 nm L_{g} gate last IGZO-TFTs with oxygen tunnel architecture for front gate devices”, Symposium on VLSI Technology Digest of Technical Papers, T10-5, 2021.

### SUMMARY OF THE INVENTION

### Problems to be Solved by the Invention

An object of one embodiment of the present invention is to provide a semiconductor device that can be miniaturized or highly integrated. Another object is to provide a semiconductor device having favorable electrical characteristics. Another object is to provide a semiconductor device with a small variation in electrical characteristics of transistors. Another object is to provide a semiconductor device having favorable reliability. Another object is to provide a semiconductor device with a high on-state current. Another object is to provide a semiconductor device with low power consumption.

Note that the description of these objects does not preclude the presence of other objects. In one embodiment of the present invention, there is no need to achieve all these objects. Other objects will be apparent from the description of the specification, the drawings, the claims, and the like, and can be derived from the description of the specification, the drawings, the claims, and the like.

### Means for Solving the Problems

One embodiment of the present invention is a semiconductor device including a first transistor including a first oxide, a second transistor including a second oxide, and a third oxide. The first oxide includes a channel formation region of the first transistor. The second oxide includes a channel formation region of the second transistor. The third oxide contains the same material as the first oxide and the second oxide. The third oxide is separated from the first oxide and the second oxide. In a top view, the third oxide is positioned between the first oxide and the second oxide. The third oxide is placed in the same layer as the first oxide and the second oxide.

In the above semiconductor device, a gate electrode of the first transistor preferably includes a region with a width greater than or equal to 1 nm and less than or equal to 20 nm in a cross-sectional view of the first transistor in a channel length direction, and a gate electrode of the second transistor preferably includes a region with a width greater than or equal to 1 nm and less than or equal to 20 nm in a cross-sectional view of the second transistor in a channel length direction.

In the above semiconductor device, the third oxide preferably does not have a function of a channel formation region of a transistor.

One embodiment of the present invention is a semiconductor device including a circuit. The circuit includes a transistor and a first region including the transistor. The transistor includes a first oxide in a channel formation region. A second oxide is provided in the first region. The second oxide contains the same material as the first oxide. The second oxide is separated from the first oxide. The first region is shaped into a square in a top view so as to include at least the channel formation region of the transistor. An area of the first region and an area occupied by one transistor converted from a transistor density of the circuit are equal to each other. The first region overlaps with at least part of the first oxide and the second oxide in the top view.

In the above semiconductor device, a gate electrode of the transistor preferably includes a region with a width greater than or equal to 1 nm and less than or equal to 20 nm in a cross-sectional view of the transistor in a channel length direction.

In the above semiconductor device, the second oxide preferably does not have a function of a channel formation region of a transistor.

One embodiment of the present invention is a semiconductor device including a circuit. The circuit includes a transistor and a first region including the transistor. The transistor includes a first conductor functioning as a gate electrode and an oxide including a channel formation region. A second conductor not overlapping with the oxide is provided in the first region. The second conductor contains the same material as the first conductor. The second conductor is separated from the first conductor. The first region is shaped into a square in a top view so as to include at least the channel formation region of the transistor. An area of the first region and an area occupied by one transistor converted from a transistor density of the circuit are equal to each other. The first region overlaps with at least part of the first conductor and the second conductor in the top view.

In the above semiconductor device, the first conductor preferably includes a region with a width greater than or equal to 1 nm and less than or equal to 20 nm in a cross-sectional view of the transistor in a channel length direction.

In the above semiconductor device, the transistor density of the circuit is preferably higher than or equal to 1 Tr/μm² and lower than or equal to 1000 Tr/μm².

### Effect of the Invention

According to one embodiment of the present invention, a semiconductor device that can be miniaturized or highly integrated can be provided. Alternatively, a semiconductor device having favorable reliability can be provided. Alternatively, a semiconductor device with a small variation in electrical characteristics can be provided. Alternatively, a semiconductor device having favorable electrical characteristics can be provided. Alternatively, a semiconductor device with a high on-state current can be provided. Alternatively, a semiconductor device with low power consumption can be provided.

Note that the description of these effects does not preclude the presence of other effects. One embodiment of the present invention does not have to have all these effects. Other effects will be apparent from the description of the specification, the drawings, the claims, and the like, and can be derived from the description of the specification, the drawings, the claims, and the like.

### BRIEF DESCRIPTION OF THE DRAWINGS

FIG. 1A, FIG. 1D, and FIG. 1E are top views of a semiconductor device of one embodiment of the present invention. FIG. 1B and FIG. 1C are cross-sectional views of the semiconductor device of one embodiment of the present invention.

FIG. 2A is a top view of a semiconductor device of one embodiment of the present invention.

FIG. 2B is a cross-sectional view of the semiconductor device of one embodiment of the present invention.

FIG. 3A is a top view of a semiconductor device of one embodiment of the present invention.

FIG. 3B and FIG. 3C are cross-sectional views of the semiconductor device of one embodiment of the present invention.

FIG. 4A to FIG. 4D are top views of a semiconductor device of one embodiment of the present invention.

FIG. 5A, FIG. 5C, and FIG. 5E are top views of a semiconductor device of one embodiment of the present invention. FIG. 5B, FIG. 5D, and FIG. 5F are cross-sectional views of the semiconductor device of one embodiment of the present invention.

FIG. 6A is a top view of a semiconductor device of one embodiment of the present invention.

FIG. 6B to FIG. 6D are cross-sectional views of the semiconductor device of one embodiment of the present invention.

FIG. 7 is a diagram showing calculation results of Id-Vg characteristics of transistors.

FIG. 8 is a cross-sectional view of a semiconductor device of one embodiment of the present invention.

FIG. 9A to FIG. 9E are cross-sectional views of a semiconductor device of one embodiment of the present invention.

FIG. 10A to FIG. 10D are schematic diagrams of aluminum concentration profiles in a metal oxide.

FIG. 11 is a graph showing stress of a variety of films.

FIG. 12A and FIG. 12B are cross-sectional views of a semiconductor device of one embodiment of the present invention.

FIG. 13A and FIG. 13B are cross-sectional views of a semiconductor device of one embodiment of the present invention.

FIG. 14A is a cross-sectional TEM image of an oxide semiconductor of one embodiment of the present invention, and FIG. 14B is a plan-view TEM image of the oxide semiconductor of one embodiment of the present invention.

FIG. 15A is a plan-view TEM image of an oxide semiconductor of one embodiment of the present invention, and FIG. 15B is a mapping image of the oxide semiconductor of one embodiment of the present invention.

FIG. 16A to FIG. 16H are enlarged views relating to an oxide semiconductor of one embodiment of the present invention.

FIG. 17A to FIG. 17C are plan-view TEM images of oxide semiconductors of one embodiment of the present invention.

FIG. 18A to FIG. 18C are mapping images of oxide semiconductors of one embodiment of the present invention.

FIG. 19A to FIG. 19C are mapping images of oxide semiconductors of one embodiment of the present invention.

FIG. 20A to FIG. 20C are Voronoi polygon distribution histograms of oxide semiconductors of one embodiment of the present invention.

FIG. 21A is a top view illustrating a method for manufacturing a semiconductor device of one embodiment of the present invention. FIG. 21B to FIG. 21D are cross-sectional views illustrating the method for manufacturing a semiconductor device of one embodiment of the present invention.

FIG. 22A is a top view illustrating a method for manufacturing a semiconductor device of one embodiment of the present invention. FIG. 22B to FIG. 22D are cross-sectional views illustrating the method for manufacturing a semiconductor device of one embodiment of the present invention.

FIG. 23A is a top view illustrating a method for manufacturing a semiconductor device of one embodiment of the present invention. FIG. 23B to FIG. 23D are cross-sectional views illustrating the method for manufacturing a semiconductor device of one embodiment of the present invention.

FIG. 24A is a top view illustrating a method for manufacturing a semiconductor device of one embodiment of the present invention. FIG. 24B to FIG. 24D are cross-sectional views illustrating the method for manufacturing a semiconductor device of one embodiment of the present invention.

FIG. 25A is a top view illustrating a method for manufacturing a semiconductor device of one embodiment of the present invention. FIG. 25B to FIG. 25D are cross-sectional views illustrating the method for manufacturing a semiconductor device of one embodiment of the present invention.

FIG. 26A is a top view illustrating a method for manufacturing a semiconductor device of one embodiment of the present invention. FIG. 26B to FIG. 26D are cross-sectional views illustrating the method for manufacturing a semiconductor device of one embodiment of the present invention.

FIG. 27A is a top view illustrating a method for manufacturing a semiconductor device of one embodiment of the present invention. FIG. 27B to FIG. 27D are cross-sectional views illustrating the method for manufacturing a semiconductor device of one embodiment of the present invention.

FIG. 28A is a top view illustrating a method for manufacturing a semiconductor device of one embodiment of the present invention. FIG. 28B to FIG. 28D are cross-sectional views illustrating the method for manufacturing a semiconductor device of one embodiment of the present invention.

FIG. 29A is a top view illustrating a method for manufacturing a semiconductor device of one embodiment of the present invention. FIG. 29B to FIG. 29D are cross-sectional views illustrating the method for manufacturing a semiconductor device of one embodiment of the present invention.

FIG. 30A is a top view illustrating a method for manufacturing a semiconductor device of one embodiment of the present invention. FIG. 30B to FIG. 30D are cross-sectional views illustrating the method for manufacturing a semiconductor device of one embodiment of the present invention.

FIG. 31A is a top view illustrating a method for manufacturing a semiconductor device of one embodiment of the present invention. FIG. 31B to FIG. 31D are cross-sectional views illustrating the method for manufacturing a semiconductor device of one embodiment of the present invention.

FIG. 32 is a top view illustrating a microwave treatment apparatus of one embodiment of the present invention.

FIG. 33 is a schematic cross-sectional view illustrating a microwave treatment apparatus of one embodiment of the present invention.

FIG. 34 is a schematic cross-sectional view illustrating a microwave treatment apparatus of one embodiment of the present invention.

FIG. 35 is a schematic view illustrating a microwave treatment apparatus of one embodiment of the present invention.

FIG. 36A is a top view of a semiconductor device of one embodiment of the present invention.

FIG. 36B to FIG. 36D are cross-sectional views of the semiconductor device of one embodiment of the present invention.

FIG. 37A is a top view of a semiconductor device of one embodiment of the present invention.

FIG. 37B to FIG. 37D are cross-sectional views of the semiconductor device of one embodiment of the present invention.

FIG. 38A is a top view of a semiconductor device of one embodiment of the present invention.

FIG. 38B to FIG. 38D are cross-sectional views of the semiconductor device of one embodiment of the present invention.

FIG. 39A is a top view of a semiconductor device of one embodiment of the present invention.

FIG. 39B to FIG. 39D are cross-sectional views of the semiconductor device of one embodiment of the present invention.

FIG. 40A is a plan view of a semiconductor device of one embodiment of the present invention.

FIG. 40B and FIG. 40C are cross-sectional views of the semiconductor device of one embodiment of the present invention.

FIG. 41 is a cross-sectional view illustrating a structure of a storage device of one embodiment of the present invention.

FIG. 42 is a cross-sectional view illustrating a structure of a storage device of one embodiment of the present invention.

FIG. 43 is a cross-sectional view of a semiconductor device of one embodiment of the present invention.

FIG. 44A and FIG. 44B are cross-sectional views of semiconductor devices of one embodiment of the present invention.

FIG. 45 is a cross-sectional view of a semiconductor device of one embodiment of the present invention.

FIG. 46A is a block diagram illustrating a structure example of a storage device of one embodiment of the present invention. FIG. 46B is a perspective view illustrating a structure example of the storage device of one embodiment of the present invention.

FIG. 47A to FIG. 47H are circuit diagrams each illustrating a structure example of a storage device of one embodiment of the present invention.

FIG. 48A and FIG. 48B are schematic views of a semiconductor device of one embodiment of the present invention.

FIG. 49A and FIG. 49B are diagrams illustrating examples of electronic components.

FIG. 50A to FIG. 50E are schematic views of storage devices of one embodiment of the present invention.

FIG. 51A to FIG. 51H are diagrams illustrating electronic appliances of one embodiment of the present invention.

FIG. 52 is a diagram illustrating an example of a device for space.

FIG. 53A and FIG. 53B show Id-Vg characteristics of transistors.

FIG. 54A and FIG. 54B are cross-sectional STEM images of a fabricated sample.

FIG. 55 is a diagram showing normal probability plots of Vth.

FIG. 56A and FIG. 56B show Id-Vg characteristics of transistors.

FIG. 57A to FIG. 57D are plan-view SEM images of samples fabricated as prototypes.

FIG. 58 is a diagram illustrating the relationship between a process node and a transistor density.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be interpreted as being limited to the description of the embodiments below.

In addition, in the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is used for portions having similar functions, and the portions are not especially denoted by reference numerals in some cases.

Furthermore, especially in a top view (also referred to as a “plan view”), a perspective view; or the like, the description of some components might be omitted for easy understanding of the invention. The description of some hidden lines might also be omitted.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components is changed as appropriate in accordance with the direction in which the components are described. Thus, without limitation to terms described in this specification, the description can be changed appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Here, X and Y each denote an object (e.g., a device, an element, a circuit, a wiring, an electrode, a terminal, a conductive film, or a layer).

In this specification and the like, a transistor is an element having at least three terminals including a gate, a drain, and a source. In addition, the transistor includes a region where a channel is formed (hereinafter, also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of a current is changed in a circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where a current flows in a semiconductor when a transistor is in an on state) and a gate electrode overlap with each other, or a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, the length of a channel formation region in a direction perpendicular to a channel length direction in a region where a semiconductor (or a portion where a current flows in a semiconductor when a transistor is in an on state) and a gate electrode overlap with each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on the transistor structure, a channel width in a region where a channel is actually formed (hereinafter also referred to as an “effective channel width”) is different from a channel width shown in a top view of a transistor (hereinafter also referred to as an “apparent channel width”) in some cases. For example, in a transistor whose gate electrode covers the side surface of a semiconductor, the effective channel width is larger than the apparent channel width, and its influence cannot be ignored in some cases. For example, in a miniaturized transistor whose gate electrode covers the side surface of a semiconductor, the proportion of a channel formation region formed in the side surface of the semiconductor is increased in some cases. In that case, the effective channel width is larger than the apparent channel width.

In such a case, the effective channel width is sometimes difficult to estimate by actual measurement. For example, estimation of an effective channel width from a designed value requires assumption that the shape of a semiconductor is known. Accordingly, in the case where the shape of a semiconductor is not known accurately, it is difficult to measure the effective channel width accurately.

In this specification, the simple term “channel width” refers to an apparent channel width in some cases. Alternatively, in this specification, the simple term “channel width” refers to an effective channel width in some cases. Note that values of a channel length, a channel width, an effective channel width, an apparent channel width, and the like can be determined, for example, by analyzing a cross-sectional TEM image.

In this specification, an apparent channel width is sometimes referred to as a gate width. The gate width sometimes refers to, for example, the length of the top surface of a semiconductor, the length of the bottom surface of a semiconductor, or the length of a semiconductor at a given position therein in a cross-sectional view of a transistor in the channel width direction. In the case where a semiconductor has a stacked-layer structure, the gate width sometimes refers to, for example, the length of the interface between a first layer and a second layer included in the stacked-layer structure in a cross-sectional view of a transistor in the channel width direction.

Note that impurities in a semiconductor refer to, for example, elements other than the main components of a semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as Vo) are formed in an oxide semiconductor in some cases by entry of impurities, for example.

Note that in this specification and the like, silicon oxynitride is a substance that contains more oxygen than nitrogen in its composition. Moreover, silicon nitride oxide is a substance that contains more nitrogen than oxygen in its composition.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor.

In this specification and the like, “normally off” means that a drain current per micrometer of channel width flowing through a transistor when no potential is applied to a gate or the gate is supplied with a ground potential is 1×10⁻²⁰ A or lower at room temperature, 1×10⁻¹⁸ A or lower at 85° C., or 1×10⁻¹⁶ A or lower at 125° C.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, when a plurality of components are denoted with the same reference numerals, and in particular need to be distinguished from each other, an identification sign such as “_1”, “[n]”, or “[m,n]” is sometimes added to the reference numerals.

In this specification, in the case where the maximum value and the minimum value are specified, a structure in which the maximum value and the minimum value are freely combined is also disclosed.

Note that in this specification and the like, the expression “level or substantially level” indicates a structure having the same level from a reference surface (e.g., a flat surface such as a substrate surface) in a cross-sectional view. For example, in a manufacturing process of the semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as being “level or substantially level” in this specification and the like. For example, the expression “level or substantially level” includes the case where two layers (here, given as a first layer and a second layer) having different two levels with respect to the reference surface are included, and the difference between the top-surface level of the first layer and the top-surface level of the second layer is less than or equal to 20 nm.

Note that in this specification and the like, the expression “end portions are aligned or substantially aligned” means that at least outlines of stacked layers partly overlap with each other in a top view. For example, the case of processing the upper layer and the lower layer with the use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned or substantially aligned”.

### Embodiment 1

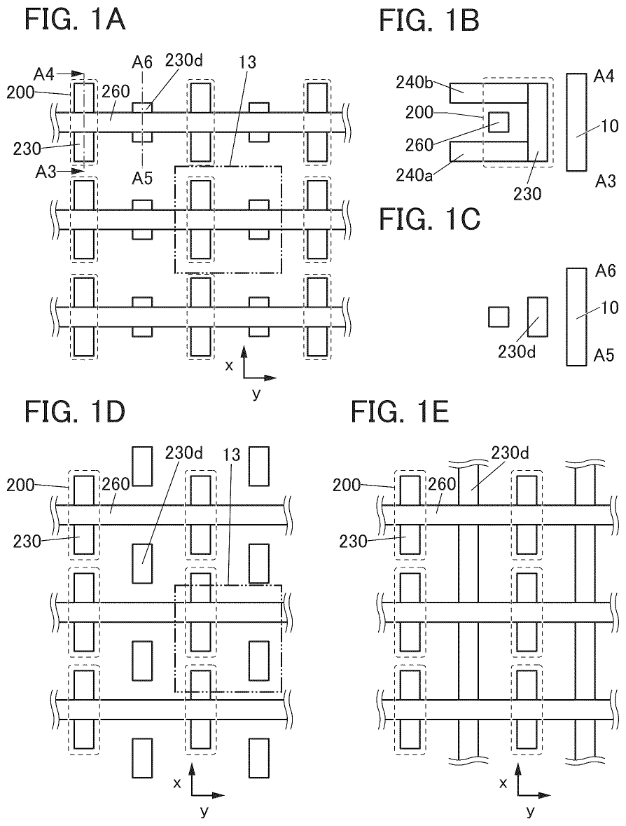

In this embodiment, an example of a semiconductor device of one embodiment of the present invention will be described with reference to FIG. 1A to FIG. 5F. The semiconductor device of one embodiment of the present invention includes a transistor. The transistor includes an oxide semiconductor including a channel formation region.

A metal oxide containing indium is preferably used as the oxide semiconductor. It is possible to use, for example, a metal oxide such as an In-M-Zn oxide (an element M is one or more kinds selected from aluminum, gallium, yttrium, tin, boron, silicon, vanadium, beryllium, copper, titanium, iron, nickel, germanium, zirconium, molybdenum, lanthanum, cerium, neodymium, hafnium, tantalum, tungsten, magnesium, cobalt, and the like). Alternatively, an In—Ga oxide or an In—Zn oxide may be used as the oxide semiconductor. Note that a metal oxide that can be used as the oxide semiconductor will be described in detail in Embodiment 2.

For example, a transistor including an oxide semiconductor in a channel formation region has an extremely low off-state current in a non-conduction state; thus, a semiconductor device with low power consumption can be provided. Note that the off-state current refers to a current that flows between a source and a drain when the transistor is in a non-conduction state.

An oxide semiconductor can be deposited by a sputtering method or the like; thus, by using an oxide semiconductor in a channel formation region, transistors can be stacked and three-dimensionally integrated. In other words, a three-dimensional integrated circuit (a 3D integrated circuit) in which a circuit is developed not only on a flat surface of a substrate but also in a perpendicular direction can be obtained.

Note that the electrical characteristics of a transistor including an oxide semiconductor are sometimes changed due to an oxygen vacancy, an impurity (typically, hydrogen, water, or the like), or the like in the oxide semiconductor. For example, a transistor including a larger amount of oxygen vacancies, impurities, or the like in an oxide semiconductor is likely to have normally-on characteristics (characteristics in which a channel exists without voltage application to a gate electrode and current flows in a transistor). Therefore, a transistor preferably includes an oxide semiconductor including a small amount of oxygen vacancies or impurities.

A plurality of circuits having different functions in a semiconductor device may be placed over the same substrate in some cases. Here, the density of elements or wirings required for forming the circuit varies depending on a required circuit structure. Specifically, there arises a difference in density of arrangement of elements and wirings (hereinafter also referred to as a layout in a circuit region) between a circuit region having regular arrangement and high integration, which is typified by a memory cell or a pixel region, and a circuit region whose layout is determined as needed, such as a driver circuit or a correction circuit.

Each structure of the transistor can be formed by repeating deposition of a film using a material suitable for the structure and processing and shaping of the film.

The film is deposited by, for example, a sputtering method, a chemical vapor deposition (CVD) method, a molecular beam epitaxy (MBE) method, a pulsed laser deposition (PLD) method, an atomic layer deposition (ALD) method, or the like.

CVD methods can be classified into a plasma CVD (PECVD: Plasma Enhanced CVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas to be used.

By a plasma CVD method, a high-quality film can be obtained at a relatively low temperature. However, a wiring, an electrode, an element (a transistor, a capacitor, or the like), or the like included in the semiconductor device might cause an electrification phenomenon (charging) when receiving charges from plasma generated during deposition (being in a charging state is also referred to as being charged up). In this case, accumulated charges might break the wiring, the electrode, the element, or the like included in the semiconductor device.

Examples of a method for processing and shaping the film include dry etching, wet etching, and chemical mechanical polishing (CMP) treatment. To perform minute processing because of a reduction in device size, dry etching using plasma is generally used. However, charge up might be caused by plasma also in dry etching.

For example, in a process of forming a wiring, each of wirings obtained by cutting a wiring is likely to be in an electrically floating state. Each of the wirings after the cutting is charged up also in a later process, which causes electrostatic breakdown (ESD: Electro-Static Discharge) of an element. In particular, there is a high probability that a gate insulator is broken when different potentials are charged in electrodes of the transistor.

In particular, in a three-dimensional integrated circuit (a 3D integrated circuit) in which a circuit is developed also in a perpendicular direction, the number of steps of depositing films and processing and shaping the films is increased as the degree of integration in the perpendicular direction is increased. That is, the probability that electrostatic breakdown due to charge up is caused tends to be increased in proportion to the number of steps of depositing films and processing and shaping the films.

Meanwhile, in the above deposition step and the above processing step, it is preferable to distribute plasma uniformly over the substrate in order to inhibit a variation. However, in the case where uniform plasma charge is induced over the substrate while there is a difference in density between layouts, there is a problem in that the amount of plasma charge differs between one of elements in a region with an element layout with high-density arrangement and one of elements in a region with an element layout with low-density arrangement, for example.

Furthermore, charge up caused in the middle of the etching step may cause abnormality in the shape of the element, a microloading phenomenon, or the like. For example, as the pattern width is narrower, there is a higher probability that the vicinity of a surface of the mask is charged up. When the vicinity of the surface of the mask is charged up, the rate of the ions reaching the vicinity of the surface of the mask is changed in accordance with a charged potential, and thus the etching rate varies in the plane, resulting in abnormality in the shape.

In the transistor including the oxide semiconductor, oxygen in the oxide semiconductor may be absorbed by a conductor forming the transistor or a conductor used for a plug or a wiring connected to the transistor, and thus oxygen vacancies are formed in the oxide semiconductor in some cases. For example, in the case where heat treatment is performed in fabricating the transistor, oxygen in the oxide semiconductor may be absorbed by a conductor forming the transistor due to the heat treatment.

Oxygen vacancies may be formed in the oxide semiconductor by process damage when the transistor is manufactured. In a heating process when the transistor is manufactured, for example, oxygen in the oxide semiconductor may be absorbed by a conductor forming the transistor or a conductor used for a plug or a wiring connected to the transistor, and thus oxygen vacancies are generated in the oxide semiconductor in some cases.

To reduce oxygen vacancies, an oxide containing oxygen to be released by heating (hereinafter, sometimes referred to as excess oxygen) is preferably provided in the vicinity of the oxide semiconductor included in the transistor. Accordingly, oxygen is supplied to the oxide semiconductor; thus, the amount of oxygen vacancies in the oxide semiconductor can be reduced. However, when there is a difference in density between layouts in circuit regions, the amount of supplied oxygen varies in the substrate plane, leading to a variation in characteristics of the semiconductor device including the transistor.

In view of the above, a component of at least one of an oxide semiconductor, a conductor, and an insulator is provided in the vicinity of the transistor included in the semiconductor device in one embodiment of the present invention. Note that the oxide semiconductor contains the same material as the above oxide semiconductor included in the transistor, and is provided in the same layer as the above oxide semiconductor included in the transistor. The conductor contains the same material as the above conductor included in the transistor, and is provided in the same layer as the above conductor included in the transistor. The insulator contains the same material as the above insulator included in the transistor, and is provided in the same layer as the above insulator included in the transistor. With such a structure, the pattern density (also referred to as the average density) of at least one of oxide semiconductors, conductors, and insulators can be uniform.

Note that in this specification, the pattern density is the area ratio of a component formed in a given region. In the case where a conductive film is deposited on an entire surface in a given region, for example, the pattern density is 100%. On the other hand, in the case where part of the conductive film is removed to form a plurality of conductors, the pattern density of the conductors can be obtained by dividing the area of the remaining conductors by the area of the given region.

In one embodiment of the present invention, when a circuit region with a sparse layout and a circuit region with a dense layout are included, a dummy element (hereinafter, also referred to as a sacrificial element) is provided in the sparse circuit region so that the density of elements or wirings is equal to that in the dense circuit region. With such a structure, a difference in density between the layouts in the circuit regions can be reduced. Here, the dummy element refers to an element that does not influence a circuit.

The density of the layout in the circuit region is made low such that a difference in the amount of excess oxygen diffused into one element placed in each region is less likely to be generated, or the pattern densities in the circuit regions are made equal. With this structure, the amount of oxygen supplied to the element included in each of the plurality of regions can be controlled.

The density of the layout in the circuit region is made low such that processing abnormality or electrostatic breakdown is less likely to be caused, or the pattern densities in the circuit regions are made equal, whereby plasma damage to the element can be reduced, and electrostatic breakdown and abnormality in the shape can be suppressed. Note that in this specification, the description “one value is equal to another value” does not necessarily mean that they are exactly equal to each other. In the range of common technical knowledge, they can be substantially the same, equivalent, or approximate.

For example, as for one component, even in the case where the average pattern density over an entire substrate is 40%, the pattern density may be 70% in one region of the substrate, and the pattern density may be 10% in the other region of the substrate. Accordingly, the region with a pattern density of 10% is a sparse region, and thus a dummy element is preferably formed such that the pattern density is approximately 70%. In other words, in the case where a dummy element is not placed, the average pattern density over the entire substrate is dₐᵥₑ %, the pattern density in a region whose pattern density is higher than dₐᵥₑ % is d_{high} %, and the pattern density in a region whose pattern density is lower than dₐᵥₑ % is d_{low} %. It is preferable that a dummy element be provided in the region whose pattern density is d_{low} % and thus the pattern density be higher than or equal to dₐᵥₑ %, preferably d_{high} %.

The above dummy element is formed in the same step as an element having a circuit function. Thus, the dummy element is provided in the same layer as the element having a circuit function. At least one of components forming the dummy element is formed using the same material as a component forming the element having a circuit function.

Note that the dummy element may have the same components as the element having a circuit function. The dummy element includes at least one same component as the element having a circuit function. Accordingly, the number of components forming the dummy element may be smaller than the number of components forming the element having a circuit function. That is, an element forming a circuit may include a conductor, an insulator, a semiconductor, or the like in addition to the components forming the dummy element.

As the element having a circuit function, a capacitor, an inductance element, a resistor (a switching element such as a transistor, a light-emitting element, a memory element, or the like), or the like can be used.

### Structure Example 1 of Semiconductor Device

Hereinafter, an example of a semiconductor device of one embodiment of the present invention will be described with reference to FIG. 1A to FIG. 3C.

FIG. 1A is a top view of a semiconductor device including a transistor 200. The x direction illustrated in FIG. 1A is parallel to the channel length direction of the transistor 200, and the y direction is perpendicular to the x direction. FIG. 1B and FIG. 1C are cross-sectional views of the semiconductor device. FIG. 1B is a cross-sectional view of a portion indicated by dashed-dotted line A3-A4 in FIG. 1A. FIG. 1C is a cross-sectional view of a portion indicated by dashed-dotted line A5-A6 in FIG. 1A. Note that for clarity of the drawing, some components are omitted in FIG. 1A.

The semiconductor device illustrated in FIG. 1A includes a plurality of transistors 200 arranged in a matrix. Note that FIG. 1A is a top view of a region including one transistor 200 among the plurality of transistors 200 arranged in a matrix and the transistors 200 arranged around the one transistor.

As illustrated in FIG. 1B, the transistor 200 is provided over a substrate 10. The transistor 200 includes at least a conductor 260 functioning as a gate electrode and an oxide 230 including a channel formation region. Although not illustrated in FIG. 1B, an insulator functioning as a gate insulator is provided between the conductor 260 and the oxide 230. Note that the transistor 200 may include conductors functioning as a source electrode and a drain electrode, a conductor functioning as a back gate electrode, an insulator functioning as a back gate insulator, and the like. Note that the structure, manufacturing method, and the like of the transistor 200 will be described in detail in Embodiment 2.

As illustrated in FIG. 1A, the conductor 260 is provided to extend in the y direction. Thus, the conductor 260 is shared by the plurality of transistors 200 arranged in the y direction. The conductor 260 can also function as a wiring. Note that the conductor 260 may be provided for each of the transistors 200. A structure in which a conductor functioning as a wiring is provided over the conductor 260 may be employed.

As illustrated in FIG. 1B, the transistor 200 is electrically connected to a conductor 240a and a conductor 240b functioning as plugs. The conductor 240a and the conductor 240b are electrically connected to a wiring included in a circuit, whereby the transistor 200 functions as a transistor included in the circuit.

Although not illustrated in FIG. 1A, an oxide containing excess oxygen is placed in the semiconductor device. Accordingly, oxygen can be supplied to the oxide 230 included in the transistor 200. Note that the oxide corresponds to an insulator 224, an insulator 250, an insulator 280, or the like described in Embodiment 2.

The semiconductor device illustrated in FIG. 1A includes an oxide 230d between the transistors 200 close to each other in the y direction. That is, it can be said that the semiconductor device includes the oxide 230d between a first transistor and a second transistor close to the first transistor in the y direction. The semiconductor device includes the first transistor, the second transistor, and the oxide 230d, and it can be said that the first transistor, the oxide 230d, and the second transistor are arranged in this order in the y direction. The semiconductor device includes a first oxide included in the first transistor, a second oxide included in the second transistor close to the first transistor in the y direction, and the oxide 230d, and it can be said that the oxide 230d is positioned between the first oxide and the second oxide.

The oxide 230d is formed in the same step as the oxide 230 included in the transistor 200. Thus, the oxide 230d contains the same material as the oxide 230. Here, it can be said that the oxide 230d contains a constituent element of the oxide 230. For example, in the case where an In-M-Zn oxide is used as the oxide 230, the oxide 230d is an In-M-Zn oxide. The oxide 230d is placed in the same layer as the oxide 230. For example, the oxide 230d is in contact with a first layer in contact with the oxide 230. Note that the case where the oxide 230 is adjacent to the first layer with a second layer therebetween also includes the case where the oxide 230d is adjacent to the first layer with a third layer, which is formed in the same step as the second layer, therebetween. Alternatively, for example, the bottom surface of the oxide 230d is level with or substantially level with the bottom surface of the oxide 230.

Note that the oxide 230 and the oxide 230d are each formed into an island shape. Note that in this specification and the like, the term “island shape” refers to a state where two or more layers formed using the same material in the same step are physically separated from each other. That is, the oxide 230d is separated from the oxide 230.

The oxide 230d is not electrically connected to a wiring included in the circuit. Thus, the oxide 230d does not have a function of the channel formation region of the transistor.

With the above structure, the arrangement or the pattern density of the oxide semiconductors that are the oxide 230 and the oxide 230d can be more uniform. Accordingly, the amount of oxygen supplied from the oxide containing excess oxygen that is placed in the vicinity of the transistor 200 to the oxide 230 can be more uniform. Thus, the transistor 200 having transistor characteristics with a small variation and favorable reliability can be provided. Moreover, by forming the oxide 230 and the oxide 230d in the same step, shape abnormality due to processing can be inhibited.

Note that the distance from the first oxide included in the first transistor to the oxide 230d is preferably equal to the distance from the second oxide included in the second transistor close to the first transistor in the y direction to the oxide 230d. With such a structure, the arrangement or the pattern density of the oxide semiconductors that are the oxide 230 and the oxide 230d can be more uniform.

FIG. 1A illustrates a structure in which the area of the oxide 230d in the top view is smaller than the area of the oxide 230 in the top view. To achieve high integration of the semiconductor device, the area of the oxide 230d in the top view is preferably smaller than the area of the oxide 230 in the top view. Note that the present invention is not limited thereto. As long as high integration of the semiconductor device is possible, the area of the oxide 230d in the top view may be equal to the area of the oxide 230 in the top view, or may be larger than the area of the oxide 230 in the top view.

The semiconductor device of one embodiment of the present invention includes the circuit. In the circuit, one or more transistors are arranged. Here, the number of transistors arranged per unit area is defined as a transistor density. In this specification and the like, the transistor density is the number of transistors per square micrometer, and is represented by number/μm², Tr/μm², or μm⁻². The transistor density of the circuit included in the semiconductor device of one embodiment of the present invention is higher than or equal to 1 Tr/μm² and lower than or equal to 3000 Tr/μm², lower than or equal to 2000 Tr/μm², or lower than or equal to 1000 Tr/μm².

Note that all the transistors counted when the transistor density of the circuit is calculated do not necessarily function as transistors included in the circuit. Examples of the transistors counted when the transistor density of the circuit is calculated may include a transistor that is placed in the circuit region but does not function as a transistor included in the circuit and a dummy element having a structure equivalent to that of a transistor functioning as a transistor included in the circuit. Thus, the transistor density is represented by a number/μm² rule, a Tr/μm² rule, or a μm⁻² rule in some cases.

The area occupied by one transistor can be calculated by converting the transistor density. Specifically, the area occupied by one transistor is an inverse of the transistor density.

Here, a region illustrated in FIG. 1A and surrounded by a dashed double-dotted line is referred to as a region 13. The circuit includes the transistor 200 and the region 13 including the transistor 200.

The region 13 is shaped into a square in the top view so as to include at least the channel formation region of the transistor 200. Note that the shape of the region 13 in the top view may be a tetragonal shape, a circular shape, or the like. The area of the region 13 is equal to the area occupied by one transistor, which is converted from the transistor density. In other words, one side of the region 13 is equal to the square root of the area occupied by one transistor, which is converted from the transistor density.

In the top view of the semiconductor device, the oxide 230d is preferably placed inside the region 13 with at least part of the oxide 230. Here, the region 13 overlaps with at least part of the oxide 230 and the oxide 230d. Specifically, in the top view of the semiconductor device, the oxide 230d is preferably placed inside the region 13 with the channel formation region in the oxide 230 or a region of the oxide 230 overlapping with the conductor 260. Here, the region 13 overlaps with the oxide 230d and the channel formation region in the oxide 230 or the region of the oxide 230 overlapping with the conductor 260. With such a structure, the arrangement or the pattern density of the oxide semiconductors that are the oxide 230 and the oxide 230d can be more uniform.

Although FIG. 1A exemplifies a structure in which the oxide 230d is provided between the first transistor and the second transistor close to the first transistor in the y direction, the present invention is not limited thereto. The oxide 230d may be provided between the first transistor and a third transistor close to the first transistor in the x direction.

As described above, as long as the oxide 230d does not have a function of the channel formation region of the transistor, the position of the oxide 230d is not particularly limited. The oxide 230d may be placed to include a region overlapping with the conductor 260 as illustrated in FIG. 1A, or may be placed in a region not overlapping with the conductor 260 as illustrated in FIG. 1D.

As long as the oxide 230d does not have a function of the channel formation region of the transistor, the top surface shape of the oxide 230d is not particularly limited. The top surface shape of the oxide 230d may be a rectangular shape as illustrated in FIG. 1A; a polygonal shape such as a triangular shape, a tetragonal shape (including a rectangular shape and a square shape), or a pentagonal shape; the polygonal shape with rounded corners; an elliptical shape; a circular shape; a shape in which a plurality of polygonal shapes are combined; or the like. In addition, a plurality of oxides 230d may be arranged in the x direction as illustrated in FIG. 1A, or the oxide 230d may be provided to extend in the x direction as a continuous layer as illustrated in FIG. 1E.

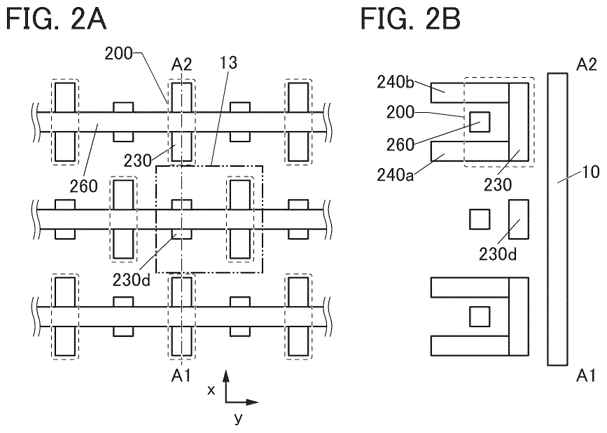

Although the plurality of transistors 200 are arranged in a matrix in the semiconductor device illustrated in FIG. 1A, the arrangement of the plurality of transistors 200 is designed as appropriate in accordance with a required circuit. For example, as illustrated in FIG. 2A, the plurality of transistors 200 are arranged in a zigzag manner in some cases.

FIG. 2A is a top view of a semiconductor device including the transistor 200. The x direction illustrated in FIG. 2A is parallel to the channel length direction of the transistor 200, and the y direction is perpendicular to the x direction. FIG. 2B is a cross-sectional view of the semiconductor device, and is a cross-sectional view of a portion indicated by dashed-dotted line A1-A2 in FIG. 2A. Note that for clarity of the drawing, some components are omitted in FIG. 2A.

The semiconductor device illustrated in FIG. 2A is different from the semiconductor device illustrated in FIG. 1A in the arrangement of the transistors 200 and the arrangement of the oxides 230d. Differences from the semiconductor device illustrated in FIG. 1A will be mainly described below, and common portions are not described in some cases.

The semiconductor device illustrated in FIG. 2A includes the oxide 230d between the transistors 200 close to each other in the x direction and between the transistors 200 close to each other in the y direction. With such a structure, the arrangement or the pattern density of the oxide semiconductors that are the oxide 230 and the oxide 230d can be more uniform.

Although FIG. 1A and FIG. 2A each illustrate a structure in which the oxide 230d is provided in a region provided with the circuit included in the semiconductor device, the present invention is not limited thereto. For example, a component that is formed in the same step as at least some components included in the transistor 200 and is not included in the transistor 200 may be provided in a region provided with the circuit included in the semiconductor device.

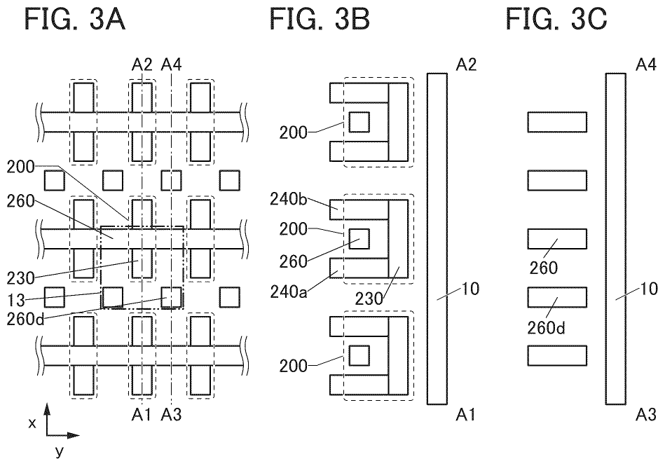

FIG. 3A is a top view of a semiconductor device. FIG. 3B and FIG. 3C are cross-sectional views of the semiconductor device. FIG. 3B is a cross-sectional view of a portion indicated by dashed-dotted line A1-A2 in FIG. 3A. FIG. 3C is a cross-sectional view of a portion indicated by dashed-dotted line A3-A4 in FIG. 3A. Note that for clarity of the drawing, some components are omitted in FIG. 3A.

The semiconductor device illustrated in FIG. 3A is different from the semiconductor device illustrated in FIG. 1A in not including the oxide 230d but including a conductor 260d. Differences from the semiconductor device illustrated in FIG. 1A will be mainly described below, and common portions are not described in some cases.

The semiconductor device illustrated in FIG. 3A includes the conductor 260d between the conductors 260 close to each other in the x direction. That is, it can be said that the semiconductor device includes the conductor 260d between a first conductor and a second conductor close to the first conductor in the x direction. Here, the conductor 260d is provided in a region provided with a circuit included in the semiconductor device.

The conductor 260d is formed in the same step as the conductor 260 included in the transistor 200. Thus, the conductor 260d contains the same material as the conductor 260. Here, it can be said that the conductor 260d contains a constituent element of the conductor 260. The conductor 260d is placed in the same layer as the conductor 260. For example, the conductor 260d is in contact with a first layer in contact with the conductor 260. Note that the case where the conductor 260 is adjacent to the first layer with a second layer therebetween also includes the case where the conductor 260d is adjacent to the first layer with a third layer, which is formed in the same step as the second layer, therebetween. Alternatively, for example, the bottom surface of the conductor 260d is level with or substantially level with the bottom surface of the conductor 260. The conductor 260d is separated from the conductor 260.

The conductor 260d is preferably in a floating state. Alternatively, it is preferable that the conductor 260d not overlap with the oxide 230. In that case, the conductor 260d does not have a function of the gate electrode of the transistor.

With the above structure, the arrangement or the pattern density of the conductors that are the conductor 260 and the conductor 260d can be more uniform. Thus, by providing the conductor 260d in the same step as the formation of the conductor 260, charge up of the conductor 260 can be inhibited. Accordingly, electrostatic breakdown of an insulator placed between the conductor 260 and the oxide 230 can be inhibited. Furthermore, variations in the shape and characteristics of an element can be inhibited.

Furthermore, owing to heat treatment in the manufacturing process of the transistor, impurities (typically, hydrogen, water, or the like) in the oxide semiconductor may be absorbed by the conductor 260d. That is, the conductor 260d captures impurities, thereby inhibiting diffusion of impurities into the transistor 200. Therefore, the reliability of the transistor 200 can be improved.

Note that the distance from the first conductor included in the first transistor to the conductor 260d is preferably equal to the distance from the second conductor included in the second transistor close to the first transistor in the x direction to the conductor 260d. With such a structure, the arrangement or the pattern density of the conductors that are the conductor 260 and the conductor 260d can be more uniform.

In the top view of the semiconductor device, the conductor 260d is preferably placed inside the region 13 with at least part of the conductor 260. Here, the region 13 overlaps with at least part of the conductor 260 and the conductor 260d. Specifically, in the top view of the semiconductor device, the conductor 260d is preferably placed inside the region 13 with a region of the conductor 260 functioning as a gate electrode or a region of the conductor 260 overlapping with the oxide 230. Here, the region 13 overlaps with the region of the conductor 260 functioning as a gate electrode or the region of the conductor 260 overlapping with the oxide 230, and the conductor 260d. With such a structure, the arrangement or the pattern density of the conductors that are the conductor 260 and the conductor 260d can be more uniform.

As long as the conductor 260d does not have a function of the gate electrode of the transistor, the top surface shape of the conductor 260d is not particularly limited. The top surface shape of the conductor 260d may be a square shape as illustrated in FIG. 3A; a polygonal shape such as a triangular shape, a tetragonal shape (including a rectangular shape and a square shape), or a pentagonal shape; the polygonal shape with rounded corners; an elliptical shape; a circular shape; a shape in which a plurality of polygonal shapes are combined; or the like. In addition, a plurality of conductors 260d may be arranged in the y direction as illustrated in FIG. 3A, or the conductor 260d may be provided to extend in the y direction as a continuous layer.

Thus, a variation in electrical characteristics of the transistor can be inhibited. In addition, a transistor having high reliability can be provided. Moreover, abnormality in shape of the transistor and electrostatic breakdown can be inhibited. Accordingly, the yield is improved, and thus the productivity of the semiconductor device can be increased.

### Structure Example 2 of Semiconductor Device

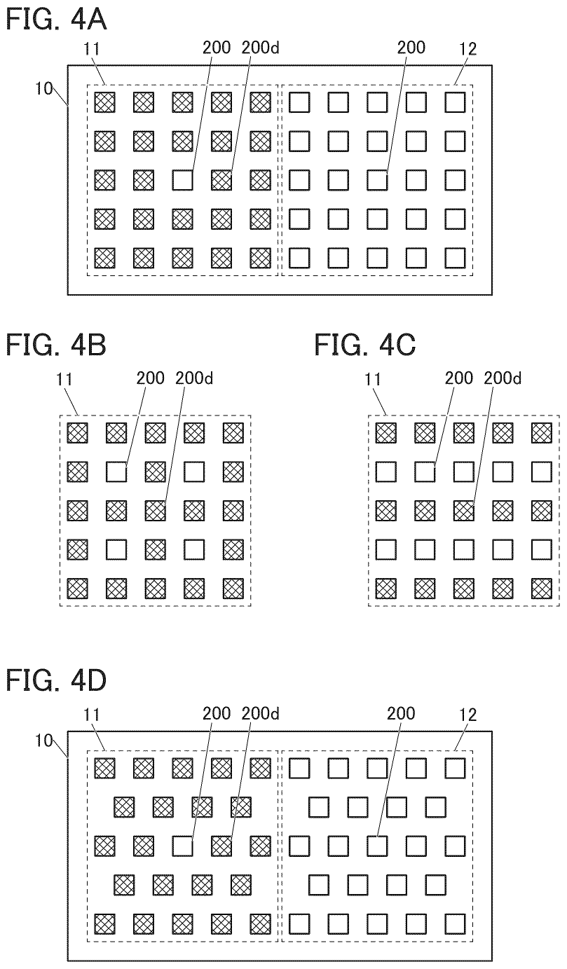

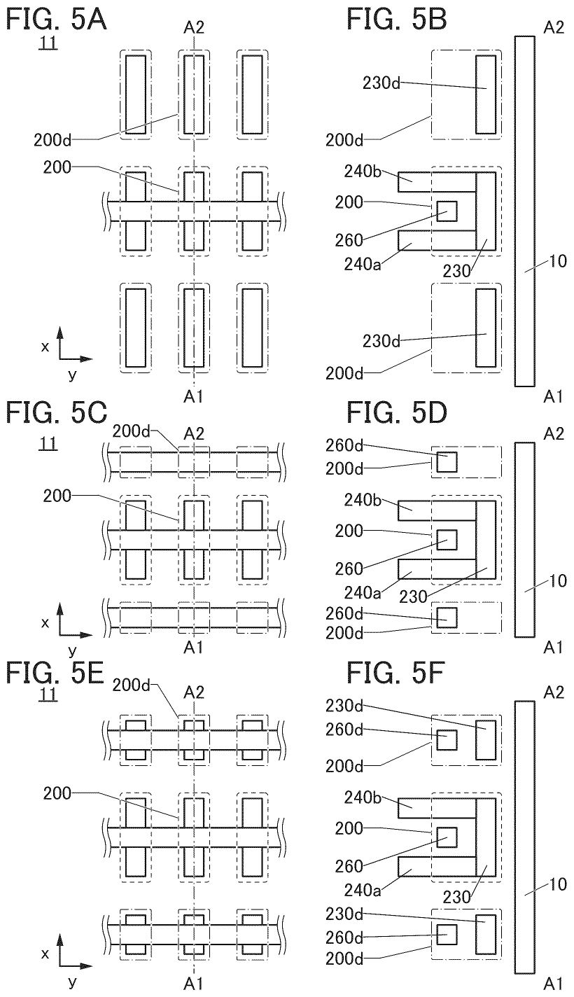

Hereinafter, another example of a semiconductor device of one embodiment of the present invention will be described with reference to FIG. 4A to FIG. 5F.

FIG. 4A to FIG. 4D are each a top view of a semiconductor device. Note that for clarity of the drawing, some components are omitted in FIG. 4A to FIG. 4D.

As illustrated in FIG. 4A, the semiconductor device includes a region 11 and a region 12 over the substrate 10. The region 11 includes the transistor 200 arranged with low density and a plurality of dummy elements 200d. Note that a plurality of components illustrated as the dummy elements 200d are hatched for easy understanding. Meanwhile, the region 12 includes a plurality of transistors 200 arranged with high density. The plurality of dummy elements 200d are arranged in the region 11, whereby the pattern density in the region 11 can be equivalent (hereinafter also referred to as an approximate value) to the pattern density in the region 12.

Although not illustrated in FIG. 4A, an oxide that contains excess oxygen is provided across the region 11 and the region 12. Therefore, the amount of oxygen supplied to one transistor 200 can be equivalent for the transistor 200 arranged in the region 11 and the plurality of transistors 200 arranged in the region 12. Accordingly, a variation in transistor characteristics is inhibited in the region 11 and the region 12, and the transistor 200 with high reliability can be provided. Note that the oxide corresponds to the insulator 224, the insulator 250, the insulator 280, or the like described in Embodiment 2.

Furthermore, by arrangement of the dummy elements 200d, impurities (typically, hydrogen, water, or the like) in an oxide semiconductor may be absorbed by a conductor included in the dummy element 200d owing to heat treatment in the process of manufacturing the transistor. In other words, the impurities are trapped by the dummy element 200d, whereby the impurities can be inhibited from being diffused into the transistor 200. Thus, the transistor 200 can have improved reliability.

In the case where a film is processed by a dry etching method to form components included in the plurality of transistors 200 and components included in the plurality of dummy elements 200d, the amount of plasma charge per transistor 200 is equivalent in the region 11 and the region 12. That is, the plasma charge is induced not only for the transistor 200 but also for the dummy element 200d in the region 11, and thus the amount of plasma charge per transistor 200 is reduced. Thus, plasma damage to the transistor 200 in the region 11 can be reduced, and electrostatic breakdown can be inhibited.

Furthermore, a microloading phenomenon can be inhibited. Thus, variations in the shape and characteristics of an element can be inhibited.

Note that the dummy elements 200d are preferably arranged in the region 11 so that the arrangement of the transistor 200 and the dummy elements 200d in the region 11 is equivalent to the arrangement of the plurality of transistors 200 in the region 12. For example, also in the structure in which the plurality of transistors 200 are arranged in a matrix in the region 11 as illustrated in FIG. 4B, the dummy elements 200d are preferably arranged in the region 11 so that the arrangement in the region 11 is equivalent to the arrangement of the plurality of transistors 200 in the region 12. For example, also in the structure in which the arrangement of the transistors 200 in a first direction in the region 11 is the same as that in the region 12 as illustrated in FIG. 4C, the dummy elements 200d are preferably arranged in the region 11 so that the arrangement in the region 11 is equivalent to the arrangement of the plurality of transistors 200 in the region 12.

Although FIG. 4A exemplifies the structure in which the plurality of transistors 200 are arranged in a matrix in the region 12, the layout in the circuit region is not limited thereto and is designed as appropriate in accordance with a required circuit. For example, as illustrated in FIG. 4D, the plurality of transistors 200 are arranged in a zigzag manner in some cases. Here, the dummy element 200d is preferably provided so that the transistor 200 and the dummy elements 200d are arranged in a zigzag manner also in the region 11.

Next, structure examples of a semiconductor device including the region 11 illustrated in FIG. 4C are described with reference to FIG. 5A to FIG. 5F.

FIG. 5A is a top view of a semiconductor device including the transistor 200. The semiconductor device illustrated in FIG. 5A includes the region 11 where elements are arranged with low density and the region 12 where elements are arranged with high density. Note that FIG. 5A illustrates part of the region 11 illustrated in FIG. 4C and does not illustrate the region 12 illustrated in FIG. 4A. The region 11 includes a dummy element as well as the transistor 200 functioning as a transistor and thus has an element pattern density equivalent to the region 12. In FIG. 5A, the x direction is parallel to the channel length direction of the transistor 200, and the y direction is perpendicular to the x direction. Note that for clarity of the drawing, some components are omitted in FIG. 5A.

Note that FIG. 5A is a top view of a region in the region 11, which includes one transistor 200 among a plurality of transistors 200 arranged in a matrix and the transistors 200 and the dummy elements 200d that are arranged around the one transistor 200. FIG. 5B is a cross-sectional view of the semiconductor device, and is a cross-sectional view of a portion indicated by dashed-dotted line A1-A2 in FIG. 5A.

Note that the transistor 200 illustrated in FIG. 5A and FIG. 5B has the same structure as the transistor 200 illustrated in FIG. 1B. Thus, the description of <Structure example 1 of semiconductor device> can be referred to for the transistor 200 illustrated in FIG. 5A and FIG. 5B.

The transistor 200 is electrically connected to the conductor 240a and the conductor 240b functioning as plugs. The conductor 240a and the conductor 240b are electrically connected to a wiring included in a circuit, whereby the transistor 200 functions as a transistor included in the circuit.

The dummy element 200d illustrated in FIG. 5A and FIG. 5B includes the oxide 230d. The oxide 230d is formed in the same step as the oxide 230 included in the transistor 200. Thus, the oxide 230d contains the same material as the oxide 230. The oxide 230d is placed in the same layer as the oxide 230.

With the above structure, the arrangement or the pattern density of the oxide semiconductors that are the oxide 230 and the oxide 230d can be more uniform. Accordingly, the amount of oxygen supplied from the oxide containing excess oxygen that is placed in the vicinity of the transistor 200 to the oxide 230 can be more uniform. Moreover, by forming the oxide 230 and the oxide 230d in the same step, shape abnormality due to processing can be inhibited.

Note that the oxide 230d illustrated in FIG. 5A and FIG. 5B has the same structure as the oxide 230d illustrated in FIG. 1C. Thus, the description of <Structure example 1 of semiconductor device> can be referred to for the oxide 230d illustrated in FIG. 5A and FIG. 5B.

Although FIG. 5A and FIG. 5B illustrate a structure in which the dummy element 200d includes the oxide 230d, the present invention is not limited thereto. The dummy element 200d preferably includes at least some or all of the components included in the transistor 200.

FIG. 5C to FIG. 5F illustrate structure examples of a semiconductor device including a dummy element different from the dummy element 200d illustrated in FIG. 5A and FIG. 5B.

FIG. 5C is a top view of a semiconductor device. FIG. 5D is a cross-sectional view of the semiconductor device, and is a cross-sectional view of a portion indicated by dashed-dotted line A1-A2 in FIG. 5C. Note that for clarity of the drawing, some components are omitted in FIG. 5C.

Note that since the transistor 200 illustrated in FIG. 5C and FIG. 5D is the same as the transistor 200 illustrated in FIG. 5A and FIG. 5B, the above description can be referred to.

The dummy element 200d illustrated in FIG. 5C and FIG. 5D includes the conductor 260d. Note that the conductor 260d is formed in the same step as the conductor 260 included in the transistor 200. Thus, the conductor 260d contains the same material as the conductor 260. The conductor 260d is placed in the same layer as the conductor 260.

With the above structure, the arrangement or the pattern density of the conductors that are the conductor 260 and the conductor 260d can be more uniform. By providing the conductor 260d in the same step as the formation of the conductor 260, charge up of the conductor 260 can be inhibited. Accordingly, electrostatic breakdown of an insulator placed between the conductor 260 and the oxide 230 can be prevented.

Note that the conductor 260d illustrated in FIG. 5C and FIG. 5D has the same structure as the conductor 260d illustrated in FIG. 3A and FIG. 3C. Thus, the description of <Structure example 1 of semiconductor device> can be referred to for the conductor 260d illustrated in FIG. 5C and FIG. 5D.

FIG. 5E is a top view of a semiconductor device. FIG. 5F is a cross-sectional view of the semiconductor device, and is a cross-sectional view of a portion indicated by dashed-dotted line A1-A2 in FIG. 5E. Note that for clarity of the drawing, some components are omitted in FIG. 5E.

Note that since the transistor 200 illustrated in FIG. 5E and FIG. 5F is the same as the transistor 200 illustrated in FIG. 5A and FIG. 5B, the above description can be referred to.

The dummy element 200d illustrated in FIG. 5E and FIG. 5F includes the oxide 230d and the conductor 260d. Note that the oxide 230d is formed in the same step as the oxide 230 included in the transistor 200. Thus, the oxide 230d contains the same material as the oxide 230. The oxide 230d is placed in the same layer as the oxide 230. The conductor 260d is formed in the same step as the conductor 260 included in the transistor 200. Thus, the conductor 260d contains the same material as the conductor 260. The conductor 260d is placed in the same layer as the conductor 260.

With the above structure, the arrangement or the pattern density of the oxide semiconductors that are the oxide 230 and the oxide 230d and the arrangement or the pattern density of the conductors that are the conductor 260 and the conductor 260d can be more uniform. Accordingly, the amount of oxygen supplied from the oxide containing excess oxygen that is placed in the vicinity of the transistor 200 to the oxide 230 can be more uniform. Moreover, by forming the oxide 230 and the oxide 230d in the same step, shape abnormality due to processing can be inhibited. By providing the conductor 260d in the same step as the formation of the conductor 260, charge up of the conductor 260 can be inhibited. Accordingly, electrostatic breakdown of an insulator placed between the conductor 260 and the oxide 230 can be prevented.

Note that in FIG. 5A, the transistor 200 is adjacent to another transistor 200 in the y direction, and is adjacent to the dummy element 200d in the x direction. The arrangement of the transistors 200 and the dummy elements 200d is not limited thereto. At least one of the elements adjacent to the transistor 200 is the dummy element 200d.

Thus, a variation in electrical characteristics of the transistor can be inhibited. In addition, a transistor having high reliability can be provided. Moreover, abnormality in shape of the transistor and electrostatic breakdown can be inhibited. Accordingly, the yield is improved, and thus the productivity of the semiconductor device can be increased.

Note that this embodiment may be implemented by combining the structure of the semiconductor device described in <Structure example 1 of semiconductor device> and the structure of the semiconductor device described in <Structure example 2 of semiconductor device>. Specifically, the semiconductor device may include the dummy element 200d and at least one of the oxide 230d and the conductor 260d.

This embodiment may be implemented in combination with a structure of a semiconductor device described in Embodiment 2. When the transistor 200 described in Embodiment 2 is used as the transistor 200 included in the semiconductor device of this embodiment, miniaturization and high integration of the semiconductor device can be achieved. For example, in a cross-sectional view in the channel length direction, the gate electrode of the transistor 200 can include a region with a width greater than or equal to 1 nm and less than or equal to 20 nm.

In addition to the above, the distance size (pitch) between the oxides 230 is less than or equal to 120 nm, less than or equal to 90 nm, or less than or equal to 75 nm. The distance size (pitch) between the conductors 260 is less than or equal to 180 nm, less than or equal to 120 nm, or less than or equal to 105 nm. With such a structure, the transistor density of the semiconductor device can be higher than or equal to 1 Tr/μm², higher than or equal to 10 Tr/μm², or higher than or equal to 100 Tr/μm².

At least part of the structure, method, and the like described in this embodiment can be implemented in appropriate combination with any of those in the other embodiments, the other examples, and the like described in this specification.

### Embodiment 2

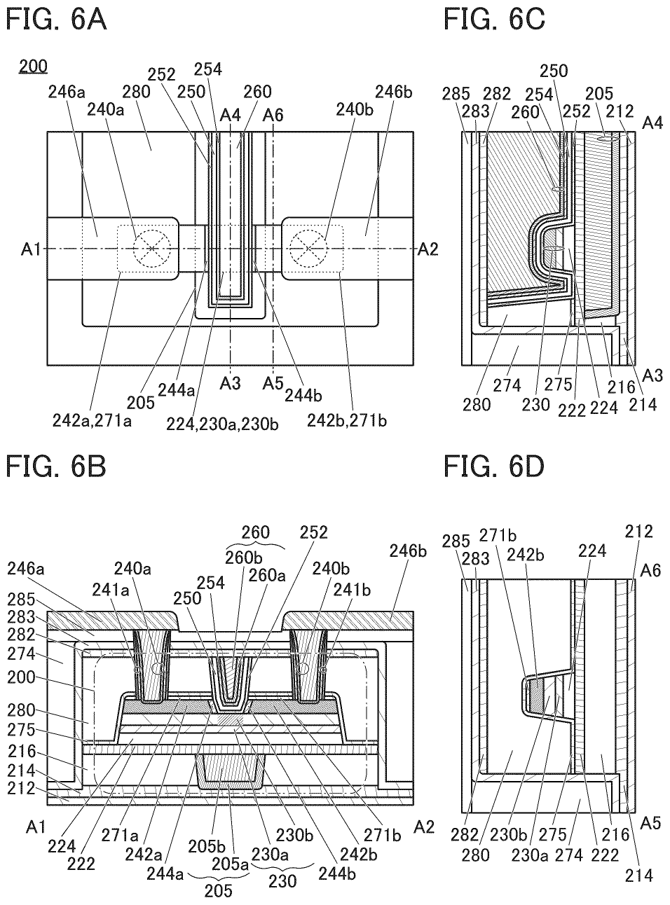

In this embodiment, an example of a semiconductor device of one embodiment of the present invention and a manufacturing method thereof will be described with reference to FIG. 6A to FIG. 40C. The semiconductor device of one embodiment of the present invention includes a transistor.

### Structure Example of Semiconductor Device

A structure of a semiconductor device including the transistor 200 is described with reference to FIG. 6A to FIG. 6D. FIG. 6A to FIG. 6D are a top view and cross-sectional views of the semiconductor device including the transistor 200. FIG. 6A is a top view of the semiconductor device. FIG. 6B to FIG. 6D are cross-sectional views of the semiconductor device. Here, FIG. 6B is a cross-sectional view of a portion indicated by dashed-dotted line A1-A2 in FIG. 6A, and is a cross-sectional view of the transistor 200 in the channel length direction. FIG. 6C is a cross-sectional view of a portion indicated by dashed-dotted line A3-A4 in FIG. 6A, and is a cross-sectional view of the transistor 200 in the channel width direction. FIG. 6D is a cross-sectional view of a portion indicated by dashed-dotted line A5-A6 in FIG. 6A. Note that for clarity of the drawing, some components are omitted in the top view in FIG. 6A.

The semiconductor device of one embodiment of the present invention includes an insulator 212 over a substrate (not illustrated), an insulator 214 over the insulator 212, the transistor 200 over the insulator 214, the insulator 280 over the transistor 200, an insulator 282 over the insulator 280, an insulator 283 over the insulator 282, an insulator 274 over the insulator 283, and an insulator 285 over the insulator 283 and the insulator 274. The insulator 212, the insulator 214, the insulator 280, the insulator 282, the insulator 283, the insulator 274, and the insulator 285 function as interlayer films. The conductor 240a and the conductor 240b that are electrically connected to the transistor 200 and function as plugs are also included. An insulator 241a is provided in contact with the side surface of the conductor 240a, and an insulator 241b is provided in contact with the side surface of the conductor 240b. A conductor 246a that is electrically connected to the conductor 240a is provided over the insulator 285 and the conductor 240a, and a conductor 246b that is electrically connected to the conductor 240b is provided over the insulator 285 and the conductor 240b. The insulator 283 is in contact with part of the top surface of the insulator 214, the side surface of the insulator 280, and the side surface and the top surface of the insulator 282.

The insulator 241a is provided in contact with an inner wall of an opening in the insulator 280, the insulator 282, the insulator 283, and the insulator 285, and the conductor 240a is provided in contact with the side surface of the insulator 241a. The insulator 241b is provided in contact with an inner wall of an opening in the insulator 280, the insulator 282, the insulator 283, and the insulator 285, and the conductor 240b is provided in contact with the side surface of the insulator 241b. Each of the insulator 241a and the insulator 241b has a structure in which a first insulator is provided in contact with the inner wall of the opening and a second insulator is provided on the inner side of the first insulator. The conductor 240a has a structure in which a first conductor is provided in contact with the side surface of the insulator 241a and a second conductor is provided on the inner side of the first conductor. The conductor 240b has a structure in which a first conductor is provided in contact with the side surface of the insulator 241b and a second conductor is provided on the inner side of the first conductor. Here, the top surface of the conductor 240a can be substantially level with the top surface of the insulator 285 in a region overlapping with the conductor 246a. Moreover, the top surface of the conductor 240b can be substantially level with the top surface of the insulator 285 in a region overlapping with the conductor 246b.

Although each of the insulator 241a and the insulator 241b has a structure in which the first insulator and the second insulator are stacked in the transistor 200, the present invention is not limited thereto. For example, each of the insulator 241a and the insulator 241b may have a single-layer structure or a stacked-layer structure of three or more layers. Although each of the conductor 240a and the conductor 240b has a structure in which the first conductor and the second conductor are stacked in the transistor 200, the present invention is not limited thereto. For example, each of the conductor 240a and the conductor 240b may have a single-layer structure or a stacked-layer structure of three or more layers. In the case where a component has a stacked-layer structure, layers may be distinguished by ordinal numbers given corresponding to the formation order.

### [Transistor 200]

As illustrated in FIG. 6A to FIG. 6D, the transistor 200 includes an insulator 216 over the insulator 214, a conductor 205 (a conductor 205a and a conductor 205b) placed to be embedded in the insulator 216, an insulator 222 over the insulator 216 and the conductor 205, the insulator 224 over the insulator 222, an oxide 230a over the insulator 224, an oxide 230b over the oxide 230a, a conductor 242a and a conductor 242b over the oxide 230b, an insulator 271a over the conductor 242a, an insulator 271b over the conductor 242b, an insulator 252 positioned over the oxide 230b and between the conductor 242a and the conductor 242b, the insulator 250 over the insulator 252, an insulator 254 over the insulator 250, the conductor 260 (a conductor 260a and a conductor 260b) positioned over the insulator 254 and overlapping with part of the oxide 230b, and an insulator 275 placed over the insulator 222, the insulator 224, the oxide 230a, the oxide 230b, the conductor 242a, the conductor 242b, the insulator 271a, and the insulator 271b. The transistor 200 includes an insulator 244a positioned between the conductor 242a and the insulator 252 and an insulator 244b positioned between the conductor 242b and the insulator 252.

Hereinafter, the oxide 230a and the oxide 230b are collectively referred to as the oxide 230 in some cases. The conductor 242a and the conductor 242b are collectively referred to as the conductor 242 in some cases. The insulator 271a and the insulator 271b are collectively referred to as the insulator 271 in some cases.

The insulator 280 is positioned over the insulator 275. Thus, it can be said that the insulator 280 is positioned above the conductor 242a and the conductor 242b. An opening reaching the oxide 230b is provided in the insulator 280 and the insulator 275. That is, it can be said that the opening includes a region that is between the conductor 242a and the conductor 242b and overlaps with the oxide 230b. It can be said that the insulator 275 includes an opening overlapping with an opening included in the insulator 280. The insulator 252, the insulator 250, the insulator 254, and the conductor 260 are placed in the opening. That is, the conductor 260 includes a region overlapping with the oxide 230b with the insulator 252, the insulator 250, and the insulator 254 therebetween. The conductor 260, the insulator 252, the insulator 250, and the insulator 254 are provided between the insulator 271a and the conductor 242a, and the insulator 271b and the conductor 242b in the channel length direction of the transistor 200. The insulator 254 includes a region in contact with the side surface of the conductor 260 and a region in contact with the bottom surface of the conductor 260.

The conductor 260 functions as a first gate (also referred to as a top gate) electrode, and the conductor 205 functions as a second gate (also referred to as a back gate) electrode. The insulator 252, the insulator 250, and the insulator 254 function as a first gate insulator, and the insulator 222 and the insulator 224 function as a second gate insulator. Note that the gate insulator is also referred to as a gate insulating layer or a gate insulating film in some cases. The conductor 242a functions as one of a source electrode and a drain electrode, and the conductor 242b functions as the other of the source electrode and the drain electrode. At least part of a region of the oxide 230 overlapping with the conductor 260 functions as a channel formation region.

To miniaturize or highly integrate transistors, a thinner gate insulator is needed. However, as the gate insulator becomes thinner, a problem such as increases in parasitic capacitance between the source electrode and the gate electrode and parasitic capacitance between the drain electrode and the gate electrode or increases in leakage current between the source electrode and the gate electrode and leakage current between the drain electrode and the gate electrode may arise.

Thus, in this embodiment, the insulator 244a is provided between the conductor 242a functioning as one of the source electrode and the drain electrode and the conductor 260 functioning as the top gate electrode, and the insulator 244b is provided between the conductor 242b functioning as the other of the source electrode and the drain electrode and the conductor 260. Since the insulator 244a and the insulator 244b are provided, a distance between the conductor 242a and the conductor 260 and a distance between the conductor 242b and the conductor 260 can be increased, so that parasitic capacitance between the conductor 242a and the conductor 260 and parasitic capacitance between the conductor 242b and the conductor 260 can be reduced. Thus, the switching speed of the transistor 200 can be improved, and the transistor can have high frequency characteristics.

In the transistor 200, a metal oxide functioning as a semiconductor (such a metal oxide is hereinafter also referred to as an oxide semiconductor) is preferably used as the oxide 230 including the channel formation region.

The metal oxide functioning as a semiconductor preferably has a band gap of 2 eV or higher, further preferably 2.5 eV or higher. With use of a metal oxide having a wide bandgap, the off-state current of the transistor can be reduced.

The channel formation region in the oxide 230 is preferably an i-type or substantially i-type region with reduced carrier concentration, and a source region and a drain region are preferably n-type regions with high carrier concentrations. With such a structure, a semiconductor device having favorable electrical characteristics can be provided. Note that at least part of the channel formation region in the oxide 230 overlaps with the conductor 260. In other words, the channel formation region is provided in a region between the conductor 242a and the conductor 242b. One of the source region and the drain region is provided to overlap with the conductor 242a, and the other of the source region and the drain region is provided to overlap with the conductor 242b.

If impurities and oxygen vacancies exist in a channel formation region in an oxide semiconductor, a transistor including the oxide semiconductor may have variable electrical characteristics and poor reliability. In some cases, a defect that is the oxygen vacancy into which hydrogen enters (hereinafter sometimes referred to as V_{O}H) is formed, which generates an electron serving as a carrier. When V_{O}H is formed in the channel formation region, the donor concentration in the channel formation region is increased in some cases. As the donor concentration in the channel formation region increases, the threshold voltage might vary. Therefore, when the channel formation region in the oxide semiconductor includes oxygen vacancies, the transistor tends to have normally-on characteristics. Thus, impurities, oxygen vacancies, and V_{O}H are preferably reduced as much as possible in the channel formation region in the oxide semiconductor.

As a countermeasure to the above, an insulator containing excess oxygen is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor. Furthermore, a variation of the amount of oxygen supplied to the source region or the drain region in the substrate plane leads to a variation in characteristics of the semiconductor device including the transistor. When oxygen supplied from the insulator to the oxide semiconductor is diffused into a conductor such as the gate electrode, the source electrode, or the drain electrode, the conductor might be oxidized and the conductivity might be impaired, for example, so that electrical characteristics and reliability of the transistor might be adversely affected.

Accordingly, oxygen vacancies and V_{O}H are preferably reduced in the channel formation region. Thus, it is preferable that oxygen be supplied to the channel formation region and an excess amount of oxygen not be supplied to the source region or the drain region. Furthermore, it is preferable to inhibit diffusion of hydrogen into the channel formation region.

### <Relationship Between Donor Concentration and Variation in Threshold Voltage>

In this section, a change in electrical characteristics of a transistor with changing donor concentration in a channel formation region of the transistor is described. In particular, the relationship between the donor concentration in the channel formation region and a variation in threshold voltage is described using the results of device simulation. Specifically, the Id-Vg characteristics of a transistor with changing donor concentration in a semiconductor layer included in the transistor were calculated with a device simulator.

The device simulation was performed with a device simulator Atlas3D developed by Silvaco Data Systems Inc. In the device simulation, a transistor structure corresponding to FIG. 6A to FIG. 6D was used.

In the device simulation, a donor concentration Nd in the channel formation region was 1×10¹⁰ cm⁻³, 1×10¹⁵ cm⁻³, 1×10¹⁶ cm⁻³, 1×10¹⁷ cm⁻³, 1×10¹⁸ cm⁻³, 5×10¹⁸ cm⁻³, or 1×10¹⁹ cm⁻³. Note that a donor concentration in a source region and a donor concentration in a drain region were each 1×10²⁰ cm⁻³.

In the device simulation, the Id-Vg characteristics were calculated while a back gate voltage was 0 V and a drain voltage Vd was 1.2 V.

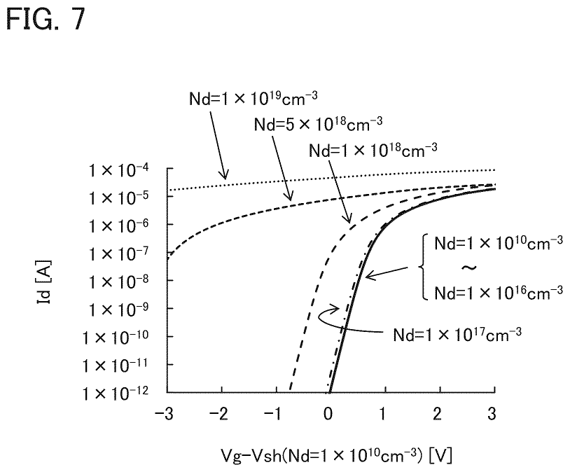

FIG. 7 shows the device simulation results. In FIG. 7, the vertical axis represents a drain current Id [A], and the horizontal axis represents a difference (Vg−Vsh (Nd=1×10¹⁰ cm⁻³)) [V] between a gate voltage Vg and the threshold voltage (Vsh) in the case where the donor concentration Nd in the channel formation region was 1×10¹⁰ cm⁻³. Here, the threshold voltage (Vsh) is defined as the gate voltage Vg when the drain current is 1 pA.

According to FIG. 7, the Id-Vg characteristics in the case where the donor concentration Nd in the channel formation region is 1×10¹⁰ cm⁻³, the Id-Vg characteristics in the case where the donor concentration Nd in the channel formation region is 1×10¹⁵ cm⁻³, and the Id-Vg characteristics in the case where the donor concentration Nd in the channel formation region is 1×10¹⁶ cm⁻³ are substantially equal to each other. In addition, the state is observed where as the donor concentration Nd in the channel formation region increases, the threshold voltage shifts in the negative direction.

The above is the description of the relationship between the donor concentration in the channel formation region and a variation in the threshold voltage.

An insulator that is likely to transmit oxygen is preferably used as the insulator 250 to supply oxygen to the channel formation region. In particular, an insulator containing excess oxygen is preferably used as the insulator 280. Such a structure enables oxygen contained in the insulator 280 to be supplied to the channel formation region in the oxide 230 through the insulator 250.

The insulator 250 can be formed using silicon oxide, silicon oxynitride, silicon oxide to which fluorine is added, silicon oxide to which carbon is added, silicon oxide to which carbon and nitrogen are added, porous silicon oxide, or the like. In particular, silicon oxide and silicon oxynitride, which are thermally stable, are preferable. The insulator 250 in this case is an insulator containing at least oxygen and silicon.

The concentration of impurities such as water and hydrogen in the insulator 250 is preferably reduced.

The thickness of the insulator 250 is preferably greater than or equal to 1 nm and less than or equal to 20 nm, further preferably greater than or equal to 0.5 nm and less than or equal to 15 nm. In particular, in order to form a minute transistor (e.g., a transistor with a gate length less than or equal to 10 nm), the thickness of the insulator 250 is preferably greater than or equal to 0.5 nm and less than or equal to 10 nm, further preferably greater than or equal to 0.5 nm and less than or equal to 5 nm. In this case, at least part of the insulator 250 preferably includes a region having the above-described thickness.

The insulator 250 is provided in contact with the top surface of the insulator 252.

An insulator containing excess oxygen is preferably used as the insulator 280. For the insulator 280, it is preferable to use an oxide containing silicon, such as silicon oxide, silicon oxynitride, silicon oxide to which fluorine is added, silicon oxide to which carbon is added, silicon oxide to which carbon and nitrogen are added, or porous silicon oxide. In particular, silicon oxide and silicon oxynitride, which are thermally stable, are preferable. A material such as silicon oxide, silicon oxynitride, or porous silicon oxide is preferable used, in which case a region containing oxygen to be released by heating can be easily formed.

The insulator 280 functions as an interlayer film and thus preferably has a low permittivity. When a material with a low permittivity is used for an interlayer film, parasitic capacitance generated between wirings can be reduced. The above-described oxide containing silicon is preferable because it is a material with a low permittivity.

The concentration of impurities such as water and hydrogen in the insulator 280 is preferably reduced.

The insulator 280 is provided over the insulator 275, and the opening is provided in a region where the insulator 252, the insulator 250, the insulator 254, and the conductor 260 are to be provided. In addition, the top surface of the insulator 280 may be planarized.

When an excess amount of oxygen is supplied to the channel formation region in the oxide 230, the source region or the drain region are excessively oxidized through the channel formation region, and the on-state current or field-effect mobility of the transistor 200 might be decreased.

Thus, the insulator 252 having a barrier property against oxygen is preferably provided between the insulator 250 and the oxide 230b. The insulator 252 is provided in contact with the bottom surface of the insulator 250, the top surface of the oxide 230b, and the side surface of the oxide 230b. Since the insulator 252 has a barrier property against oxygen, oxygen contained in the insulator 250 can be supplied to the channel formation region, while oxygen contained in the insulator 250 can be inhibited from being excessively supplied to the channel formation region. Thus, it is possible to inhibit supply of excess oxygen to the source region and the drain region through the channel formation region and decrease in the on-state current or field-effect mobility of the transistor 200. In addition, it is possible to inhibit release of oxygen from the oxide 230 when heat treatment or the like is performed and inhibit formation of oxygen vacancies in the oxide 230. Accordingly, the transistor 200 can have favorable electrical characteristics and higher reliability.

The insulator 252 is provided between the insulator 280 and the insulator 250 and includes a region in contact with the sidewall of the opening included in the insulator 280. With such a structure, oxygen contained in the insulator 280 can be supplied to the insulator 250, while oxygen contained in the insulator 280 can be inhibited from being excessively supplied to the insulator 250.

An insulator containing an oxide of one or both of aluminum and hafnium is preferably used as the insulator 252. As the insulator, aluminum oxide, hafnium oxide, an oxide containing aluminum and hafnium (hafnium aluminate), an oxide containing hafnium and silicon (hafnium silicate), or the like can be used. In this embodiment, aluminum oxide is used for the insulator 252. In this case, the insulator 252 contains at least oxygen and aluminum. Note that oxygen is less likely to pass through the insulator 252 than the insulator 250, for example. For the insulator 252, a material through which oxygen is less likely to pass than the insulator 250 is used, for example. For the insulator 252, magnesium oxide, gallium oxide, gallium zinc oxide, or indium gallium zinc oxide may be used, for example.

Note that the thickness of the insulator 252 is preferably small. It is because when the thickness of the insulator 252 is too large, the amount of oxygen supplied to the oxide 230 through the insulator 250 is reduced. Specifically, the thickness of the insulator 252 is greater than or equal to 0.1 nm and less than or equal to 5.0 nm, preferably greater than or equal to 0.5 nm and less than or equal to 3.0 nm, further preferably greater than or equal to 1.0 nm and less than 3.0 nm. In this case, at least part of the insulator 252 preferably includes a region having the above-described thickness. For example, the insulator 252 preferably includes a region having a thickness smaller than the thickness of the insulator 250. In this case, at least part of the insulator 252 preferably includes a region having a thickness smaller than that of the insulator 250.

To form the insulator 252 having a small thickness as described above, an ALD method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one has advantages such as deposition of an extremely thin film, deposition on a component with a high aspect ratio, deposition of a film with a small number of defects such as pinholes, deposition with excellent coverage, and low-temperature deposition. Therefore, the insulator 252 can be deposited on, for example, the side surface of the opening formed in the insulator 280 and the like, with a small thickness like the above-described thickness and a favorable coverage.

Note that some of precursors used in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

When the thickness of the insulator 252 is reduced, the transistor 200 can be miniaturized. This is because the insulator 252 is provided in the opening formed in the insulator 280 and the like, together with the insulator 254, the insulator 250, and the conductor 260. With the above structure, a semiconductor device that can be miniaturized or highly integrated can be provided.

The insulator 252 is provided between the insulator 250 and the conductor 242a and between the insulator 250 and the conductor 242b. When the thickness of the insulator 252 is reduced, the side surface of the conductor 242a is oxidized and the insulator 244a is formed. Similarly, the side surface of the conductor 242b is oxidized and the insulator 244b is formed. In other words, the transistor 200 includes the insulator 244a positioned between the conductor 242a and the insulator 252 and the insulator 244b positioned between the conductor 242b and the insulator 252.

Note that the lengths of the insulator 244a and the insulator 244b in the channel length direction can be controlled by adjusting the thickness of the insulator 252. For example, when the thickness of the insulator 252 is increased, the amount of oxygen contained in the insulator 250 and diffused into the conductor 242a and the conductor 242b is reduced, so that the side surfaces of the conductor 242a and the conductor 242b can be inhibited from being oxidized and the lengths of the insulator 244a and the insulator 244b in the channel length direction can be reduced. Accordingly, a decrease in the on-state current or field-effect mobility of the transistor 200 can be inhibited.

As will be described in detail later, the insulator 244a and the insulator 244b are formed in a self-aligned manner in a step of forming the conductor 242a and the conductor 242b or after forming the conductor 242a and the conductor 242b. Thus, parasitic capacitance between the conductor 242a and the conductor 260 and parasitic capacitance between the conductor 242b and the conductor 260 can be reduced in a self-aligned manner.

The insulator 244a contains an element contained in the conductor 242a and oxygen. Similarly, the insulator 244b contains an element contained in the conductor 242b and oxygen. For example, in the case where a material containing a metal element is used for each of the conductor 242a and the conductor 242b, the insulator 244a and the insulator 244b each contain the metal element and oxygen. For example, in the case where a conductive material containing a metal element and nitrogen is used for each of the conductor 242a and the conductor 242b, the insulator 244a and the insulator 244b each contain the metal element, oxygen, and nitrogen.

In order to inhibit diffusion of hydrogen into the channel formation region, an insulator having a function of inhibiting diffusion of hydrogen is preferably provided in the vicinity of the oxide 230. In the semiconductor device described in this embodiment, the insulator corresponds to, for example, the insulator 252 and the insulator 254.

Aluminum oxide that can be suitably used for the insulator 252 has a function of inhibiting diffusion of hydrogen (e.g., at least one of a hydrogen atom, a hydrogen molecule, and the like). Thus, diffusion of impurities such as hydrogen contained in the insulator 250 into the oxide 230 can be prevented. Note that hydrogen is less likely to pass through the insulator 252 than the insulator 250, for example. The insulator 252 is a material through which hydrogen is less likely to pass than the insulator 250, for example.

The insulator 254 preferably has a barrier property against hydrogen. This can prevent diffusion of impurities such as hydrogen contained in the conductor 260 into the insulator 250 and the oxide 230. For example, silicon nitride deposited by a PEALD method is used as the insulator 254. In this case, the insulator 254 contains at least nitrogen and silicon. For the insulator 254, aluminum oxide, magnesium oxide, hafnium oxide, gallium oxide, indium gallium zinc oxide, silicon nitride oxide, or the like may be used, for example. Note that hydrogen is less likely to pass through the insulator 254 than the insulator 250, for example. For the insulator 254, a material through which hydrogen is less likely to pass than the insulator 250 is used, for example.

The insulator 254 may also have a barrier property against oxygen. The insulator 254 is provided between the insulator 250 and the conductor 260. Thus, diffusion of oxygen contained in the insulator 250 into the conductor 260 can be prevented, so that oxidation of the conductor 260 can be inhibited. In addition, a reduction in the amount of oxygen supplied to the oxide 230 can be inhibited. Note that oxygen is less likely to pass through the insulator 254 than the insulator 250, for example. For the insulator 254, a material through which oxygen is less likely to pass than the insulator 250 is used, for example.

The insulator 254 needs to be provided in the opening formed in the insulator 280 and the like, together with the insulator 252, the insulator 250, and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 preferably includes a region having the above-described thickness. The thickness of the insulator 254 is preferably smaller than the thickness of the insulator 250. In this case, at least part of the insulator 254 preferably includes a region having a thickness smaller than that of the insulator 250.

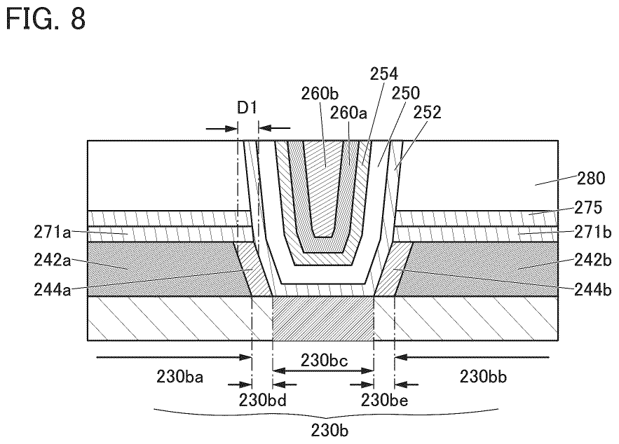

Here, FIG. 8 illustrates an enlarged view of the vicinity of the channel formation region in FIG. 6B. As illustrated in FIG. 8, the length of the insulator 244a in the channel length direction is referred to as a length D1. Note that the length D1 also refers to the distance from the conductor 242a to the insulator 252 in a cross-sectional view in the channel length direction. The length D1 also refers to the distance from the side surface of the conductor 242a to a surface of the insulator 252 that is in contact with the insulator 244a. The length D1 corresponds to, for example, a difference in position between the interface between the conductor 242a and the insulator 244a and the interface between the insulator 244a and the insulator 252. The length of the insulator 244b in the channel length direction is equal to or substantially equal to the length D1.

The length D1 is preferably greater than or equal to 1 nm, greater than or equal to 3 nm, or greater than or equal to 5 nm and less than or equal to 20 nm, less than or equal to 15 nm, or less than or equal to 10 nm. Alternatively, the length D1 is preferably greater than or equal to the thickness of the insulator 252 and less than or equal to a distance from the conductor 260 to the oxide 230. Here, the distance from the conductor 260 to the oxide 230b refers to, for example, a distance from the bottom surface of the conductor 260a to the top surface of the oxide 230b in the cross-sectional view in the channel length direction. Note that the distance from the conductor 260 to the oxide 230b is also the sum of the thickness of the insulator 252, the thickness of the insulator 250, and the thickness of the insulator 254. That is, it can also be said that the distance from the conductor 260 to the oxide 230b is the physical thickness of the first gate insulator. With such a structure, the transistor 200 can have favorable electrical characteristics. Note that the length D1 can be measured by observing a cross-sectional shape of the insulator 244a and its vicinity with a transmission electron microscope (TEM) or the like in some cases.

Furthermore, the length D1 can sometimes be calculated by composition line analysis of the insulator 244a and its vicinity with energy dispersive X-ray spectroscopy (EDX). As an example of a calculation method of the length D1, first, EDX line analysis is performed with the channel length direction as the depth direction. Next, in the profile of quantitative values of elements in the depth direction, which is obtained from the analysis, the depth (position) of the interface between the insulator 244a and the insulator 252 is regarded as a depth at which the quantitative value of an element that is the main component of the insulator 252 but is not the main component of the conductor 242a becomes half. Moreover, the depth (position) of the interface between the conductor 242a and the insulator 244a is regarded as a depth at which the quantitative value of oxygen becomes half. In this manner, the length D1 can be calculated.

As illustrated in FIG. 8, the oxide 230b includes a region 230bc functioning as the channel formation region of the transistor 200 and a region 230ba and a region 230bb that are provided to sandwich the region 230bc and function as the source region and the drain region. At least part of the region 230bc overlaps with the conductor 260. In other words, the region 230bc is provided in a region between the conductor 242a and the conductor 242b. The region 230ba is provided to overlap with the conductor 242a, and the region 230bb is provided to overlap with the conductor 242b.

The region 230bc has a smaller amount of oxygen vacancies or a lower impurity concentration than those of the region 230ba and the region 230bb, and thus is a high-resistance region with a low carrier concentration. Thus, the region 230bc can be regarded as being i-type (intrinsic) or substantially i-type.

The region 230ba and the region 230bb include a large amount of oxygen vacancies or have a high concentration of an impurity such as hydrogen, nitrogen, or a metal element, and thus are each a low-resistance region with an increased carrier concentration. In other words, the region 230ba and the region 230bb are each an n-type region having a higher carrier concentration and a lower resistance than the region 230bc.

Here, the carrier concentration in the region 230bc is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration in the region 230bc functioning as the channel formation region is not particularly limited and can be, for example, 1×10⁻⁹ cm⁻³.

Since the transistor 200 includes the insulator 244a, a region 230bd is formed in the oxide 230b below the insulator 244a. The region 230bd is a region having a carrier concentration lower than or substantially equal to the carrier concentration of the region 230ba and higher than or substantially equal to the carrier concentration of the region 230bc. The region 230bd is positioned between the region 230bc and the region 230ba and thus functions as a junction region or an offset region between the region 230bc and the region 230ba. The region 230bd has a hydrogen concentration lower than or substantially equal to the hydrogen concentration in the region 230ba and higher than or substantially equal to the hydrogen concentration in the region 230bc in some cases. Similarly, since the transistor 200 includes the insulator 244b, a region 230be is formed in the oxide 230b below the insulator 244b. Like the region 230bd, the region 230be functions as a junction region or an offset region between the region 230bc and the region 230bb.

Since the region 230bd is positioned below the insulator 244a, oxygen contained in the insulator 250 or the like is sometimes supplied to the region 230bd through the insulator 244a. Thus, the amount of oxygen vacancies in the region 230bd is smaller than or substantially equal to the amount of oxygen vacancies in the region 230ba and larger than or substantially equal to the amount of oxygen vacancies in the region 230bc in some cases. Similarly, the amount of oxygen vacancies in the region 230be is smaller than or substantially equal to the amount of oxygen vacancies in the region 230bb and larger than or substantially equal to the amount of oxygen vacancies in the region 230bc in some cases.

Although FIG. 8 illustrates an example where the region 230ba, the region 230bb, the region 230bc, the region 230bd, and the region 230be are formed in the oxide 230b, the present invention is not limited thereto. For example, the above regions may be formed not only in the oxide 230b but also in the oxide 230a.

In the oxide 230, the areas of the regions are difficult to detect clearly in some cases. The concentration of a metal element and an impurity element such as hydrogen or nitrogen, which is detected in each region, may be not only gradually changed between the regions but also continuously changed in each region. That is, the region closer to the channel formation region preferably has a lower concentration of an impurity element such as hydrogen or nitrogen.

As illustrated in FIG. 6C, the insulator 252 is provided in contact with the top surface and the side surface of the oxide 230b, the side surface of the oxide 230a, the side surface of the insulator 224, and the top surface of the insulator 222. That is, the regions of the oxide 230a, the oxide 230b, and the insulator 224 that overlap with the conductor 260 are covered with the insulator 252 in the cross section in the channel width direction. The insulator 252 includes a region in contact with the side surface of the insulator 271a, a region in contact with the side surface of the insulator 271b, and a region in contact with a sidewall of the opening included in the insulator 275.

With the above structure, the region 230bc functioning as the channel formation region can be an i-type or substantially i-type region, the region 230ba and the region 230bb functioning as the source region and the drain region can be n-type regions. In addition, the parasitic capacitance between the conductor 260 and the conductor 242a and the parasitic capacitance between the conductor 260 and the conductor 242b can be reduced in a self-aligned manner. Thus, a semiconductor device with favorable electrical characteristics can be provided. The semiconductor device with the above structure can have favorable electrical characteristics even when being miniaturized or highly integrated. For example, the semiconductor device can have favorable electrical characteristics even when a gate length is less than or equal to 20 nm, less than or equal to 15 nm, less than or equal to 10 nm, or less than or equal to 7 nm and greater than or equal to 1 nm, greater than or equal to 3 nm, or greater than or equal to 5 nm. Note that the gate length will be described later.

Furthermore, miniaturization of the transistor 200 can improve high-frequency characteristics. Specifically, a cutoff frequency can be improved. When the gate length is within the above range, the cutoff frequency of the transistor can be greater than or equal to 50 GHz or greater than or equal to 100 GHz at room temperature, for example.

In the case where aluminum oxide is used for the insulator 252, silicon oxide or silicon oxynitride is used for the insulator 250, and silicon nitride is used for the insulator 254, the insulator 252 and the insulator 250 each contain oxygen, and the insulator 250 and the insulator 254 each contain silicon. When layers in contact with each other contain a common element as a main component, the density of defect states at the interface between the layers can be decreased. Thus, carrier traps or the like due to the defect states are reduced, so that the transistor 200 and the semiconductor device which have favorable characteristics and high reliability can be manufactured.

Furthermore, in the case where titanium nitride or tantalum nitride is used for the conductor 260a, the insulator 254 and the conductor 260a each contain nitrogen. With such a structure, the transistor 200 and the semiconductor device which have favorable characteristics and high reliability can be manufactured as described above.

Note that since the oxide 230b contains oxygen as a main component, the density of defect states at the interface between the oxide 230b and the insulator 252 can be decreased. Thus, carrier traps or the like due to the defect states are reduced, so that the transistor 200 and the semiconductor device which have favorable characteristics and high reliability can be manufactured.

In the cross-sectional view in the channel length direction, the bottom surface of the conductor 260a is preferably positioned between the bottom surface and the top surface of the conductor 242a. With such a structure, the electric field of the conductor 260 is likely to act on the channel formation region of the oxide 230b. Thus, the on-state current of the transistor 200 can be increased, and the frequency characteristics of the transistor 200 can be improved. Note that the bottom surface of the conductor 260a is sometimes positioned below the bottom surface of the conductor 242a or positioned above the top surface of the conductor 242a in the cross-sectional view in the channel length direction, depending on the thickness of the gate insulator, the amount of removal of the upper portion of the oxide 230b, or the like.

Here, the gate length is described.

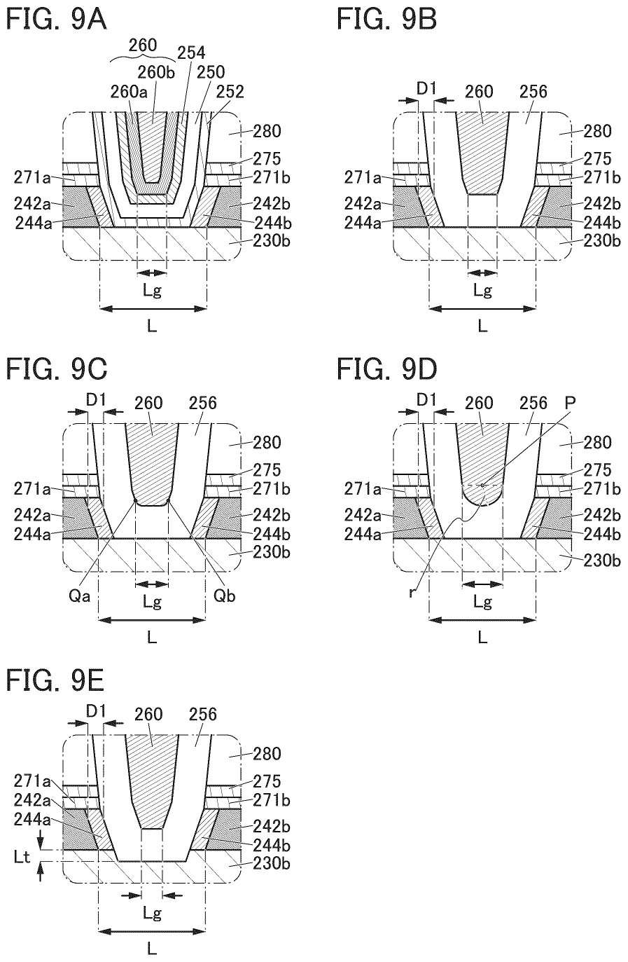

FIG. 9A illustrates an enlarged view of the vicinity of the channel formation region in FIG. 6B. FIG. 9A is a cross-sectional view of the transistor 200 in the channel length direction. As described above, the insulator 252, the insulator 250, and the insulator 254 function as the first gate insulator.

Hereinafter, the insulator 252, the insulator 250, and the insulator 254 are collectively referred to as an insulator 256 in some cases. In this case, the insulator 256 includes the insulator 252, the insulator 250 over the insulator 252, and the insulator 254 over the insulator 250. The insulator 256 functions as the first gate insulator.

FIG. 9B illustrates a cross-sectional view in which the insulator 252, the insulator 250, and the insulator 254 included in FIG. 9A are replaced with the insulator 256. In FIG. 9B, the conductor 260 is illustrated as a single layer for simplification of the drawing. Note that as described above, the conductor 260 may have a stacked-layer structure of the conductor 260a and the conductor 260b or a stacked-layer structure of three or more layers.

A width Lg illustrated in FIG. 9A and FIG. 9B is the width of the bottom surface of the conductor 260 in a region overlapping with the oxide 230b in a cross-sectional view in the channel length direction. Hereinafter, the bottom surface of the conductor 260 in the region overlapping with the oxide 230b in a cross-sectional view in the channel length direction is sometimes simply referred to as the bottom surface of the conductor 260 in the region overlapping with the oxide 230b. That is, the bottom surface of the conductor 260 in the region overlapping with the oxide 230b described later can sometimes be rephrased as the bottom surface of the conductor 260 in the region overlapping with the oxide 230b in a cross-sectional view in the channel length direction.

The gate length refers to the length of a gate electrode in a direction in which carriers move inside a channel formation region during operation of the transistor and to the width of the bottom surface of the gate electrode in a top view of the transistor. In this specification and the like, the gate length is the width of the bottom surface of the conductor 260 in the region overlapping with the oxide 230b in a cross-sectional view in the channel length direction. That is, the gate length is the width Lg illustrated in FIG. 9A and FIG. 9B. Note that the conductor 260 is provided in the opening included in the insulator 275 and the insulator 280. The sidewall of the opening is perpendicular to a substrate surface or inclined to the substrate surface. In particular, in the case where the angle formed between the sidewall of the opening and the substrate surface is less than or equal to 90°, the minimum width of the conductor 260 in the region overlapping with the oxide 230b is the width Lg. Thus, the conductor 260 can be regarded as having a region with the width Lg in a cross-sectional view in the channel length direction.

The bottom surface of the conductor 260 in the region overlapping with the oxide 230b preferably includes a flat region. As illustrated in FIG. 9A and FIG. 9B, in the case where the bottom surface of the conductor 260 in the region overlapping with the oxide 230b includes a flat region, the width Lg is the width of the flat region. When the bottom surface of the conductor 260 in the region overlapping with the oxide 230b includes the flat region, an electric field can be uniformly generated in the channel formation region in the oxide 230.

Although FIG. 9A and FIG. 9B each illustrate a structure in which the bottom surface of the conductor 260 in the region overlapping with the oxide 230b includes the flat region, the present invention is not limited thereto. In a cross-sectional view in the channel length direction, the bottom surface of the conductor 260 in the region overlapping with the oxide 230b may have a curve.

FIG. 9C illustrates a modification example of the transistor 200 illustrated in FIG. 9B. FIG. 9C is a cross-sectional view of the transistor 200 in the channel length direction. For example, as illustrated in FIG. 9C, the bottom surface of the conductor 260 in the region overlapping with the oxide 230b may include a flat region and a region having a curve. Note that the region having a curve is positioned at an end portion of each side of the bottom surface. Here, a point where the curve of the bottom surface on the conductor 242a side is in contact with the side surface of the conductor 260 on the conductor 242a side is referred to as a point Qa. A point where the curve of the bottom surface on the conductor 242b side is in contact with the side surface of the conductor 260 on the conductor 242b side is referred to as a point Qb. In this structure, the width Lg is the length of a line segment connecting the point Qa and the point Qb.

FIG. 9D illustrates a modification example of the transistor 200 illustrated in FIG. 9B. FIG. 9D is a cross-sectional view of the transistor 200 in the channel length direction. For example, as illustrated in FIG. 9D, the bottom surface of the conductor 260 may have an arc shape. Note that the arc has a radius r and a curvature center P is positioned in the conductor 260. In this structure, the width Lg is the width of a region where a straight line that includes the curvature center P and is parallel to the bottom surface of the oxide 230b overlaps with the conductor 260. In other words, the width Lg is twice as long as the radius r. Note that the straight line indicated by a dashed line in FIG. 9D is the straight line that includes the curvature center P and is parallel to the bottom surface of the oxide 230b.

Note that in the case where the radius r is large (e.g., the case where the radius r is larger than the channel length) in the shape of the bottom surface of the conductor 260 illustrated in FIG. 9D, the distance becomes large from the curvature center P to the channel formation region in the oxide 230b. At this time, the width Lg illustrated in FIG. 9C may be applied as the gate length of the shape. That is, the width Lg may be calculated by determining the point Qa and the point Qb in the shape of the bottom surface of the conductor 260 illustrated in FIG. 9D.

It is sometimes difficult to determine the point Qa and the point Qb in the shape of the bottom surface of the conductor 260 illustrated in FIG. 9C. At this time, the width Lg illustrated in FIG. 9D may be applied as the gate length of the shape. That is, the width Lg may be calculated by determining the curvature center P in the shape of the bottom surface of the conductor 260 illustrated in FIG. 9C.

The above is the description of the gate length. Next, the channel length is described.

The insulator 244a has lower conductivity than the conductor 242a, and the insulator 244b has lower conductivity than the conductor 242b. Accordingly, in the case where the transistor 200 includes the insulator 244a and the insulator 244b, the distance between the lower end portion of the conductor 242a and the lower end portion of the conductor 242b can be regarded as the channel length as illustrated in FIG. 9A to FIG. 9D. That is, when the insulator 244a and the insulator 244b are formed, the channel length can be increased. Accordingly, the source-drain withstand voltage of the transistor 200 can be improved, so that the transistor can be highly reliable. Therefore, the transistor can have favorable electrical characteristics even when miniaturized. Note that the distance between the lower end portion of the conductor 242a and the lower end portion of the conductor 242b is a distance L.

The channel length is set in accordance with a material used for the conductor 260, the gate length, a material and the thickness used for the first gate insulator, and the like. In the case where the gate length is within the above range, the channel length is less than or equal to 60 nm, less than or equal to 50 nm, less than or equal to 40 nm, or less than or equal to 30 nm and greater than or equal to 5 nm, greater than or equal to 10 nm, greater than or equal to 15 nm, or greater than or equal to 20 nm, for example.

The length D1 of the insulator 244a in the channel length direction is preferably smaller than the width Lg and is preferably within any of the above ranges. With such a structure, even when the gate length is within any of the above ranges, the transistor 200 can have favorable electrical characteristics. Note that in the case where the width Lg is significantly small (e.g., the case where the width Lg is less than 5 nm), the length D1 is larger than the width Lg in some cases.

When the opening is formed in the insulator 280 and the insulator 275, an upper portion of the oxide 230b in a region overlapping with the opening is removed in some cases. At this time, as illustrated in FIG. 9E, the thickness of the oxide 230b in a region overlapping with the conductor 260 is smaller than the thickness of the oxide 230b in a region overlapping with the conductor 242a. Note that the transistor 200 illustrated in FIG. 9E is a modification example of the transistor 200 illustrated in FIG. 9B. FIG. 9E is a cross-sectional view of the transistor 200 in the channel length direction.

As illustrated in FIG. 9E, a difference between the thickness of the oxide 230b in the region overlapping with the conductor 260 and the thickness of the oxide 230b in the region overlapping with the conductor 242a is referred to as difference Lt. When the difference Lt is small, the distance L may be regarded as the channel length.

According to the above, a semiconductor device having favorable reliability can be provided. A semiconductor device having favorable electrical characteristics can be provided. A semiconductor device that can be miniaturized or highly integrated can be provided. A semiconductor device that has favorable electrical characteristics and can be miniaturized or highly integrated can be provided.

In this embodiment, microwave treatment is performed in an atmosphere containing oxygen in a state where the conductor 242a and the conductor 242b are provided over the oxide 230b so that oxygen vacancies and V_{O}H in the region 230bc are reduced. Note that the microwave treatment will be described in detail in <Manufacturing method of semiconductor device> below.

At least one of the insulator 212, the insulator 214, the insulator 271, the insulator 275, the insulator 282, the insulator 283, and the insulator 285 preferably functions as a barrier insulating film, which inhibits diffusion of impurities such as water and hydrogen from the substrate side or above the transistor 200 into the transistor 200. Thus, for at least one of the insulator 212, the insulator 214, the insulator 271, the insulator 275, the insulator 282, the insulator 283, and the insulator 285, it is preferable to use an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom (an insulating material through which the impurities are less likely to pass). Alternatively, it is preferable to use an insulating material having a function of inhibiting diffusion of oxygen (e.g., at least one of an oxygen atom, an oxygen molecule, and the like) (an insulating material through which the oxygen is less likely to pass).

Note that in this specification, a barrier insulating film refers to an insulating film having a barrier property. A barrier property in this specification means a function of inhibiting diffusion of a targeted substance (also referred to as having low permeability). In addition, a barrier property in this specification means a function of capturing and fixing (also referred to as gettering) a targeted substance.

An insulator having a function of inhibiting diffusion of oxygen and impurities such as water and hydrogen is preferably used for the insulator 212, the insulator 214, the insulator 271, the insulator 275, the insulator 282, the insulator 283, and the insulator 285; for example, aluminum oxide, magnesium oxide, hafnium oxide, gallium oxide, indium gallium zinc oxide, silicon nitride, or silicon nitride oxide can be used. For example, silicon nitride or the like, which has a higher hydrogen barrier property, is preferably used for the insulator 212, the insulator 275, and the insulator 283. For example, aluminum oxide, magnesium oxide, or the like, which has a function of capturing and fixing hydrogen well, is preferably used for the insulator 214, the insulator 271, the insulator 282, and the insulator 285. In this case, impurities such as water and hydrogen can be inhibited from being diffused to the transistor 200 side from the substrate side through the insulator 212 and the insulator 214. Impurities such as water and hydrogen can be inhibited from being diffused to the transistor 200 side through the insulator 283 and the insulator 282 from an interlayer insulating film and the like which are provided outside the insulator 285. Alternatively, oxygen contained in the insulator 224 and the like can be inhibited from being diffused to the substrate side through the insulator 212 and the insulator 214. Alternatively, oxygen contained in the insulator 280 and the like can be inhibited from being diffused above the transistor 200 through the insulator 282 and the like. In this manner, it is preferable that the transistor 200 be surrounded by the insulator 212, the insulator 214, the insulator 271, the insulator 275, the insulator 282, the insulator 283, and the insulator 285, which have a function of inhibiting diffusion of oxygen and impurities such as water and hydrogen.

Here, an oxide having an amorphous structure is preferably used for the insulator 212, the insulator 214, the insulator 271, the insulator 275, the insulator 282, the insulator 283, and the insulator 285. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as the component of the transistor 200 or provided around the transistor 200, hydrogen contained in the transistor 200 or hydrogen around the transistor 200 can be captured or fixed. In particular, hydrogen contained in the channel formation region of the transistor 200 is preferably captured or fixed. The metal oxide having an amorphous structure is used as the component of the transistor 200 or provided around the transistor 200, whereby the transistor 200 and a semiconductor device which have favorable characteristics and high reliability can be manufactured.

Although each of the insulator 212, the insulator 214, the insulator 271, the insulator 275, the insulator 282, the insulator 283, and the insulator 285 preferably has an amorphous structure, a region having a polycrystalline structure may be partly formed. Alternatively, each of the insulator 212, the insulator 214, the insulator 271, the insulator 275, the insulator 282, the insulator 283, and the insulator 285 may have a multilayer structure in which a layer having an amorphous structure and a layer having a polycrystalline structure are stacked. For example, a stacked-layer 20) structure in which a layer having a polycrystalline structure is formed over a layer having an amorphous structure may be employed.

The insulator 212, the insulator 214, the insulator 271, the insulator 275, the insulator 282, the insulator 283, and the insulator 285 are deposited by a sputtering method, for example. Since a sputtering method does not need to use a molecule containing hydrogen for a deposition gas, the hydrogen concentrations in the insulator 212, the insulator 214, the insulator 271, the insulator 275, the insulator 282, the insulator 283, and the insulator 285 can be reduced. Note that the deposition method is not limited to a sputtering method, and a CVD method, an MBE method, a PLD method, an ALD method, or the like may be used as appropriate.

The resistivities of the insulator 212, the insulator 275, and the insulator 283 are preferably low in some cases. For example, by setting the resistivities of the insulator 212, the insulator 275, and the insulator 283 to approximately 1×10¹³ Ωcm, the insulator 212, the insulator 275, and the insulator 283 can sometimes reduce charge up of the conductor 205, the conductor 242, the conductor 260, the conductor 246a, or the conductor 246b in treatment using plasma or the like in the manufacturing process of a semiconductor device. The resistivities of the insulator 212, the insulator 275, and the insulator 283 are preferably higher than or equal to 1×10¹⁰ Ωcm and lower than or equal to 1×10¹⁵ Ωcm.

The insulator 216, the insulator 274, the insulator 280, and the insulator 285 each preferably have a lower permittivity than the insulator 214. When a material with a low permittivity is used for an interlayer film, parasitic capacitance generated between wirings can be reduced. For the insulator 216, the insulator 274, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

The conductor 205 is placed to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the above opening. The conductor 205b is provided to be embedded in a depressed portion formed in the conductor 205a. Here, the top surface of the conductor 205b is level with or substantially level with the top surface of the conductor 205a and the top surface of the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen contained in the conductor 205b can be prevented from being diffused into the oxide 230 through the insulator 216, the insulator 224, and the like. When the conductor 205a is formed using a conductive material having a function of inhibiting diffusion of oxygen, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. Thus, the conductor 205a may be a single layer or a stacked layer of the above conductive materials. For example, titanium nitride is used for the conductor 205a.

Moreover, the conductor 205b is preferably formed using a conductive material containing tungsten, copper, or aluminum as its main component. For example, tungsten is used for the conductor 205b.

The conductor 205 sometimes functions as a second gate electrode. In that case, by changing a potential applied to the conductor 205 out of synchronization with and independently of a potential applied to the conductor 260, the threshold voltage (Vth) of the transistor 200 can be controlled. In particular, Vth of the transistor 200 can be higher in the case where a negative potential is applied to the conductor 205, and the off-state current can be reduced. Thus, a drain current at the time when a potential applied to the conductor 260 is 0 V can be lower in the case where a negative potential is applied to the conductor 205 than in the case where the negative potential is not applied to the conductor 205.

The electric resistivity of the conductor 205 is designed in consideration of the potential applied to the conductor 205, and the thickness of the conductor 205 is determined in accordance with the electric resistivity. The thickness of the insulator 216 is substantially equal to that of the conductor 205. The conductor 205 and the insulator 216 are preferably as thin as possible in the allowable range of the design of the conductor 205. When the thickness of the insulator 216 is reduced, the absolute amount of impurity such as hydrogen contained in the insulator 216 can be reduced, inhibiting the diffusion of the impurity into the oxide 230.

As illustrated in FIG. 6A, the conductor 205 is preferably provided to be larger than a region of the oxide 230 that does not overlap with the conductor 242a or the conductor 242b. As illustrated in FIG. 6C, it is particularly preferable that the conductor 205 extend to a region outside the end portion of the oxide 230 in the channel width direction. That is, the conductor 205 and the conductor 260 preferably overlap with each other with the insulators therebetween on the outer side of the side surface of the oxide 230 in the channel width direction. With this structure, the channel formation region in the oxide 230 can be electrically surrounded by the electric field of the conductor 260 functioning as a first gate electrode and the electric field of the conductor 205 functioning as the second gate electrode. In this specification, a transistor structure in which a channel formation region is electrically surrounded by electric fields of a first gate and a second gate is referred to as a surrounded channel (S-channel) structure.

In this specification and the like, a transistor having the S-channel structure refers to a transistor having a structure in which a channel formation region is electrically surrounded by an electric field of one or the other of a pair of gate electrodes. The S-channel structure disclosed in this specification and the like is different from a Fin-type structure and a planar structure. Meanwhile, the S-channel structure disclosed in this specification and the like can also be regarded as a kind of the Fin-type structure. In this specification and the like, the Fin-type structure refers to a structure in which a gate electrode is placed to cover at least two surfaces (specifically, two surfaces, three surfaces, four surfaces, or the like) of a channel. With the Fin-type structure and the S-channel structure, resistance to a short-channel effect can be enhanced, that is, a transistor in which a short-channel effect is less likely to occur can be provided.

When the transistor 200 becomes normally-off and has the above-described S-channel structure, the channel formation region can be electrically surrounded. The S-channel structure is a structure with the electrically surrounded channel formation region, and thus is, in a sense, equivalent to a GAA (Gate All Around) structure or an LGAA (Lateral Gate All Around) structure. When the transistor 200 has the S-channel structure, the GAA structure, or the LGAA structure, the channel formation region that is formed at the interface between the oxide 230 and the gate insulator or in the vicinity of the interface can be formed in the entire bulk of the oxide 230. Accordingly, the density of current flowing in the transistor can be improved, and it can be expected to improve the on-state current of the transistor or increase the field-effect mobility of the transistor.

Note that although a transistor with an S-channel structure is exemplified as the transistor 200 illustrated in FIG. 6B, the semiconductor device of one embodiment of the present invention is not limited thereto. For example, a transistor structure that can be employed in one embodiment of the present invention is one or more selected from a planar structure, a Fin-type structure, and a GAA structure.

Furthermore, as illustrated in FIG. 6C, the conductor 205 is extended to function as a wiring as well. However, without limitation to this, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is described, the present invention is not limited thereto. For example, the conductor 205 may be provided to have a single-layer structure or a stacked-layer structure of three or more layers.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

As the insulator 222, an insulator containing an oxide of one or both of aluminum and hafnium, which is an insulating material, is preferably used. For the insulator, aluminum oxide, hafnium oxide, an oxide containing aluminum and hafnium (hafnium aluminate), or the like is preferably used. Alternatively, an oxide containing hafnium and zirconium, e.g., a hafnium-zirconium oxide is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen into the oxide 230 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. A stack of the insulator and any of silicon oxide, silicon oxynitride, and silicon nitride may be used for the insulator 222. For example, a two-layer structure in which silicon nitride and silicon oxide are stacked in this order or a three-layer structure in which silicon nitride, silicon oxide, and aluminum oxide are stacked in this order can be employed for the insulator 222.

For example, a single layer or stacked layers of an insulator(s) containing what is called a high-k material such as aluminum oxide, hafnium oxide, tantalum oxide, zirconium oxide, or hafnium-zirconium oxide may be used for the insulator 222. As miniaturization and high integration of transistors progress, a problem such as a leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr)TiO₃ (BST) may be used for the insulator 222.

Silicon oxide or silicon oxynitride, for example, can be used as appropriate for the insulator 224 that is in contact with the oxide 230.

Note that one or both of the insulator 222 and the insulator 224 may have a stacked-layer structure of two or more layers. In that case, without limitation to a stacked-layer structure formed of the same material, a stacked-layer structure formed of different materials may be employed. The insulator 224 may be formed into an island shape so as to overlap with the oxide 230a. In this case, the insulator 275 is in contact with the side surfaces of the insulator 224 and the top surface of the insulator 222.

As the oxide 230, it is possible to use an In-M-Zn oxide containing indium, the element M, and zinc (the element M is one or more kinds selected from aluminum, gallium, yttrium, tin, boron, silicon, vanadium, beryllium, copper, titanium, iron, nickel, germanium, zirconium, molybdenum, lanthanum, cerium, neodymium, hafnium, tantalum, tungsten, magnesium, cobalt, and the like), for example. In particular, a metal oxide containing indium, zinc, and one or more selected from gallium, aluminum, and tin is preferably used. Note that an In—Ga oxide, an In—Zn oxide, an indium oxide, or the like may be used as the oxide 230.

The oxide 230 preferably has a stacked-layer structure of a plurality of oxide layers with different chemical compositions. For example, the atomic ratio of the element M to a metal element that is a main component of the metal oxide used as the oxide 230a is preferably greater than the atomic ratio of the element M to a metal element that is a main component of the metal oxide used as the oxide 230b. Moreover, the atomic ratio of the element M to In in the metal oxide used as the oxide 230a is preferably greater than the atomic ratio of the element M to In in the metal oxide used as the oxide 230b. With this structure, impurities and oxygen can be inhibited from being diffused into the oxide 230b from the components formed below the oxide 230a.

Furthermore, the atomic ratio of In to the element M in the metal oxide used as the oxide 230b is preferably greater than the atomic ratio of In to the element M in the metal oxide used as the oxide 230a. With this structure, the transistor 200 can have a high on-state current and high frequency characteristics.

When the oxide 230a and the oxide 230b contain a common element as the main component besides oxygen, the density of defect states at the interface between the oxide 230a and the oxide 230b can be made low. Thus, the influence of interface scattering on carrier conduction is small, and the transistor 200 can have a high on-state current and excellent frequency characteristics.

Specifically, as the oxide 230a, a metal oxide with a composition of In:M:Zn=1:3:4 [atomic ratio] or in the neighborhood thereof, a composition of In:M:Zn=1:3:2 [atomic ratio] or in the neighborhood thereof, or a composition of In:M:Zn=1:1:0.5 [atomic ratio] or in the neighborhood thereof is used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, a composition of In:M:Zn=4:2:3 [atomic ratio] or in the neighborhood thereof, or a composition of In:M:Zn=5:1:3 [atomic ratio] or in the neighborhood thereof is used. Note that a composition in the neighborhood includes the range of +30% of an intended atomic ratio. Gallium or aluminum is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

Note that in the case where the transistor 200 is used in, for example, a pixel circuit of a display device, part of light (stray light) emitted by a light-emitting element included in the display device might enter the transistor 200. In that case, the stray light sometimes causes a degradation in transistor characteristics and adversely affects pixel operation.

The stray-light-induced degradation amount of transistor characteristics can be evaluated using the amount of change in the threshold voltage or the amount of change in the shift voltage (Vsh) measured in a NBTIS (Negative Bias Temperature Illumination Stress) test of the transistor, for example. Note that the shift voltage (Vsh) is defined as Vg at which, in a drain current (Id)-gate voltage (Vg) curve of a transistor, the tangent at a point where the slope of the curve is the steepest intersects the straight line of Id=1 pA. Here, the degradation that the threshold voltage of the transistor varies or the degradation that Vsh varies in the NBTIS test is referred to as negative-bias stress temperature photodegradation in some cases.

Accordingly, in the case where the transistor 200 is used in the pixel circuit of the display device, the influence of stray light is preferably reduced in the transistor 200. For example, the stray-light-induced degradation of transistor characteristics is preferably reduced in the transistor 200. Specifically, the transistor 200 preferably has high resistance to the NBTIS test (reduces negative-bias stress temperature photodegradation).

In the case where the transistor 200 is used for the pixel circuit of the display device, for example, the metal oxide functioning as a semiconductor of the transistor 200 preferably has a bandgap greater than or equal to 3.1 eV, further preferably greater than or equal to 3.3 eV. The energy of light having a wavelength greater than or equal to 400 nm is less than or equal to 3.1 eV. In other words, even when light having a wavelength greater than or equal to 400 nm enters the metal oxide, electrons in the valence band are less likely to be excited into the conduction band. Thus, when a metal oxide having a wider bandgap is used in a channel formation region of the transistor, the resistance to the NBTIS test can be increased. That is, with use of a metal oxide having a wider bandgap in a channel formation region of the transistor, influence of stray light can be reduced even when a light-blocking layer or the like is not provided, so that degradation of the transistor characteristics can be suppressed.

Specifically, as the oxide 230, a metal oxide with a composition of In:M:Zn=2:6:5 [atomic ratio] or in the neighborhood thereof, a metal oxide with a composition of In:M:Zn=1:3:4 [atomic ratio] or in the neighborhood thereof, a metal oxide with a composition of In:M:Zn=1:1:1 [atomic ratio] or in the neighborhood thereof, or a metal oxide with a composition of In:M:Zn=1:4:5 [atomic ratio] or in the neighborhood thereof is used.

For example, when the atomic ratio is described as In:M:Zn=2:6:5 or a composition in the neighborhood thereof, the case is included where M is greater than or equal to 4 and less than or equal to 8 and Zn is greater than or equal to 3 and less than or equal to 7.5 with In being 2. When the atomic ratio is described as In:M:Zn=1:1:1 or a composition in the neighborhood thereof, the case is included where M is greater than 0.1 and less than or equal to 2 and Zn is greater than 0.1 and less than or equal to 2 with In being 1.

The bandgap of the metal oxide can be evaluated using one or a plurality of optical evaluation with a spectrophotometer, spectroscopic ellipsometry, a photoluminescence method, X-ray photoelectron spectroscopy (XPS or ESCA: Electron Spectroscopy For Chemical Analysis), an X-ray absorption fine structure (XAFS), and the like.

The composition of the metal oxide can be evaluated by an inductively coupled plasma-mass spectrometry (ICP-MS), XPS, SEM (Scanning Electron Microscopy)-EDX (Energy Dispersive X-Ray Spectroscopy), SIMS, or the like.

The oxide 230b preferably has crystallinity. It is particularly preferable to use a CAAC-OS (c-axis aligned crystalline oxide semiconductor) as the oxide 230b.

The CAAC-OS is a metal oxide having a dense structure with high crystallinity and a small amount of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Therefore, the metal oxide including a CAAC-OS is resistant to heat and has high reliability.

When an oxide having crystallinity, such as a CAAC-OS, is used as the oxide 230b, oxygen extraction from the oxide 230b by the conductor 242a or the conductor 242b can be inhibited. This can reduce oxygen extraction from the oxide 230b even when heat treatment is performed; thus, the transistor 200 is stable with respect to high temperatures in a manufacturing process (what is called thermal budget). Furthermore, it is possible to inhibit a reduction in the conductivity of the conductor 242a and the conductor 242b.

As illustrated in FIG. 6C, a curved surface may be provided between the side surface of the oxide 230b and the top surface of the oxide 230b in a cross-sectional view of the transistor 200 in the channel width direction. In other words, an end portion of the side surface and an end portion of the top surface may be curved (hereinafter referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, and further preferably greater than or equal to 2 nm and less than or equal to 10 nm. Such a shape can improve the coverage of the oxide 230b with the insulator 252, the insulator 250, the insulator 254, and the conductor 260.

When aluminum oxide is used for the insulator 252, aluminum is sometimes added to a region of the oxide 230b in contact with the insulator 252 and to the vicinity thereof. Note that addition of aluminum to the region of the oxide 230b in contact with the insulator 252 and to the vicinity thereof is caused by a step in or after a step of the deposition of the insulating film, such as the deposition of the insulating film to be the insulator 252, the formation of a film over the insulating film, or heat treatment performed in or after the deposition of the insulating film.

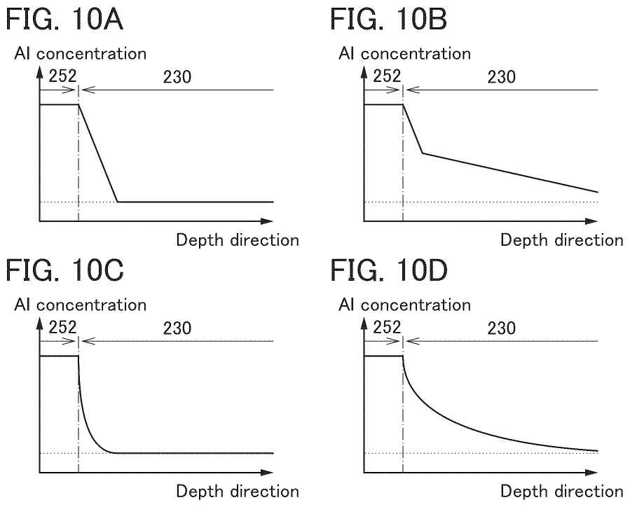

FIG. 10A to FIG. 10D schematically show aluminum concentration profiles in depth direction in the insulator 252 and the oxide 230. In FIG. 10A to FIG. 10D, the vertical axis represents the aluminum (Al) concentration and the horizontal axis represents the depth. Note that the depth can be referred to as a thickness.

In the case where a metal oxide not containing aluminum is used as the oxide 230 before addition of aluminum, the dotted lines shown in FIG. 10A to FIG. 10D represent lower detection limit of the aluminum concentration. In the case where a metal oxide containing aluminum is used as the oxide 230 before addition of aluminum, the dotted lines shown in FIG. 10A to FIG. 10D represent the concentration of aluminum in the oxide 230 in the vicinity of the insulator 224.

As shown in FIG. 10A to FIG. 10D, the oxide 230 has a concentration gradient in which the aluminum concentration increases from the lower surface of the oxide 230 to the upper surface of the oxide 230. In other words, the oxide 230 has a concentration gradient in which the aluminum concentration increases toward the insulator 252 in the thickness direction.

As shown in FIG. 10A, the oxide 230 includes a region where the aluminum concentration decreases monotonously from the peak at the interface between the insulator 252 and the oxide 230 and a region where the aluminum concentration is constant, in some cases. The region where the aluminum concentration decreases monotonously is located close to the insulator 252, compared with the region where the aluminum concentration is constant.

As shown in FIG. 10B, the oxide 230 includes a first region where the aluminum concentration decreases monotonously from the peak at the interface between the insulator 252 and the oxide 230 and a second region where the aluminum concentration decreases monotonously, in some cases. In this case, the first region is located close to the insulator 252, compared with the second region.

As shown in FIG. 10C, the oxide 230 includes a region where the aluminum concentration decreases exponentially from the peak at the interface between the insulator 252 and the oxide 230 and a region where the aluminum concentration is constant, in some cases. In this case, the region where the aluminum concentration decreases exponentially is located close to the insulator 252, compared with the region where the aluminum concentration is constant.

As shown in FIG. 10D, the aluminum concentration of the oxide 230 decreases exponentially from the peak at the interface between the insulator 252 and the oxide 230 in some cases.

The addition of aluminum to the region of the oxide 230b in contact with the insulator 252 and to the vicinity thereof can inhibit the formation of oxygen vacancies in the region and in the vicinity thereof. Since a channel is easily formed in the region of the oxide 230b and the vicinity thereof, oxygen vacancies in the channel formation region can be reduced with such a structure. Accordingly, a change in the electrical characteristics of the transistor 200 can be inhibited, and thus a variation in the electrical characteristics of the transistors 200 in the substrate plane can be inhibited. In the case where an In-M-Zn oxide is used as the oxide 230b before addition of aluminum, the oxide 230b contains at least indium (In), aluminum (Al), and zinc (Zn). Alternatively, indium (In), the element M, aluminum (Al), and zinc (Zn) are contained.

The insulator 252 containing aluminum oxide or the like is provided in contact with the top surface and the side surface of the oxide 230, whereby indium contained in the oxide 230 is unevenly distributed, in some cases, at the interface between the oxide 230 and the insulator 252 and in its vicinity. Accordingly, the vicinity of the surface of the oxide 230 has an atomic ratio close to that of an indium oxide or that of an In—Zn oxide. Such an increase in the atomic ratio of indium in the vicinity of the surface of the oxide 230, especially the vicinity of a surface of the oxide 230b, can increase the field-effect mobility of the transistor 200.

Although the transistor 200 having a structure in which the oxide 230 is a stack of the two layers, the oxide 230a and the oxide 230b, is described, the present invention is not limited thereto. For example, the oxide 230 may be provided as a single layer of the oxide 230a or a single layer of the oxide 230b or as a stacked-layer structure of three or more layers, or the oxide 230a and the oxide 230b may each have a stacked-layer structure.

The conductor 242a and the conductor 242b are provided in contact with the top surface of the oxide 230b.

A conductive material that is not easily oxidized, a conductive material having a function of inhibiting diffusion of oxygen, or the like is preferably used for each of the conductor 242a and the conductor 242b. Examples of the conductive material include a conductive material containing nitrogen and a conductive material containing oxygen. Thus, a decrease in conductivity of the conductor 242a and the conductor 242b can be inhibited. In the case where a conductive material containing a metal element and nitrogen is used for each of the conductor 242a and the conductor 242b, the conductor 242a and the conductor 242b each contain at least the metal element and nitrogen.

For each of the conductor 242a and the conductor 242b, for example, a nitride containing tantalum, a nitride containing titanium, a nitride containing molybdenum, a nitride containing tungsten, a nitride containing tantalum and aluminum, a nitride containing titanium and aluminum, or the like is preferably used. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the oxide 230b or the like is diffused into the conductor 242a or the conductor 242b in some cases. In particular, when a nitride containing tantalum is used for each of the conductor 242a and the conductor 242b, hydrogen contained in the oxide 230b or the like is likely to be diffused into the conductor 242a or the conductor 242b, and the diffused hydrogen is bonded to nitrogen contained in the conductor 242a or the conductor 242b in some cases. That is, hydrogen contained in the oxide 230b or the like is absorbed by the conductor 242a or the conductor 242b in some cases.

No curved surface is preferably formed between the side surface of the conductor 242 and the top surface of the conductor 242. When no curved surface is formed in the conductor 242, the conductor 242 can have a large cross-sectional area in the channel width direction as illustrated in FIG. 6D. Accordingly, the conductivity of the conductor 242 is increased, so that the on-state current of the transistor 200 can be increased.

When heat treatment is performed in the state where the conductor 242a and the oxide 230b are in contact with each other, the sheet resistance of the oxide 230b in a region overlapping with the conductor 242a is decreased in some cases. Furthermore, the carrier concentration is sometimes increased. Thus, the resistance of the oxide 230b in the region overlapping with the conductor 242a can be lowered in a self-aligned manner. Similarly, when heat treatment is performed in the state where the conductor 242b and the oxide 230b are in contact with each other, the sheet resistance of the oxide 230b in a region overlapping with the conductor 242b is decreased in some cases. Furthermore, the carrier concentration is sometimes increased. Thus, the resistance of the oxide 230b in the region overlapping with the conductor 242b can be lowered in a self-aligned manner.

The conductor 242a and the conductor 242b are each preferably formed using a conductive film having compressive stress. This can form distortion extended in the tensile direction (hereinafter, such distortion is sometimes referred to as tensile distortion) in the region 230ba and the region 230bb. When V_{O}H is stably formed in the tensile distortion, the region 230ba and the region 230bb can be stable n-type regions. The compressive stress of the conductor 242a refers to stress for relaxing the compressive shape of the conductor 242a that has a vector in a direction from a center portion to an end portion of the conductor 242a. The same applies to the compressive stress of the conductor 242b.

The level of the compressive stress of the conductor 242a is, for example, preferably higher than or equal to 500 MPa, further preferably higher than or equal to 1000 MPa, still further preferably higher than or equal to 1500 MPa, yet still further preferably higher than or equal to 2000 MPa. The level of the stress of the conductor 242a may be determined from the measured stress of a sample formed by depositing a conductive film to be used for the conductor 242a on a substrate. The same applies to the level of the compressive stress of the conductor 242b.

Due to the action of the compressive stress of each of the conductor 242a and the conductor 242b, distortion is generated in each of the region 230ba and the region 230bb. The distortion is distortion (tensile distortion) extended in the tensile direction by the action of the compressive stress of each of the conductor 242a and the conductor 242b. In the case where the region 230ba and the region 230bb each have a CAAC structure, the distortion corresponds to extension in the direction perpendicular to the c-axis of the CAAC structure. When the CAAC structure is extended in the direction perpendicular to the c-axis of the CAAC structure, oxygen vacancies are likely to be formed in the distortion. Furthermore, hydrogen is likely to be taken in the distortion, so that V_{O}H is likely to be formed. Thus, oxygen vacancies and V_{O}H are easily formed in the distortion, and they are likely to have a stable structure. Thus, the region 230ba and the region 230bb can be stable n-type regions with high carrier concentrations.

Note that although the distortion formed in the oxide 230b is described above, the present invention is not limited thereto. In some cases, a similar distortion is formed in the oxide 230a.

In one embodiment of the present invention, a nitride containing tantalum or a nitride containing titanium is particularly preferably used for each of the conductor 242a and the conductor 242b. In this case, the conductor 242a and the conductor 242b each contain tantalum or titanium and nitrogen.

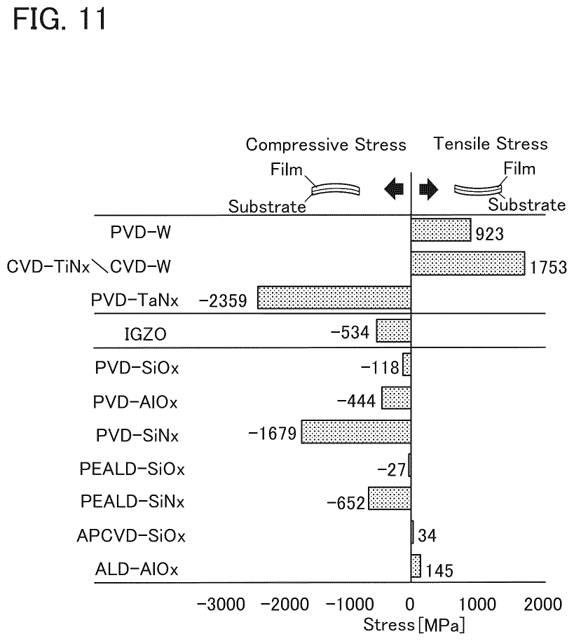

Here, FIG. 11 is a graph showing measured stress of a variety of films (Film) provided over a substrate (Substrate). In FIG. 11, the horizontal axis represents stress (Stress) [MPa]. The film has tensile stress (Tensile Stress) in the case where the stress is positive, and the film has compressive stress (Compressive Stress) in the case where the stress is negative.

In FIG. 11, PVD-W represents a tungsten film deposited by a sputtering method. CVD-TiNx\CVD-W represents a stacked-layer film of a titanium nitride film deposited by a CVD method and a tungsten film deposited thereover by a CVD method. PVD-TaNx represents a tantalum nitride film deposited by a sputtering method. IGZO represents an In—Ga—Zn oxide film deposited by a sputtering method using an oxide target with In:Ga:Zn=1:1:1.2 [atomic ratio]. PVD-SiOx represents a silicon oxide film deposited by a sputtering method. PVD-AlOx represents an aluminum oxide film deposited by a sputtering method. PVD-SiNx represents a silicon nitride film deposited by a sputtering method. PEALD-SiOx represents a silicon oxide film deposited by a PEALD method. PEALD-SiNx represents a silicon nitride film deposited by a PEALD method. APCVD-SiOx represents a silicon oxide film deposited by an atmospheric pressure CVD (APCVD) method. ALD-AlOx represents an aluminum oxide film deposited by a thermal ALD method.

As shown in FIG. 11, the stress of PVD-TaNx is negative and its absolute value is large. That is, it is found that PVD-TaNx has a significantly large compressive stress and is suitably used for each of the conductor 242a and the conductor 242b.

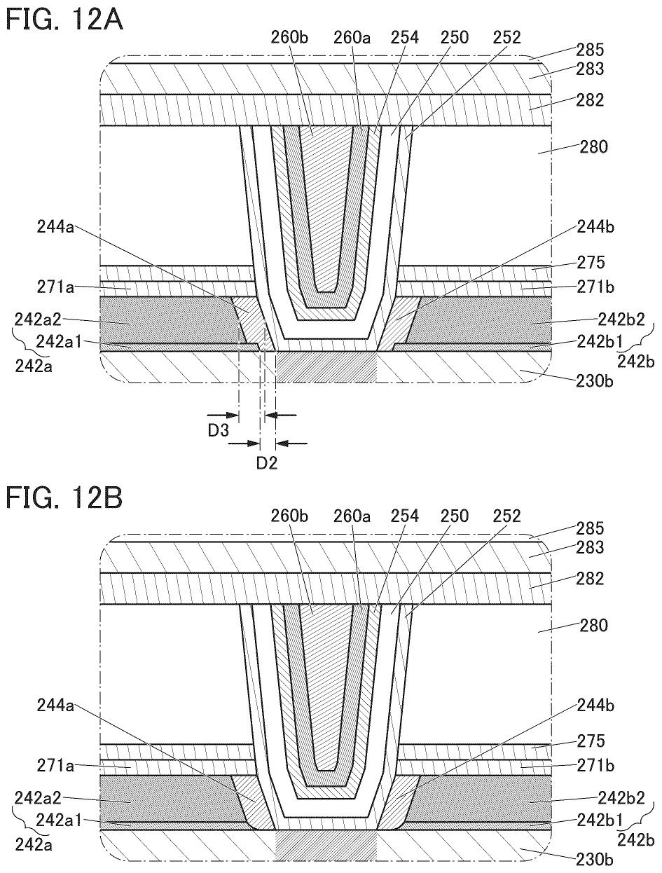

Although FIG. 6A to FIG. 6D and the like illustrate a single-layer structure of the conductor 242, the present invention is not limited thereto, and a stacked-layer structure of two or more layers may be employed. For example, as illustrated in FIG. 12A, the conductor 242a has a two-layer structure of a conductor 242a1 and a conductor 242a2 over the conductor 242a1. The conductor 242b may have a two-layer structure of a conductor 242b1 and a conductor 242b2 over the conductor 242b1. At this time, the conductor 242a1 and the conductor 242b1 are placed so as to be in contact with the oxide 230b.

Hereinafter, the conductor 242a1 and the conductor 242b1 are collectively referred to as a lower layer of a conductor 242 in some cases. The conductor 242a2 and the conductor 242b2 are collectively referred to as an upper layer of the conductor 242 in some cases.

The lower layer (the conductor 242a1 and the conductor 242b1) of the conductor 242 is preferably formed using a conductive material having a property of oxidation resistance. This can inhibit the oxidation of the lower layer of the conductor 242 and a reduction in the conductivity of the conductor 242. Note that the lower layer of the conductor 242 may have such a property that hydrogen is easily absorbed (easily extracted) thereinto. Accordingly, hydrogen in the oxide 230 is diffused into the lower layer of the conductor 242, so that the hydrogen concentration in the oxide 230 can be reduced. As a result, the transistor 200 can have stable electrical characteristics.

An upper layer of the conductor 242 (the conductor 242a2 and the conductor 242b2) is preferably formed using a conductive material with higher conductivity than that of the lower layer of the conductor 242 (the conductor 242a1 and the conductor 242b1). In this case, at least part of the upper layer of the conductor 242 includes a region with higher conductivity than that of the lower layer of the conductor 242. Alternatively, the upper layer of the conductor 242 is preferably formed using a conductive material with lower resistivity than that of the lower layer of the conductor 242. As a result, a semiconductor device with reduced wiring delay can be fabricated.

Note that the upper layer of the conductor 242 may have such a property that hydrogen is easily absorbed. Accordingly, hydrogen absorbed by the lower layer of the conductor 242 is also diffused into the upper layer of the conductor 242, so that the hydrogen concentration in the oxide 230 can be further reduced. As a result, the transistor 200 can have stable electrical characteristics.

Here, for the lower layer of the conductor 242 and the upper layer of the conductor 242, conductive materials containing the same constituent elements and different chemical compositions are preferably used. In this case, the lower layer of the conductor 242 and the upper layer of the conductor 242 can be deposited successively without being exposed to an atmospheric environment. By the deposition without exposure to the atmosphere, impurities or moisture from the atmospheric environment can be prevented from being attached onto the surface of the lower layer of the conductor 242, so that the vicinity of the interface between the lower layer of the conductor 242 and the upper layer of the conductor 242 can be kept clean.

In addition, a nitride containing tantalum with a high atomic ratio of nitrogen to tantalum is preferably used for the lower layer of the conductor 242, and a nitride containing tantalum with a low atomic ratio of nitrogen to tantalum is preferably used for the upper layer of the conductor 242. For example, a nitride containing tantalum at an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used for the lower layer of the conductor 242. In addition, a nitride containing tantalum at an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used for the upper layer of the conductor 242.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the upper layer of the conductor 242. As a result, a semiconductor device with reduced wiring delay can be fabricated.

When the lower layer of the conductor 242 is formed using a conductive material having a property of being less likely to be oxidized and the upper layer of the conductor 242 is formed using a conductive material having a higher conductivity than that of the lower layer of the conductor 242, the insulator 244a and the insulator 244b each include regions having different lengths in the channel length direction as illustrated in FIG. 12A. Here, a distance from the lower layer of the conductor 242 to the insulator 252 is referred to as a length D2, and a distance from the upper layer of the conductor 242 to the insulator 252 is referred to as a length D3. In this case, it can be said that the insulator 244a and the insulator 244b each include a first region whose length in the channel length direction is the length D2 and a second region whose length in the channel length direction is the length D3 over the first region. With such a structure, parasitic capacitance between the conductor 242a and the conductor 260 and parasitic capacitance between the conductor 242b and the conductor 260 can be reduced, and an increase in the channel length can be inhibited. Thus, the switching speed of the transistor 200 can be improved, and the transistor can have high frequency characteristics. In addition, a decrease in the on-state current or field-effect mobility of the transistor 200 can be inhibited.

Although FIG. 12A illustrates the structure in which the lengths of the insulator 244a and the insulator 244b in the channel length direction are discontinuous at the boundary between the upper layer of the conductor 242 and the lower layer of the conductor 242, the lengths of the insulator 244a and the insulator 244b in the channel length direction may be continuously changed at the boundary between the upper layer of the conductor 242 and the lower layer of the conductor 242 as illustrated in FIG. 12B. In this case, the side surface of the insulator 244a in contact with the conductor 242a has a curve in a cross-sectional view. Similarly, the side surface of the insulator 244b in contact with the conductor 242b has a curve in a cross-sectional view. Also with this structure, parasitic capacitance between the conductor 242a and the conductor 260 and parasitic capacitance between the conductor 242b and the conductor 260 can be reduced, and an increase in the channel length can be inhibited.

Note that even when the conductor 242a is a single layer, the side surface of the insulator 244a that is in contact with the conductor 242a has a curve in some cases. Similarly, even when the conductor 242b is a single layer, the side surface of the insulator 244b that is in contact with the conductor 242b has a curve in some cases.

Note that the boundary between the upper layer and the lower layer of the conductor 242 is difficult to clearly detect in some cases. In the case where a nitride containing tantalum is used for the conductor 242, the tantalum concentration and the nitrogen concentration detected in each layer may gradually change within each layer and may also change continuously (or in a gradation manner) in a region between the upper layer and the lower layer. That is, the atomic ratio of nitrogen to tantalum is preferably higher in the region of the conductor 242 that is closer to the oxide 230. Thus, the atomic ratio of nitrogen to tantalum in a lower region of the conductor 242 is preferably higher than the atomic ratio of nitrogen to tantalum in an upper region of the conductor 242.

The thickness of the lower layer of the conductor 242 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the lower layer of the conductor 242 preferably includes a region having the above-described thickness. Furthermore, the thickness of the lower layer of the conductor 242 is preferably smaller than the thickness of the upper layer of the conductor 242. In this case, at least part of the lower layer of the conductor 242 preferably includes a region having a thickness smaller than that of the upper layer of the conductor 242.

In the example shown above, conductive materials containing the same constituent elements and having different chemical compositions are used for the lower layer of the conductor 242 and the upper layer of the conductor 242; however, one embodiment of the present invention is not limited thereto, and the lower layer of the conductor 242 and the upper layer of the conductor 242 may be formed using different conductive materials.

Note that the structures of the lower layer of the conductor 242 and the upper layer of the conductor 242 are not limited to the above. For example, one or more selected from the constituent elements, chemical composition, and deposition conditions may be different between the lower layer of the conductor 242 and the upper layer of the conductor 242. For example, a nitride containing tantalum may be used for the lower layer of the conductor 242 and a nitride containing titanium may be used for the upper layer of the conductor 242.

The insulator 271a is provided in contact with the top surface of the conductor 242a, and the insulator 271b is provided in contact with the top surface of the conductor 242b. The insulator 271 preferably functions as at least a barrier insulating film against oxygen. Thus, the insulator 271 preferably has a function of inhibiting diffusion of oxygen. For example, the insulator 271 preferably has a function of inhibiting diffusion of oxygen more than the insulator 280. As the insulator 271, an insulator such as silicon nitride, aluminum oxide, or magnesium oxide is used, for example.

The insulator 275 is provided to cover the insulator 224, the oxide 230a, the oxide 230b, the conductor 242a, the conductor 242b, the insulator 271a, and the insulator 271b. Specifically, the insulator 275 includes a region in contact with the side surface of the insulator 224, a region in contact with the side surface of the oxide 230a, a region in contact with the side surface of the oxide 230b, a region in contact with the side surface of the conductor 242a, a region in contact with the side surface of the conductor 242b, a region in contact with the side surface and the top surface of the insulator 271a, and a region in contact with the side surface and the top surface of the insulator 271b.

The insulator 275 preferably has a function of capturing and fixing hydrogen. In that case, the insulator 275 preferably includes silicon nitride, or a metal oxide having an amorphous structure, for example, an insulator such as aluminum oxide or magnesium oxide. Alternatively, for example, a stacked-layer film of aluminum oxide and silicon nitride over the aluminum oxide may be used as the insulator 275.

The insulator 275 preferably has a barrier property against oxygen. In this case, oxygen contained in the insulator 280 can be inhibited from being diffused into the side surface of the conductor 242a on the side in contact with the insulator 275 and the side surface of the conductor 242b on the side in contact with the insulator 275. Accordingly, oxidation of the side surface of the conductor 242a on the side in contact with the insulator 275 and the side surface of the conductor 242b on the side in contact with the insulator 275 due to oxygen contained in the insulator 280 can be inhibited, so that an increase in resistivity and a reduction in on-state current can be inhibited. Note that oxygen is less likely to pass through the insulator 275 than the insulator 280, for example. For the insulator 275, a material through which oxygen is less likely to pass than the insulator 280 is used, for example.

When the above insulator 271 and the insulator 275 are provided, the conductor 242 can be surrounded by the insulators having a barrier property against oxygen. That is, oxygen contained in the insulator 280 can be prevented from being diffused into the conductor 242. As a result, the conductor 242 can be inhibited from being directly oxidized by oxygen contained in the insulator 280, so that an increase in resistivity and a reduction in on-state current can be inhibited.

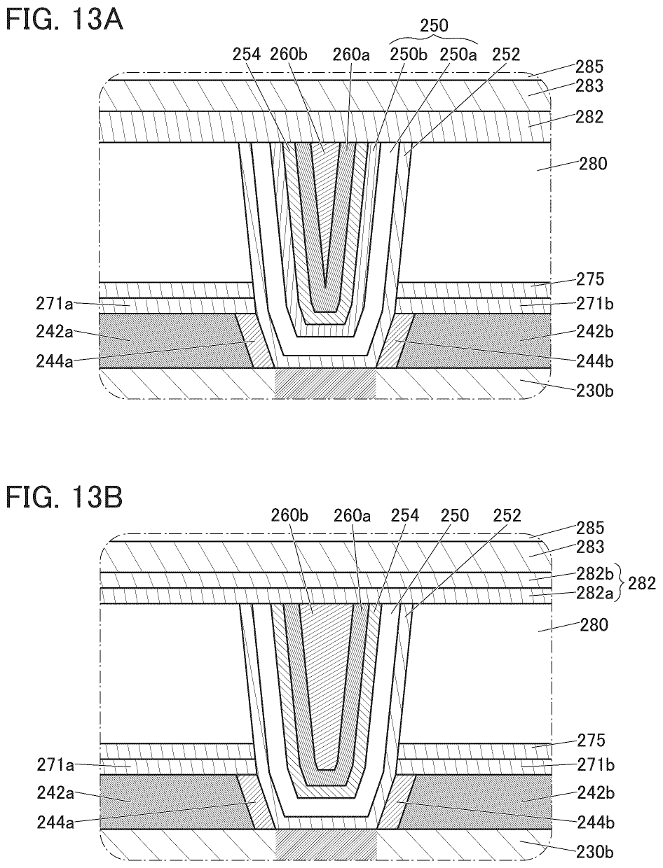

The insulator 250 functions as part of the gate insulator. Although FIG. 6A to FIG. 6D and the like illustrate a single-layer structure of the insulator 250, the present invention is not limited thereto, and a stacked-layer structure of two or more layers may be employed. For example, as illustrated in FIG. 13A, the insulator 250 may have a stacked-layer structure including two layers of an insulator 250a and an insulator 250b over the insulator 250a.

In the case where the insulator 250 has a stacked-layer structure of two layers as illustrated in FIG. 13A, it is preferable that the insulator 250a be formed using an insulator that is likely to transmit oxygen and the insulator 250b be formed using an insulator having a function of inhibiting diffusion of oxygen. With such a structure, oxygen contained in the insulator 250a can be inhibited from being diffused into the conductor 260. That is, a reduction in the amount of oxygen supplied to the oxide 230 can be inhibited. In addition, oxidation of the conductor 260 due to oxygen contained in the insulator 250a can be inhibited. For example, it is preferable that the insulator 250a be provided using any of the above-described materials that can be used for the insulator 250 and the insulator 250b be provided using an insulator containing an oxide of one or both of aluminum and hafnium. As the insulator, aluminum oxide, hafnium oxide, an oxide containing aluminum and hafnium (hafnium aluminate), an oxide containing hafnium and silicon (hafnium silicate), or the like can be used. In this embodiment, hafnium oxide is used for the insulator 250b. In this case, the insulator 250b contains at least oxygen and hafnium. The thickness of the insulator 250b is greater than or equal to 0.5 nm and less than or equal to 5.0 nm, preferably greater than or equal to 1.0 nm and less than or equal to 5.0 nm, further preferably greater than or equal to 1.0 nm and less than or equal to 3.0 nm. In that case, at least part of the insulator 250b preferably includes a region having the above-described thickness.

In the case where silicon oxide, silicon oxynitride, or the like is used for the insulator 250a, the insulator 250b may be formed using an insulating material that is a high-k material having a high relative permittivity. The gate insulator having a stacked-layer structure of the insulator 250a and the insulator 250b can be thermally stable and can have a high relative permittivity. Accordingly, a gate potential applied during the operation of the transistor can be reduced while the physical thickness of the gate insulator is maintained. In addition, the equivalent oxide thickness (EOT) of the insulator functioning as the gate insulator can be reduced. Therefore, the withstand voltage of the insulator 250 can be increased.

Note that in the case where the insulator 250 has a stacked-layer structure of two layers as illustrated in FIG. 13A, an insulator having a function of inhibiting the passage of oxygen and impurities such as hydrogen, e.g., hafnium oxide, is used as the insulator 250b, whereby the insulator 250b can also have the function of the insulator 254. In such a case, the structure without the insulator 254 enables simplification of the manufacturing process and the improvement in productivity of the semiconductor device.

The conductor 260 functions as the first gate electrode of the transistor 200. The conductor 260 preferably includes the conductor 260a and the conductor 260b placed over the conductor 260a. For example, the conductor 260a is preferably placed to cover the bottom surface and the side surface of the conductor 260b. As illustrated in FIG. 6B and FIG. 6C, the top surface of the conductor 260 is level or substantially level with the uppermost portion of the insulator 254, the uppermost portion of the insulator 250, the uppermost portion of the insulator 252, and the top surface of the insulator 280. Although the conductor 260 has a two-layer structure of the conductor 260a and the conductor 260b in FIG. 6B and FIG. 6C, the conductor 260 may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen contained in the insulator 250. As the conductive material having a function of inhibiting diffusion of oxygen, for example, titanium, titanium nitride, tantalum, tantalum nitride, ruthenium, or ruthenium oxide is preferably used. In the case where titanium nitride or tantalum nitride is used for the conductor 260a, the conductor 260a contains titanium or tantalum, and nitrogen.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening formed in the insulator 280 and the like. The formation of the conductor 260 in this manner allows the conductor 260 to be placed properly in a region between the conductor 242a and the conductor 242b without alignment.

As illustrated in FIG. 6C, in the channel width direction of the transistor 200, with reference to the bottom surface of the insulator 222, the level of the bottom surface of the conductor 260 in a region not overlapping with the oxide 230b is preferably lower than the level of the bottom surface of the oxide 230b. When the conductor 260 functioning as the gate electrode covers the side surface and the top surface of the channel formation region of the oxide 230b with the insulator 250 and the like therebetween, the electric field of the conductor 260 is likely to act on the entire channel formation region of the oxide 230b. Thus, the on-state current of the transistor 200 can be increased, and the frequency characteristics of the transistor 200 can be improved. With reference to the bottom surface of the insulator 222, the difference between the level of the bottom surface of the conductor 260 in the region not overlapping with the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

As illustrated in FIG. 6B, the insulator 282 is in contact with at least parts of the top surfaces of the conductor 260, the insulator 252, the insulator 250, the insulator 254, and the insulator 280.

The insulator 282 preferably functions as a barrier insulating film that inhibits impurities such as water and hydrogen from being diffused into the insulator 280 from above and preferably has a function of capturing impurities such as hydrogen. The insulator 282 preferably functions as a barrier insulating film that inhibits passage of oxygen. For the insulator 282, a metal oxide having an amorphous structure, for example, an insulator such as aluminum oxide is used. In this case, the insulator 282 contains at least oxygen and aluminum. The insulator 282, which has a function of capturing impurities such as hydrogen, is provided in contact with the insulator 280 in a region interposed between the insulator 212 and the insulator 283, whereby impurities such as hydrogen contained in the insulator 280 and the like can be captured and the amount of hydrogen in the region can be constant. It is preferable to use, in particular, aluminum oxide having an amorphous structure for the insulator 282, because hydrogen can be captured or fixed more effectively in some cases. Accordingly, the transistor 200 and a semiconductor device which have favorable characteristics and high reliability can be manufactured.

The insulator 282 provided over the insulator 280 is preferably formed by a method in which oxygen can be added to the insulator 280. Thus, excess oxygen can be contained in the insulator 280. As the insulator 282, aluminum oxide is preferably deposited by a sputtering method, further preferably, aluminum oxide is deposited by a pulsed DC sputtering method using an aluminum target in an atmosphere containing an oxygen gas. The use of the pulsed DC sputtering method can achieve more uniform thickness and improve the sputtering rate and film quality. Here, RF (Radio Frequency) power may be applied to the substrate. The amount of oxygen implanted into a layer below the insulator 282 can be controlled depending on the amount of the RF power applied to the substrate. For example, the amount of oxygen implanted into the layer below the insulator 282 is smaller as the RF power is lower, and the amount of oxygen is easily saturated even when the insulator 282 has a small thickness. Moreover, the amount of oxygen implanted into the layer below the insulator 282 is larger as the RF power is higher.

The RF power is higher than or equal to 0 W/cm² and lower than or equal to 1.86 W/cm², for example. In other words, an appropriate amount of oxygen for the transistor characteristics can be changed and implanted by RF power used for the formation of the insulator 282. Accordingly, an appropriate amount of oxygen for improving the reliability of the transistor can be implanted.

The RF frequency is preferably greater than or equal to 10 MHz. The typical frequency is 13.56 MHz. The higher the RF frequency is, the less damage the substrate gets.

Although FIG. 6A to FIG. 6D and the like illustrate a single-layer structure of the insulator 282, the present invention is not limited thereto, and a stacked-layer structure of two or more layers may be employed. For example, as illustrated in FIG. 13B, the insulator 282 may have a stacked-layer structure including two layers of an insulator 282a and an insulator 282b over the insulator 282a.

The insulator 282a and the insulator 282b are preferably formed using the same material by different methods. For example, when aluminum oxide is deposited as the insulator 282 by a pulsed DC sputtering method with use of an aluminum target in an atmosphere containing an oxygen gas, RF power applied to the substrate in the deposition of the insulator 282a and RF power applied to the substrate in the deposition of the insulator 282b are preferably different from each other, and the RF power applied to the substrate in the deposition of the insulator 282a is preferably lower than the RF power applied to the substrate in the deposition of the insulator 282b. Specifically, the insulator 282a is deposited with the RF power applied to the substrate of approximately 0 W/cm² to 0.62 W/cm² inclusive, and the insulator 282b is deposited with the RF power applied to the substrate of 1.86 W/cm² or lower. More specifically, the insulator 282a is deposited with the RF power applied to the substrate of 0 W/cm², and the insulator 282b is deposited with the RF power applied to the substrate of 0.31 W/cm². With such a structure, the insulator 282 can have an amorphous structure, and the amount of oxygen supplied to the insulator 280 can be controlled.

Note that the RF power applied to the substrate in the deposition of the insulator 282a may be higher than the RF power applied to the substrate in the deposition of the insulator 282b. Specifically, the insulator 282a is deposited with the RF power applied to the substrate of 1.86 W/cm² or lower, and the insulator 282b is deposited with the RF power applied to the substrate of approximately 0 W/cm² to 0.62 W/cm² inclusive. More specifically, the insulator 282a is deposited with the RF power applied to the substrate of 1.86 W/cm², and the insulator 282b is deposited with the RF power applied to the substrate of 0.62 W/cm². With such a structure, the amount of oxygen supplied to the insulator 280 can be increased.

The thickness of the insulator 282a is greater than or equal to 1 nm and less than or equal to 20 nm, preferably greater than or equal to 1.5 nm and less than or equal to 15 nm, further preferably greater than or equal to 2 nm and less than or equal to 10 nm, still further preferably greater than or equal to 3 nm and less than or equal to 8 nm. With such a structure, the insulator 282a can have an amorphous structure regardless of the RF power. When the insulator 282a has an amorphous structure, the insulator 282b easily has an amorphous structure, so that the insulator 282 can have an amorphous structure.

Although the insulator 282a and the insulator 282b described above form the stacked-layer structure of the same material, the present invention is not limited thereto. The insulator 282a and the insulator 282b may form a stacked-layer structure of different materials.

The insulator 283 is in contact with part of the top surface of the insulator 214, the side surface of the insulator 216, the side surface of the insulator 222, the side surface of the insulator 275, the side surface of the insulator 280, and the side surface and the top surface of the insulator 282.

The insulator 283 functions as a barrier insulating film that inhibits impurities such as water and hydrogen from being diffused into the insulator 280 from above. The insulator 283 is placed over the insulator 282. The insulator 283 is preferably formed using a nitride containing silicon such as silicon nitride or silicon nitride oxide. For example, silicon nitride deposited by a sputtering method may be used for the insulator 283. When the insulator 283 is deposited by a sputtering method, a high-density silicon nitride film can be formed. To obtain the insulator 283, silicon nitride deposited by a PEALD method or a CVD method may be stacked over silicon nitride deposited by a sputtering method.

For the conductor 240a and the conductor 240b, a conductive material containing tungsten, copper, or aluminum as its main component is preferably used. The conductor 240a and the conductor 240b may each have a stacked-layer structure.

In the case where the conductor 240a and the conductor 240b each have a stacked-layer structure, a conductive material having a function of inhibiting passage of impurities such as water and hydrogen is preferably used for a first conductor placed in the vicinity of the insulator 285, the insulator 283, the insulator 282, the insulator 280, the insulator 275, and the insulator 271. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen contained in a layer above the insulator 283 can be inhibited from entering the oxide 230 through the conductor 240a and the conductor 240b.

For each of the insulator 241a and the insulator 241b, a barrier insulating film that can be used for the insulator 275 or the like is used. As each of the insulator 241a and the insulator 241b, for example, an insulator such as silicon nitride, aluminum oxide, or silicon nitride oxide is used. Since the insulator 241a and the insulator 241b are provided in contact with the insulator 283, the insulator 282, and the insulator 271, impurities such as water and hydrogen contained in the insulator 280) or the like can be inhibited from entering the oxide 230 through the conductor 240a and the conductor 240b. In particular, silicon nitride is suitable because of its high blocking property against hydrogen. Furthermore, oxygen contained in the insulator 280 can be prevented from being absorbed by the conductor 240a and the conductor 240b.

When the insulator 241a and the insulator 241b each have a stacked-layer structure illustrated in FIG. 6B, a first insulator in contact with an inner wall of the opening in the insulator 280 and the like and a second insulator on the inner side of the first insulator are preferably formed using a combination of a barrier insulating film against oxygen and a barrier insulating film against hydrogen.

For example, aluminum oxide deposited by an ALD method is used for the first insulator and silicon nitride deposited by a PEALD method is used for the second insulator. With such a structure, oxidation of the conductor 240a and the conductor 240b can be inhibited, and hydrogen can be inhibited from entering the conductor 240a and the conductor 240b.

The conductor 246a functioning as a wiring may be placed in contact with the top surface of the conductor 240a and the conductor 246b functioning as a wiring may be placed in contact with the top surface of the conductor 240b. The conductor 246a and the conductor 246b are each preferably formed using a conductive material containing tungsten, copper, or aluminum as its main component. Furthermore, the conductor may have a stacked-layer structure and may be a stacked layer of titanium or titanium nitride and the conductive material, for example. Note that the conductor may be formed so as to be embedded in an opening provided in an insulator.

### <Component Materials of Semiconductor Device>

Component materials that can be used for the semiconductor device are described below.

### <<Substrate>>

As a substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor element, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. By contrast, when a material with a low relative permittivity is used for the insulator functioning as an interlayer film, the parasitic capacitance generated between wirings can be reduced. Thus, a material is preferably selected depending on the function of an insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

The oxide 230 is preferably formed using a metal oxide functioning as a semiconductor (an oxide semiconductor). A metal oxide that can be used as the oxide 230 of the present invention is described below.

The metal oxide preferably contains at least indium or zinc. In particular, indium and zinc are preferably contained. Furthermore, aluminum, gallium, yttrium, tin, or the like is preferably contained in addition to them. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, the element M, and zinc is considered. The element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also collectively referred to as a metal oxide in some cases. A metal oxide containing nitrogen may be called a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including a completely amorphous structure), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method. The XRD spectrum obtained by GIXD measurement may be hereinafter simply referred to as an XRD spectrum.

For example, the XRD spectrum of the quartz glass substrate shows a peak with a substantially bilaterally symmetrical shape. Meanwhile, the peak of the XRD spectrum of an In—Ga—Zn oxide film having a crystal structure has a bilaterally asymmetrical shape. The asymmetrical peak of the XRD spectrum clearly shows the presence of crystals in the film or the substrate. In other words, the crystal structure of the film or the substrate cannot be regarded as amorphous unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass is in an amorphous state. Furthermore, not a halo pattern but a spot-like pattern is observed in the diffraction pattern of the In—Ga—Zn oxide film deposited at room temperature. Thus, it is suggested that the In—Ga—Zn oxide deposited at room temperature is in an intermediate state, which is neither a single crystal nor polycrystal nor an amorphous state, and it cannot be concluded that the In—Ga—Zn oxide is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter less than 10 nm). In the case where the crystal region is formed of one fine crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Thus, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the transistor including a metal oxide in its channel formation region (referred to as an OS transistor in some cases) can extend the degree of freedom of the manufacturing process.

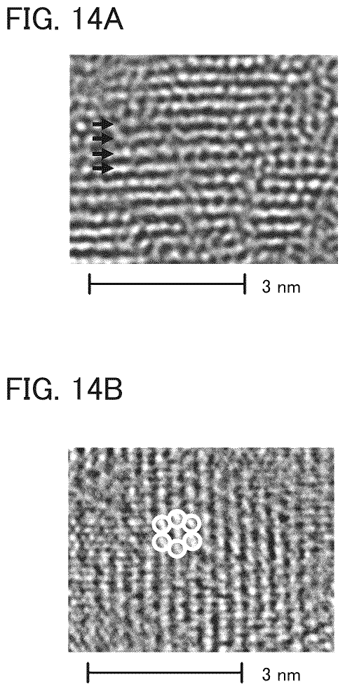

Here, FIG. 14A and FIG. 14B show TEM images of a CAAC-OS deposited by a sputtering method using an oxide target with In:Ga:Zn=1:1:1.2 [atomic ratio]. Here, FIG. 14A is a cross-sectional TEM image of the CAAC-OS observed from the direction perpendicular to the c-axis, and FIG. 14B is a plan-view TEM image of the CAAC-OS observed from the direction parallel to the c-axis.

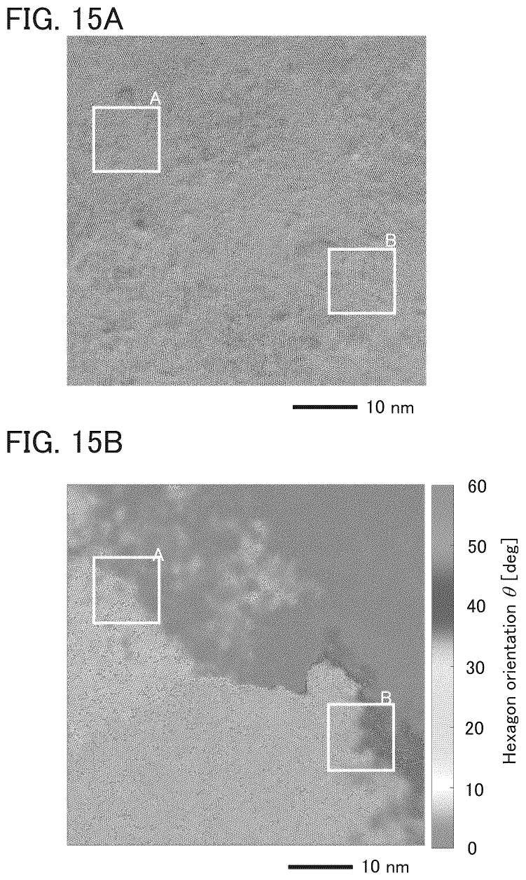

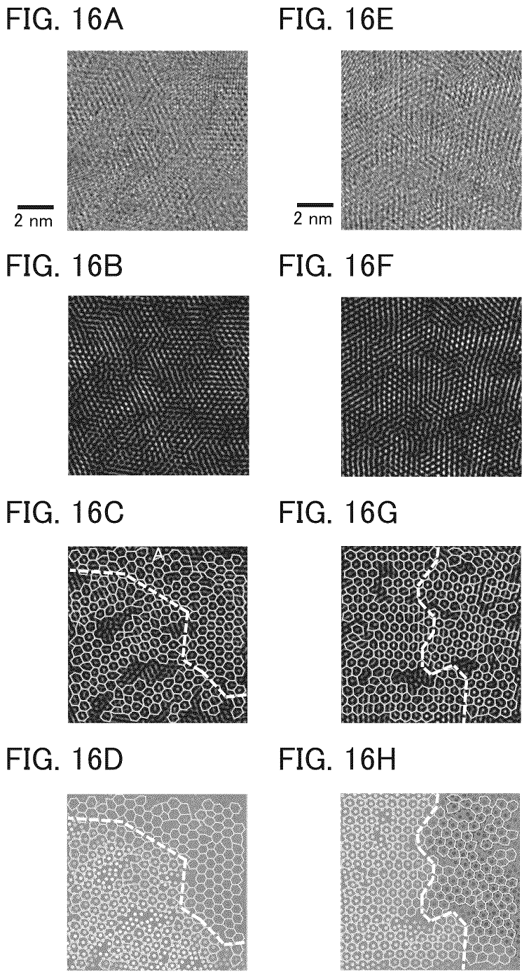

In FIG. 14A, a layered structure aligned in the c-axis direction is observed. In FIG. 14B, a large number of hexagonal lattice arrangements are observed, and in a portion, a non-regular hexagonal lattice arrangement is also observed. As described above, the CAAC-OS is an oxide semiconductor having c-axis alignment and having no clear alignment in the a-b plane direction. Next, the distribution of hexagonal lattice orientations in a CAAC-OS is described with reference to FIG. 15 and FIG. 16.

FIG. 15A shows a plan-view TEM image of a CAAC-OS deposited by a sputtering method using an oxide target with In:Ga:Zn=1:1:1.2 [atomic ratio]. FIG. 15B shows a mapping image showing the distribution of hexagonal lattice orientations in the CAAC-OS. FIG. 15B is the mapping image obtained by analyzing the image in FIG. 15A.

The mapping image shown in FIG. 15B was obtained in the following procedure. First, the plan-view TEM image in FIG. 15A was subjected to fast Fourier transform (FFT), so that an FFT image was obtained. Then, the FFT image was subjected to mask processing except for a specific frequency range. After that, the FFT image subjected to the mask processing was subjected to inverse fast Fourier transform (IFFT) to obtain an FFT filtering image. Next, the FFT filtering image was subjected to image analysis to extract lattice points. Then, a hexagon orientation θ [deg], which is the orientation of a hexagon formed by six lattice points closest to each other, was obtained. The hexagon orientation θ was determined in a range greater than or equal to 0° and less than 60° while an angle that appears most frequently was set to 30°. In the mapping image in FIG. 15B, color density was set in accordance with the degree of the hexagon orientation θ.

In FIG. 15B, a plurality of domains of the same color each having a width of approximately several tens of nanometers are observed. That is, in the CAAC-OS, a structure with a uniform hexagonal lattice orientation having a width of approximately several tens of nanometers is formed.

Here, FIG. 16 shows a region A and a region B each including a boundary between two structures different from each other in a hexagonal lattice orientation. FIG. 16A is a plan-view TEM image of the region A and is an enlarged view of the region A in FIG. 15A. FIG. 16B is an FFT filtering image of the region A. FIG. 16C is an image obtained by extracting hexagonal lattice points of the region A from FIG. 16B. FIG. 16D is a mapping image of the region A. FIG. 16E is a plan-view TEM image of the region B and is an enlarged view of the region B in FIG. 15A. FIG. 16F is an FFT filtering image of the region B. FIG. 16G is an image obtained by extracting hexagonal lattice points of the region B from FIG. 16F. FIG. 16H is a mapping image of the region B. Note that the dashed line shown in each of FIG. 16C, FIG. 16D, FIG. 16G, and FIG. 16H corresponds to a boundary portion between the two structures different from each other in a hexagonal lattice orientation.

As shown in FIG. 16D and FIG. 16H, in the vicinity of the boundary portion, a difference in color density and a difference in hexagonal lattice orientation are small between the two structures different from each other in a hexagonal lattice orientation. The boundary portion between the two structures different from each other in a hexagonal lattice orientation was observed in a blurred state, and a state where the structures are connected to each other so as to be tangled with each other was observed. As described above, a clear crystal grain boundary is not observed in the CAAC-OS.

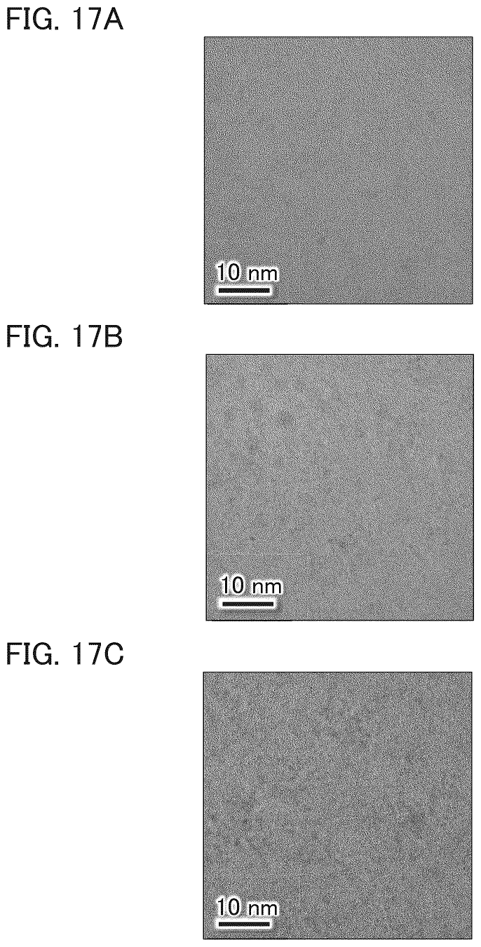

Next, the distribution of hexagonal lattice orientations in CAAC-OSs different from each other in thickness and whether or not heat treatment is performed is described with reference to FIG. 17 to FIG. 20.

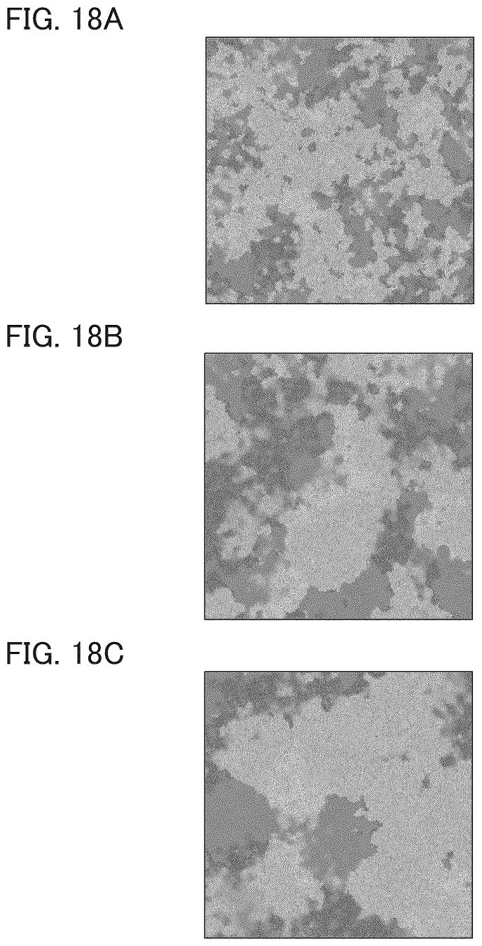

FIG. 17A to FIG. 17C each show a plan-view TEM image of a CAAC-OS deposited by a sputtering method using an oxide target with In:Ga:Zn=1:1:1.2 [atomic ratio]. Here, FIG. 17A shows a CAAC-OS with a thickness of 5 nm, FIG. 17B shows a CAAC-OS with a thickness of 10 nm, and FIG. 17C shows a CAAC-OS with a thickness of 20 nm. FIG. 18A to FIG. 18C show mapping images corresponding to FIG. 17A to FIG. 17C, respectively. Like FIG. 15B, FIG. 18A to FIG. 18C each show the mapping image showing the distribution of hexagonal lattice orientations in the CAAC-OS.

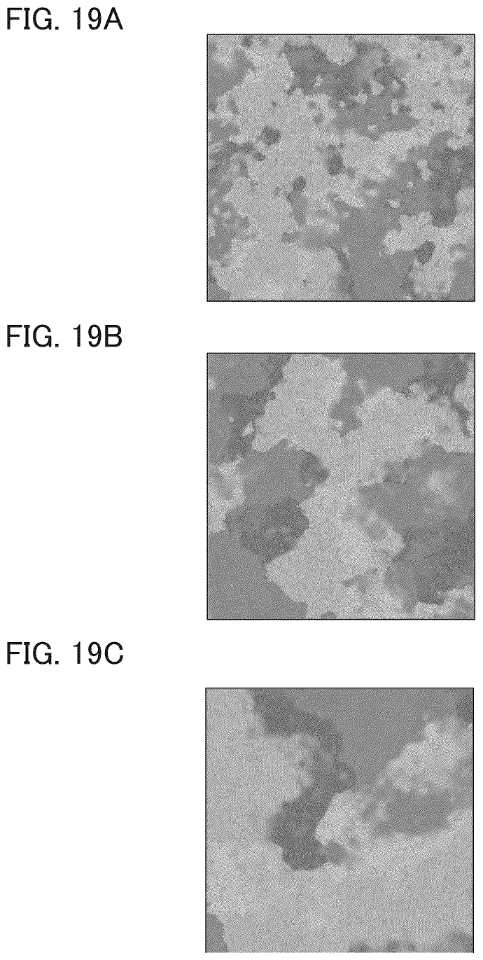

FIG. 19A to FIG. 19C show mapping images of CAAC-OSs, which are CAAC-OSs subjected to additional heat treatment. The heat treatment was performed in a mixed atmosphere of an oxygen gas of 1 slm and a nitrogen gas of 4 slm at a substrate temperature of 450° C. for one hour. The thicknesses of the CAAC-OSs shown in FIG. 19A to FIG. 19C correspond to FIG. 17A to FIG. 17C, respectively. Like FIG. 15B, FIG. 19A to FIG. 19C each show the mapping image showing the distribution of hexagonal lattice orientations in the CAAC-OS.

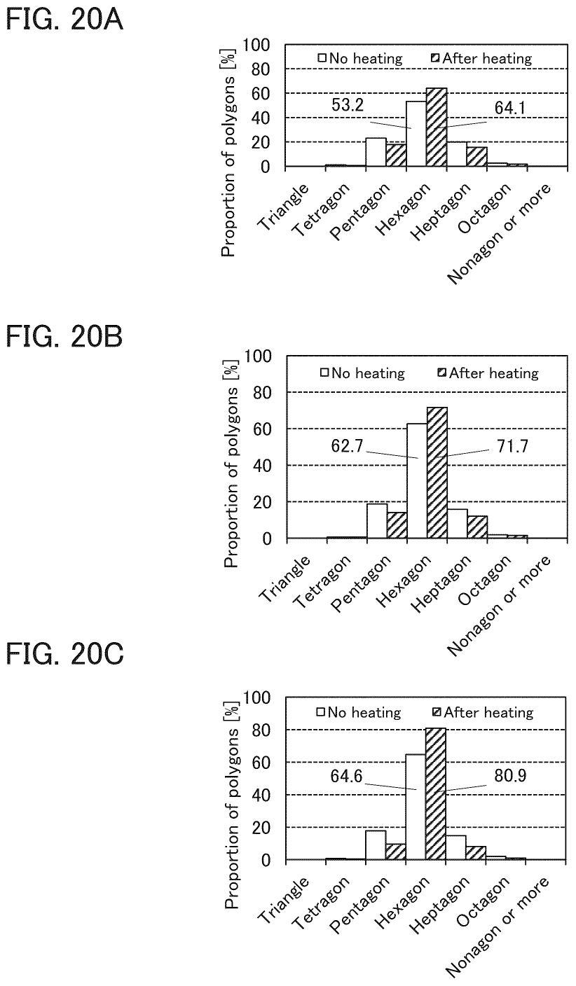

FIG. 20A to FIG. 20C show Voronoi polygon distribution histograms of the CAAC-OSs having different thicknesses. The thicknesses of the CAAC-OSs shown in FIG. 20A to FIG. 20C correspond to FIG. 17A to FIG. 17C, respectively. FIG. 20A to FIG. 20C each show the histogram of the CAAC-OS not subjected to the heat treatment and the histogram of the CAAC-OS after the heat treatment side by side.

It was found from FIG. 17 to FIG. 20 that as the thickness of the CAAC-OS became large, the domain with a uniform hexagonal lattice orientation tended to become large, and the angle between the domains tended to be continuously changed. It was also found that when the heat treatment was performed, the domain tended to become large. The above indicates that the CAAC-OS starts to be crystallized at the time when the CAAC-OS is deposited to have a certain thickness. It is also indicated that the heat treatment promotes crystallization of the CAAC-OS.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter nearly equal to or smaller than the diameter of a nanocrystal (e.g., 1 nm or larger and 30 nm or smaller).

[a-Like OS]

The a-like OS is an oxide semiconductor having a structure between those of the nc-OS and the amorphous oxide semiconductor. The a-like OS contains a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas may be used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

Meanwhile, the second region has a higher insulating property than the first region. In other words, when the second regions are distributed in a metal oxide, off-state current can be inhibited.

Thus, in the case where a CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Iₒₙ), a high field-effect mobility (μ), and an excellent switching operation can be achieved.

A transistor including the CAC-OS has high reliability. Thus, the CAC-OS is most suitable for a variety of semiconductor devices such as display devices.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states are reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that impurities in an oxide semiconductor refer to, for example, elements other than the main components of an oxide semiconductor. For example, an element with a concentration lower than 0.1 atomic % can be regarded as an impurity.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor (the concentration obtained by SIMS) is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor including an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

### <<Other Semiconductor Materials>>

The oxide 230 can be rephrased as a semiconductor layer including a channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single element semiconductor such as silicon, a compound semiconductor such as gallium arsenide, or a layered substance functioning as a semiconductor (also referred to as an atomic layer material or a two-dimensional material) is preferably used as a semiconductor material. In particular, a layered substance functioning as a semiconductor is favorably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, and chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

For a semiconductor layer of a transistor, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### <Manufacturing Method of Semiconductor Device>

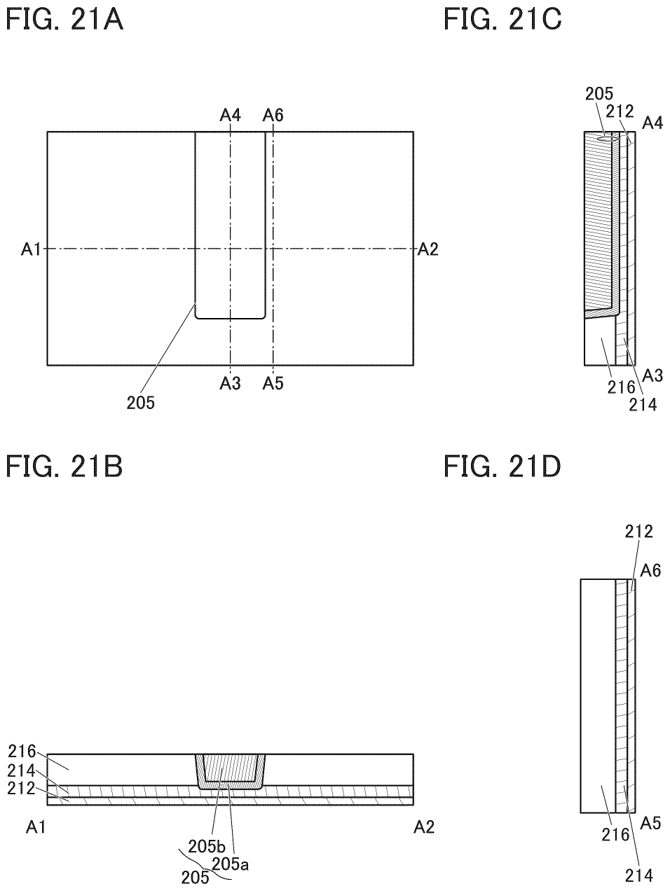

Next, a method for manufacturing the semiconductor device of one embodiment of the present invention illustrated in FIG. 6A to FIG. 6D is described with reference to FIG. 21A to FIG. 31D.

Note that A of each drawing is a top view. Moreover, B of each drawing is a cross-sectional view corresponding to a portion indicated by dashed-dotted line A1-A2 in A of each drawing, and is also a cross-sectional view of the transistor 200 in the channel length direction. Furthermore, C of each drawing is a cross-sectional view corresponding to a portion indicated by dashed-dotted line A3-A4 in A of each drawing, and is also a cross-sectional view of the transistor 200 in the channel width direction. Furthermore, D of each drawing is a cross-sectional view of a portion indicated by dashed-dotted line A5-A6 in A of each drawing. Note that for clarity of the drawing, some components are not illustrated in the top view of A of each drawing.

Hereinafter, an insulating material for forming an insulator, a conductive material for forming a conductor, or a semiconductor material for forming a semiconductor can be deposited by a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is deposited, and a DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD method, a thermal CVD method, a photo CVD method, and the like. Moreover, the CVD method can be classified into a metal CVD method and a metal organic CVD method depending on a source gas to be used.

A high-quality film can be obtained at a relatively low temperature by a plasma enhanced CVD method. Furthermore, a thermal CVD method is a deposition method that does not use plasma and thus enables less plasma damage to an object. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. In contrast, such plasma damage is not caused in the case of a thermal CVD method not using plasma, and thus the yield of the semiconductor device can be increased. In addition, a thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, a CVD method and an ALD method are deposition methods that enable favorable step coverage almost regardless of the shape of an object. In particular, an ALD method has excellent step coverage and excellent thickness uniformity and thus is suitable for covering a surface of an opening portion with a high aspect ratio, for example. Note that an ALD method has a relatively low deposition rate, and thus is preferably used in combination with another deposition method with a high deposition rate, such as a CVD method, in some cases.

By a CVD method, a film with a certain composition can be deposited depending on the flow rate ratio of the source gases. For example, by a CVD method, by changing the flow rate ratio of the source gases during the deposition, a film in which the composition is continuously changed can be deposited. In the case where the film is deposited while the flow rate ratio of the source gases is changed, as compared to the case where the film is deposited using a plurality of deposition chambers, the time taken for the deposition can be shortened because the time taken for transfer or pressure adjustment is omitted. Thus, the productivity of the semiconductor device can be increased in some cases.

In an ALD method, a film with a freely selected composition can be deposited by concurrently introducing different kinds of precursors. Alternatively, in the case where different kinds of precursors are introduced, a film with a freely selected composition can be deposited by controlling the cycle number of each of the precursors.

First, a substrate (not illustrated) is prepared, and the insulator 212 is deposited over the substrate (see FIG. 21A to FIG. 21D). The insulator 212 is preferably deposited by a sputtering method. By using a sputtering method that does not need to use a molecule containing hydrogen for a deposition gas, the hydrogen concentration in the insulator 212 can be reduced. Without limitation to a sputtering method, the insulator 212 may be deposited by a CVD method, an MBE method, a PLD method, an ALD method, or the like as appropriate.

In this embodiment, for the insulator 212, silicon nitride is deposited by a pulsed DC sputtering method using a silicon target in an atmosphere containing a nitrogen gas. The use of the pulsed DC sputtering method can inhibit generation of particles due to arcing on the target surface, enabling more uniform thickness. In addition, by using the pulsed voltage, rising and falling in discharge can be made steep as compared with the case where a high-frequency voltage is used. As a result, power can be supplied to an electrode more efficiently to improve the sputtering rate and film quality.

The use of an insulator through which impurities such as water and hydrogen are less likely to pass, such as silicon nitride, can inhibit diffusion of impurities such as water and hydrogen contained in a layer below the insulator 212. When an insulator through which copper is less likely to pass, such as silicon nitride, is used for the insulator 212, even in the case where a metal that is likely to diffuse, such as copper, is used for a conductor in a layer (not illustrated) below the insulator 212, upward diffusion of the metal through the insulator 212 can be inhibited.

Next, the insulator 214 is deposited over the insulator 212 (see FIG. 21A to FIG. 21D). The insulator 214 is preferably deposited by a sputtering method. By using a sputtering method that does not need to use a molecule containing hydrogen for a deposition gas, the hydrogen concentration in the insulator 214 can be reduced. Without limitation to a sputtering method, the insulator 214 may be deposited by a CVD method, an MBE method, a PLD method, an ALD method, or the like as appropriate.

A metal oxide having an amorphous structure and an excellent function of capturing and fixing hydrogen, such as aluminum oxide, is preferably used for the insulator 214. In this case, the insulator 214 captures or fixes hydrogen contained in the insulator 216 and the like and prevents the hydrogen from being diffused into the oxide 230. In particular, it is preferable to use aluminum oxide having an amorphous structure or amorphous aluminum oxide for the insulator 214 because hydrogen can be captured or fixed more effectively in some cases. Accordingly, the transistor 200 and a semiconductor device which have favorable characteristics and high reliability can be manufactured.

In this embodiment, for the insulator 214, aluminum oxide is deposited by a pulsed DC sputtering method using an aluminum target in an atmosphere containing an oxygen gas. The use of the pulsed DC sputtering method can achieve more uniform thickness and improve the sputtering rate and film quality. Here, RF power may be applied to the substrate. The amount of oxygen implanted into a layer below the insulator 214 can be controlled depending on the amount of the RF power applied to the substrate. The RF power is higher than or equal to 0 W/cm² and lower than or equal to 1.86 W/cm². In other words, the amount of oxygen to be implanted can be changed to be appropriate for the characteristics of the transistor, with the RF power used at the time of forming the insulator 214. Accordingly, an appropriate amount of oxygen for improving the reliability of the transistor can be implanted. The RF frequency is preferably greater than or equal to 10 MHz. The typical frequency is 13.56 MHz. The higher the RF frequency is, the less damage the substrate gets.

Next, the insulator 216 is deposited over the insulator 214. The insulator 216 is preferably deposited by a sputtering method. By using a sputtering method that does not need to use a molecule containing hydrogen for a deposition gas, the hydrogen concentration in the insulator 216 can be reduced. Without limitation to a sputtering method, the insulator 216 may be deposited by a CVD method, an MBE method, a PLD method, an ALD method, or the like as appropriate.

In this embodiment, for the insulator 216, silicon oxide is deposited by a pulsed DC sputtering method using a silicon target in an atmosphere containing an oxygen gas. The use of the pulsed DC sputtering method can achieve more uniform thickness and improve the sputtering rate and film quality.

The insulator 212, the insulator 214, and the insulator 216 are preferably successively deposited without exposure to the air. For example, a multi-chamber deposition apparatus may be used. As a result, the amounts of hydrogen in the deposited insulator 212, insulator 214, and insulator 216 can be reduced, and furthermore, entry of hydrogen into the films in intervals between deposition steps can be inhibited.

Then, an opening reaching the insulator 214 is formed in the insulator 216. Examples of the opening include a groove and a slit. A region where an opening is formed is referred to as an opening portion in some cases. Wet etching can be used for the formation of the opening; however, dry etching is preferably used for microfabrication. As the insulator 214, it is preferable to select an insulator that functions as an etching stopper film used in forming the groove by etching the insulator 216. For example, in the case where silicon oxide or silicon oxynitride is used for the insulator 216 in which the groove is to be formed, silicon nitride, aluminum oxide, or hafnium oxide is preferably used for the insulator 214.

As a dry etching apparatus, a capacitively coupled plasma (CCP) etching apparatus having parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus having a high-density plasma source can be used. As the dry etching apparatus including a high-density plasma source, an inductively coupled plasma (ICP) etching apparatus can be used, for example.

After the formation of the opening, a conductive film to be the conductor 205a is deposited. The conductive film desirably includes a conductor having a function of inhibiting passage of oxygen. For example, tantalum nitride, tungsten nitride, or titanium nitride can be used. Alternatively, a stacked-layer film of the conductor having a function of inhibiting passage of oxygen and tantalum, tungsten, titanium, molybdenum, aluminum, copper, or a molybdenum-tungsten alloy can be used. The conductive film can be deposited by a sputtering method, a CVD method, an MBE method, a PLD method, an ALD method, or the like.

In this embodiment, titanium nitride is deposited as the conductive film to be the conductor 205a. When such a metal nitride is used for a layer under the conductor 205b, oxidation of the conductor 205b by the insulator 216 or the like can be inhibited. Furthermore, even when a metal that is likely to diffuse, such as copper, is used for the conductor 205b, the metal can be prevented from being diffused to the outside through the conductor 205a.

Next, a conductive film to be the conductor 205b is deposited. Tantalum, tungsten, titanium, molybdenum, aluminum, copper, a molybdenum-tungsten alloy, or the like can be used for the conductive film. The conductive film can be deposited by a plating method, a sputtering method, a CVD method, an MBE method, a PLD method, an ALD method, or the like. In this embodiment, tungsten is deposited for the conductive film.

Next, by performing CMP treatment, part of the conductive film to be the conductor 205a and part of the conductive film to be the conductor 205b are removed to expose the insulator 216 (see FIG. 21A to FIG. 21D). As a result, the conductor 205a and the conductor 205b remain only in the opening portion. Note that the insulator 216 is partly removed by the CMP treatment in some cases.

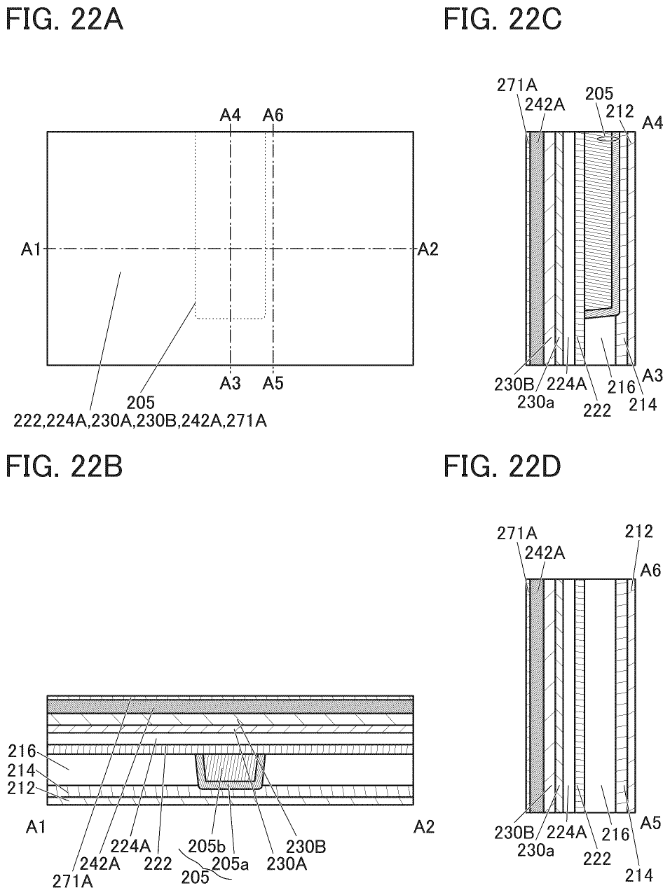

Next, the insulator 222 is deposited over the insulator 216 and the conductor 205 (see FIG. 22A to FIG. 22D). An insulator containing an oxide of one or both of aluminum and hafnium is preferably deposited as the insulator 222. Note that as the insulator containing an oxide of one or both of aluminum and hafnium, aluminum oxide, hafnium oxide, an oxide containing aluminum and hafnium (hafnium aluminate), or the like is preferably used. Alternatively, hafnium-zirconium oxide is preferably used. The insulator containing an oxide of one or both of aluminum and hafnium has a barrier property against oxygen, hydrogen, and water. When the insulator 222 has a barrier property against hydrogen and water, hydrogen and water contained in components provided around the transistor 200 are inhibited from being diffused into the transistor 200 through the insulator 222, and generation of oxygen vacancies in the oxide 230 can be inhibited.

The insulator 222 can be deposited by a sputtering method, a CVD method, an MBE method, a PLD method, an ALD method, or the like. In this embodiment, for the insulator 222, hafnium oxide is deposited by an ALD method.

Sequentially, heat treatment is preferably performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the insulator 222 and the like as much as possible.

In this embodiment, as the heat treatment, treatment is performed with a flow rate ratio of a nitrogen gas and an oxygen gas of 4:1 at 400° C. for one hour after the deposition of the insulator 222. By the heat treatment, impurities such as water and hydrogen contained in the insulator 222 can be removed, for example. In the case where an oxide containing hafnium is used for the insulator 222, the insulator 222 is partly crystallized by the heat treatment in some cases. The heat treatment can also be performed after the deposition of the insulating film to be the insulator 224, for example.

Next, an insulating film 224A is deposited over the insulator 222 (see FIG. 22A to FIG. 22D). The insulating film 224A can be deposited by a sputtering method, a CVD method, an MBE method, a PLD method, an ALD method, or the like. In this embodiment, for the insulating film 224A, silicon oxide is deposited by a sputtering method. By using a sputtering method that does not need to use a molecule containing hydrogen for a deposition gas, the hydrogen concentration in the insulating film 224A can be reduced. The hydrogen concentration in the insulating film 224A is preferably reduced because the insulating film 224A is in contact with the oxide 230a in a later step.

Next, an oxide film 230A and an oxide film 230B are deposited in this order over the insulating film 224A (see FIG. 22A to FIG. 22D). Note that it is preferable to deposit the oxide film 230A and the oxide film 230B successively without exposure to the air. By the deposition without exposure to the air, impurities or moisture from the atmospheric environment can be prevented from being attached onto the oxide film 230A and the oxide film 230B, so that the vicinity of the interface between the oxide film 230A and the oxide film 230B can be kept clean.

The oxide film 230A and the oxide film 230B can be deposited by a sputtering method, a CVD method, an MBE method, a PLD method, an ALD method, or the like. In this embodiment, the oxide film 230A and the oxide film 230B are deposited by a sputtering method.

For example, in the case where the oxide film 230A and the oxide film 230B are deposited by a sputtering method, oxygen or a mixed gas of oxygen and a noble gas is used as a sputtering gas. Increasing the proportion of oxygen contained in the sputtering gas can increase the amount of excess oxygen in the deposited oxide films. In the case where the oxide films are deposited by a sputtering method, the above In-M-Zn oxide target or the like can be used.

In particular, when the oxide film 230A is deposited, part of oxygen contained in the sputtering gas is supplied to the insulator 224 in some cases. Thus, the proportion of oxygen contained in the sputtering gas is higher than or equal to 70%, preferably higher than or equal to 80%, further preferably 100%.

In the case where the oxide film 230B is formed by a sputtering method and the proportion of oxygen contained in the sputtering gas is higher than 30% and lower than or equal to 100%, preferably higher than or equal to 70% and lower than or equal to 100%, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the oxide film 230B is formed by a sputtering method and the proportion of oxygen contained in the sputtering gas is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the deposition is performed while the substrate is being heated, the crystallinity of the oxide film can be improved.

In this embodiment, the oxide film 230A is deposited by a sputtering method using an oxide target with In:Ga:Zn=1:3:4 [atomic ratio]. In addition, the oxide film 230B is deposited by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 230a and the oxide 230b by selecting the deposition conditions and the atomic ratios as appropriate.

The insulating film 224A, the oxide film 230A, and the oxide film 230B are preferably deposited by a sputtering method without exposure to the air. For example, a multi-chamber deposition apparatus is used. As a result, entry of hydrogen into the insulating film 224A, the oxide film 230A, and the oxide film 230B in intervals between deposition steps can be inhibited.

Next, heat treatment is preferably performed. The heat treatment is performed in a temperature range where the oxide film 230A and the oxide film 230B do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide film 230A and the oxide film 230B to reduce oxygen vacancies. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere. Alternatively, the heat treatment may be performed in a nitrogen gas or inert gas atmosphere successively after heat treatment is performed in an atmosphere containing an oxidizing gas at 10 ppm or more, 1% or more, or 10% or more.

Note that by oxygen adding treatment performed on the oxide 230, oxygen vacancies in the oxide 230 can be repaired with supplied oxygen. Furthermore, hydrogen remaining in the oxide 230 reacts with supplied oxygen, so that the hydrogen can be removed as H₂O (dehydration). This can inhibit recombination of hydrogen remaining in the oxide 230 with oxygen vacancies and formation of V_{O}H.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the oxide film 230A, the oxide film 230B, and the like as much as possible.

In this embodiment, the heat treatment is performed at 400° C. for one hour with the flow rate ratio of nitrogen gas to oxygen gas being 4:1. By the heat treatment using the oxygen gas, impurities such as water and hydrogen in the oxide film 230A and the oxide film 230B can be reduced, for example. Such a reduction of impurities in the films improves the crystallinity of the oxide film 230B, thereby offering a dense structure with higher density. Thus, crystalline regions in the oxide film 230A and the oxide film 230B are expanded, so that in-plane variations of the crystalline regions in the oxide film 230A and the oxide film 230B can be reduced. Accordingly, an in-plane variation of electrical characteristics of the transistor 200 can be reduced.

By performing heat treatment, hydrogen in the insulator 216, the insulating film 224A, the oxide film 230A, and the oxide film 230B moves into the insulator 222 and is absorbed by the insulator 222. In other words, hydrogen in the insulator 216, the insulating film 224A, the oxide film 230A, and the oxide film 230B are diffused into the insulator 222. Accordingly, the hydrogen concentration in the insulator 222 increases, and the hydrogen concentrations in the insulator 216, the insulating film 224A, the oxide film 230A, and the oxide film 230B decrease.

In particular, the insulating film 224A functions as a gate insulator of the transistor 200, and the oxide film 230A and the oxide film 230B function as the channel formation region of the transistor 200. Thus, the transistor 200 preferably includes the insulating film 224A, the oxide film 230A, and the oxide film 230B with reduced hydrogen concentrations because favorable reliability can be obtained.

Next, a conductive film 242A is deposited over the oxide film 230B (see FIG. 22A to FIG. 22D). The conductive film 242A can be deposited by a sputtering method, a CVD method, an MBE method, a PLD method, an ALD method, or the like. For example, as the conductive film 242A, a tantalum nitride film is deposited by a sputtering method. Note that heat treatment may be performed before the deposition of the conductive film 242A. This heat treatment may be performed under reduced pressure, and the conductive film 242A may be successively deposited without exposure to the air. The treatment can remove moisture and hydrogen adsorbed onto the surface of the oxide film 230B, and further can reduce the moisture concentration and the hydrogen concentration in the oxide film 230A and the oxide film 230B. The heat treatment is preferably performed at a temperature higher than or equal to 100° C. and lower than or equal to 400° C. In this embodiment, the heat treatment is preferably performed at 200° C.

Next, an insulating film 271A is deposited over the conductive film 242A (see FIG. 22A to FIG. 22D). The insulating film 271A can be deposited by a sputtering method, a CVD method, an MBE method, a PLD method, an ALD method, or the like. As the insulating film 271A, an insulating film having a function of inhibiting passage of oxygen is preferably used. For example, as the insulating film 271A, an aluminum oxide film or a silicon nitride film may be deposited by a sputtering method. For another example, as the insulating film 271A, a silicon nitride film and a silicon oxide film over the silicon nitride film may be deposited by a sputtering method.

Note that the conductive film 242A and the insulating film 271A are preferably deposited by a sputtering method without exposure to the air. For example, a multi-chamber deposition apparatus may be used. As a result, the amounts of hydrogen in the conductive film 242A and the insulating film 271A can be reduced, and furthermore, entry of hydrogen into the films in intervals between deposition steps can be inhibited. In the case where a hard mask is provided over the insulating film 271A, a film to be the hard mask is preferably successively deposited without exposure to the air.

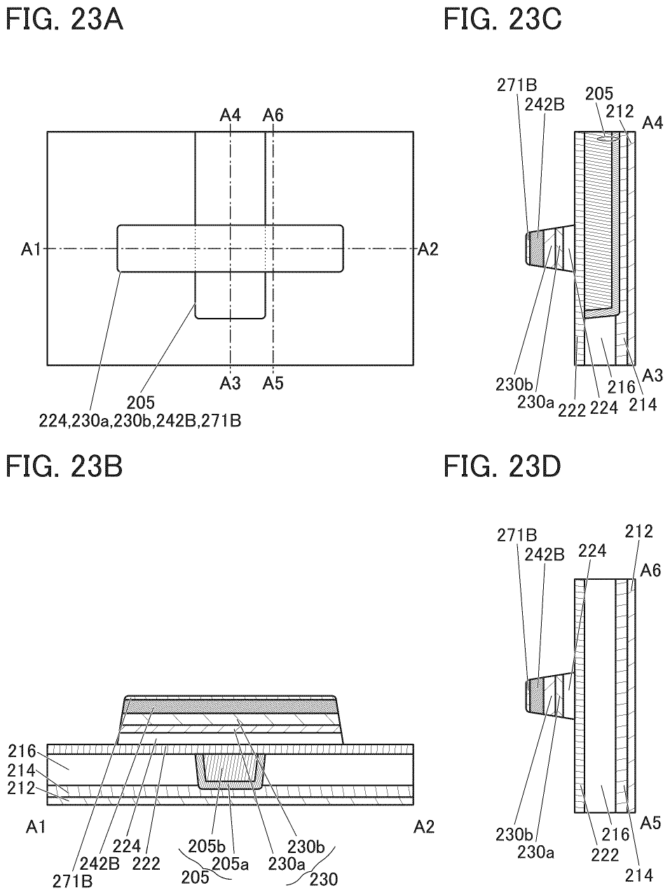

Next, the insulating film 224A, the oxide film 230A, the oxide film 230B, the conductive film 242A, and the insulating film 271A are processed into island shapes by a lithography method to form the insulator 224, the oxide 230a, the oxide 230b, a conductive layer 242B, and an insulating layer 271B (see FIG. 23A to FIG. 23D). Here, the insulator 224, the oxide 230a, the oxide 230b, the conductive layer 242B, and the insulating layer 271B are formed to at least partly overlap with the conductor 205. A dry etching method or a wet etching method can be used for the processing. A dry etching method is suitable for microfabrication. The insulating film 224A, the oxide film 230A, the oxide film 230B, the conductive film 242A, and the insulating film 271A may be processed under different conditions.

Note that in the lithography method, first, a resist is exposed to light through a mask. Next, a region exposed to light is removed or left using a developing solution, so that a resist mask is formed. Then, etching process through the resist mask is conducted, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. Alternatively, a liquid immersion technique may be employed in which a gap between a substrate and a projection lens is filled with liquid (e.g., water) in light exposure. Alternatively, an electron beam or an ion beam may be used instead of the light. Note that a mask is unnecessary in the case of using an electron beam or an ion beam. Note that the resist mask can be removed by a dry etching process such as ashing, a wet etching process, a wet etching process after a dry etching process, or a dry etching process 20) after a wet etching process.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the conductive film 242A, a resist mask is formed thereover, and then the hard mask material is etched. The etching of the conductive film 242A and the like may be performed after removing the resist mask or with the resist mask remaining. In the latter case, the resist mask sometimes disappears during the etching. The hard mask may be removed by etching after the etching of the conductive film 242A and the like. Meanwhile, the hard mask is not necessarily removed when the hard mask material does not affect later steps or can be utilized in later steps. In this embodiment, the insulating layer 271B is used as a hard mask.

Here, the insulating layer 271B functions as a mask for the conductive layer 242B; thus, as illustrated in FIG. 23B to FIG. 23D, the conductive layer 242B does not have a curved surface between the side surface and the top surface. Thus, end portions at the intersections of the side surfaces and the top surfaces of the conductor 242a and the conductor 242b illustrated in FIG. 6B and FIG. 6D are angular. The cross-sectional area of the conductor 242 in the case where the end portion at the intersection of the side surface and the top surface of the conductor 242 is angular is larger than that in the case where the end portion is rounded. Accordingly, the resistance of the conductor 242 is reduced, so that the on-state current of the transistor 200 can be increased.

Furthermore, as illustrated in FIG. 23B to FIG. 23D, the side surfaces of the insulator 224, the oxide 230a, the oxide 230b, the conductive layer 242B, and the insulating layer 271B may have tapered shapes. In this specification and the like, a tapered shape indicates a shape in which at least part of the side surface of a structure is inclined to a substrate surface. For example, the angle formed between the inclined side surface and the substrate surface (hereinafter, the angle is referred to as a taper angle in some cases) is preferably less than 90°. Each of the side surfaces of the insulator 224, the oxide 230a, the oxide 230b, the conductive layer 242B, and the insulating layer 271B has a taper angle greater than or equal to 60° and less than 90°. With such tapered shapes of the side surfaces, the coverage with the insulator 275 and the like can be improved in a later step, so that defects such as a void can be reduced.

Not being limited to the above, the insulator 224, the oxide 230a, the oxide 230b, the conductive layer 242B, and the insulating layer 271B may be processed to have side surfaces that are substantially perpendicular to the top surface of the insulator 222. With such a structure, a plurality of transistors 200 can be provided with high density in a small area.

A by-product generated in the above etching step is sometimes formed in a layered manner on the side surfaces of the insulator 224, the oxide 230a, the oxide 230b, the conductive layer 242B, and the insulating layer 271B. In this case, the layered by-product is formed between the insulator 275 and the insulator 224, the oxide 230a, the oxide 230b, the conductive layer 242B, and the insulating layer 271B. Hence, the layered by-product formed in contact with the top surface of the insulator 222 is preferably removed.

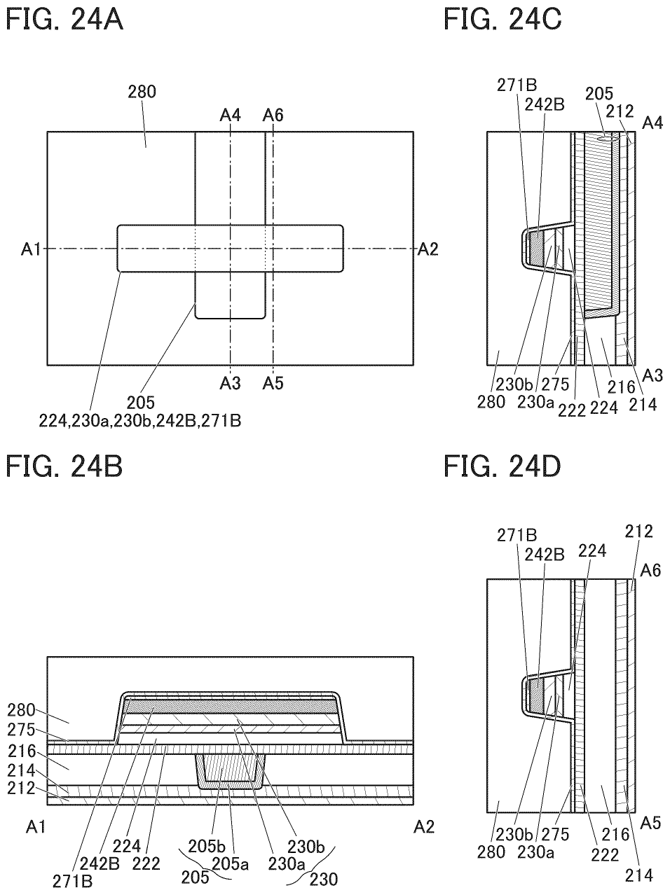

Next, the insulator 275 is deposited to cover the insulator 224, the oxide 230a, the oxide 230b, the conductive layer 242B, and the insulating layer 271B (see FIG. 24A to FIG. 24D). Here, it is preferable that the insulator 275 be in contact with the top surface of the insulator 222 and the side surface of the insulator 224. The insulator 275 can be deposited by a sputtering method, a CVD method, an MBE method, a PLD method, an ALD method, or the like. The insulator 275 is preferably formed using an insulating film having a function of inhibiting passage of oxygen. For example, silicon nitride may be deposited as the insulator 275 by an ALD method. For example, as the insulator 275, aluminum oxide may be deposited by a sputtering method, and silicon nitride may be deposited thereover by a PEALD method. When the insulator 275 has such a stacked-layer structure, the function of inhibiting diffusion of impurities such as water or hydrogen and oxygen is improved in some cases.

In this manner, the insulator 224, the oxide 230a, the oxide 230b, and the conductive layer 242B can be covered with the insulator 275 and the insulating layer 271B, which have a function of inhibiting diffusion of oxygen. This structure can suppress direct diffusion of oxygen from the insulator 280 into the insulator 224, the oxide 230a, the oxide 230b, and the conductive layer 242B in a later step.

Next, an insulating film to be the insulator 280 is deposited over the insulator 275. The insulating film can be deposited by a sputtering method, a CVD method, an MBE method, a PLD method, an ALD method, or the like. A silicon oxide film may be deposited by a sputtering method as the insulating film, for example. When the insulating film is deposited by a sputtering method in an oxygen-containing atmosphere, the insulator 280 containing excess oxygen can be formed. Since a molecule containing hydrogen is not used for a deposition gas in the sputtering method, the hydrogen concentration in the insulator 280 can be reduced. Note that heat treatment may be performed before the insulating film is deposited. The heat treatment may be performed under reduced pressure, and the insulating film may be successively deposited without exposure to the air. The treatment can remove moisture and hydrogen adsorbed onto the surface of the insulator 275 and the like, and further can reduce the moisture concentration and the hydrogen concentration in the oxide 230a, the oxide 230b, and the insulator 224. For the heat treatment, the above heat treatment conditions can be used.

Next, the insulating film to be the insulator 280 is subjected to CMP treatment, so that the insulator 280 with a flat top surface is formed (see FIG. 24A to FIG. 24D). Note that, for example, silicon nitride may be deposited over the insulator 280 by a sputtering method and CMP treatment may be performed on the silicon nitride until the insulator 280 is reached.

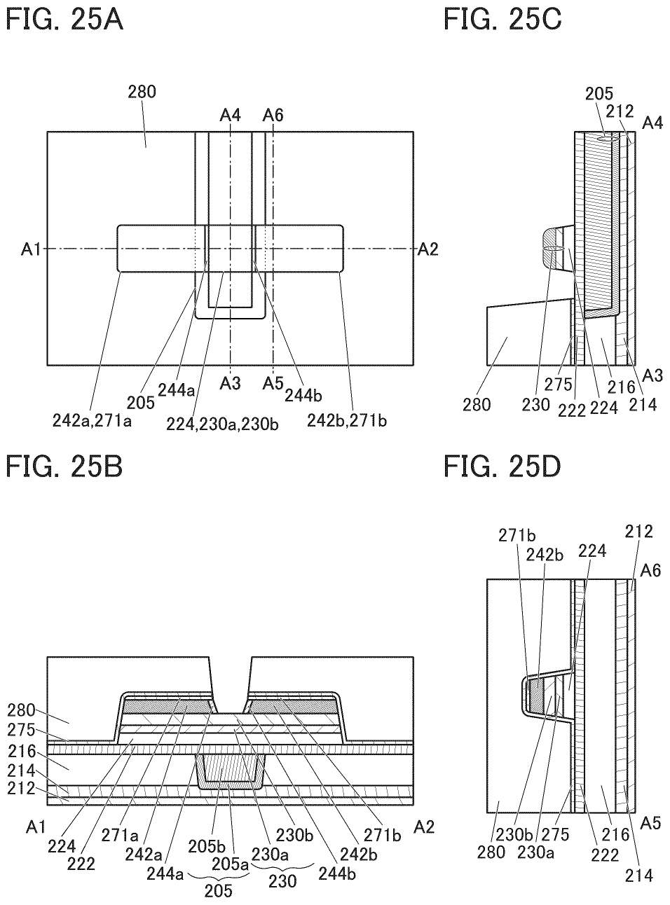

Then, part of the insulator 280, part of the insulator 275, part of the insulating layer 271B, and part of the conductive layer 242B are processed to form an opening reaching the oxide 230b. The opening is preferably formed to overlap with the conductor 205. The insulator 271a, the insulator 271b, the conductor 242a, and the conductor 242b are formed through the formation of the opening (see FIG. 25A to FIG. 25D).

Here, as illustrated in FIG. 25B and FIG. 25C, the side surfaces of the insulator 280, the insulator 275, the insulator 271, and the conductor 242 may be tapered. The taper angle of the insulator 280 is larger than the taper angle of the conductor 242 in some cases. Although not illustrated in FIG. 25A to FIG. 25C, the upper portion of the oxide 230b is sometimes removed when the opening is formed. When part of the oxide 230b is removed, a groove portion is sometimes formed in the oxide 230b.

The part of the insulator 280, the part of the insulator 275, the part of the insulating layer 271B, and the part of the conductive layer 242B can be processed by a dry etching method or a wet etching method. A dry etching method is suitable for microfabrication. The processing may be performed under different conditions. For example, the part of the insulator 280 may be processed by a dry etching method, the part of the insulator 275 and the part of the insulating layer 271B may be processed by a wet etching method, and the part of the conductive layer 242B may be processed by a dry etching method.

In forming the opening, the side surface of the conductor 242a is oxidized to form the insulator 244a in some cases. Furthermore, the side surface of the conductor 242b is oxidized to form the insulator 244b in some cases. Note that the lengths of the insulator 244a and the insulator 244b in the channel length direction change depending on the processing conditions for forming the opening.

A dry etching apparatus used for forming the conductor 242a and the conductor 242b has a function of eliminating static electricity accumulated on a substrate during etching. That is, plasma treatment is performed with power lower than that in the formation of the conductor 242a and the conductor 242b after the etching process for forming the conductor 242a and the conductor 242b is completed, whereby static electricity accumulated on the substrate is eliminated. This plasma treatment is referred to as static neutralization plasma treatment. For example, in the case where nitrogen is used in the static neutralization plasma treatment, the lengths of the insulator 244a and the insulator 244b in the channel length direction tend to be smaller than those in the case where oxygen is used in the static neutralization plasma treatment.

Here, impurities are attached onto the side surface of the oxide 230a, the top surface and the side surface of the oxide 230b, the side surface of the conductor 242, the side surface of the insulator 280, and the like or the impurities might be diffused thereinto in some cases. A step of removing the impurities may be performed. In addition, a damaged region might be formed on the surface of the oxide 230b by the above dry etching. The damaged region may be removed. The impurities come from components contained in the insulator 280, the insulator 275, part of the insulating layer 271B, and the conductive layer 242B; components contained in a member of an apparatus used to form the opening; and components contained in a gas or a liquid used for etching, for instance. Examples of the impurities include hafnium, silicon, tantalum, fluorine, and chlorine.

In particular, impurities such as silicon might reduce the crystallinity of the oxide 230b. Thus, it is preferable that impurities such as silicon be removed from the surface of the oxide 230b and the vicinity thereof. The concentration of the impurities is preferably reduced. For example, the concentration of silicon atoms in the surface of the oxide 230b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet further preferably lower than 0.3 atomic %.

Note that since the density of a crystal structure is reduced in a low-crystallinity region of the oxide 230b due to impurities such as silicon, a large amount of V_{O}H is formed; thus, the transistor is likely to be normally on. Hence, the low-crystallinity region of the oxide 230b is preferably reduced or removed.

In contrast, the oxide 230b preferably has a layered CAAC structure. In particular, the CAAC structure preferably reaches a lower edge portion of a drain in the oxide 230b. Here, in the transistor 200, the conductor 242a or the conductor 242b, and its vicinity function as a drain. In other words, the oxide 230b in the vicinity of the lower edge portion of the conductor 242a or the conductor 242b preferably has a CAAC structure. In this manner, the low-crystallinity region of the oxide 230b is removed and the CAAC structure is formed also in the edge portion of the drain, which significantly affects the drain breakdown voltage, so that a variation in electrical characteristics of the transistor 200 can be further suppressed. In addition, the reliability of the transistor 200 can be improved.

In order to remove impurities and the like attached to the surface of the oxide 230b in the above etching step, cleaning treatment is performed. Examples of the cleaning method include wet cleaning using a cleaning solution (also can be referred to as wet etching process), plasma treatment using plasma, and cleaning by heat treatment, and any of these cleanings may be performed in combination as appropriate. Note that the cleaning treatment sometimes makes the groove portion deeper.

The cleaning treatment may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution may be adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency greater than or equal to 200 kHz is preferable, and a frequency greater than or equal to 900 KHz is further preferable. Damage to the oxide 230b and the like can be reduced with this frequency.

The cleaning treatment may be performed a plurality of times, and the cleaning solution may be changed in every cleaning treatment. For example, the first cleaning treatment may use diluted hydrofluoric acid or diluted ammonia water and the second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like. Furthermore, the crystallinity of the oxide 230b can be increased by removing a region with low crystallinity.

After the etching or the cleaning treatment, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 230a and the oxide 230b to reduce oxygen vacancies. In addition, the crystallinity of the oxide 230b can be improved by the heat treatment. The heat treatment may be performed under reduced pressure. Alternatively, heat treatment may be performed in an oxygen atmosphere, and then heat treatment may be successively performed in a nitrogen atmosphere without exposure to the air.

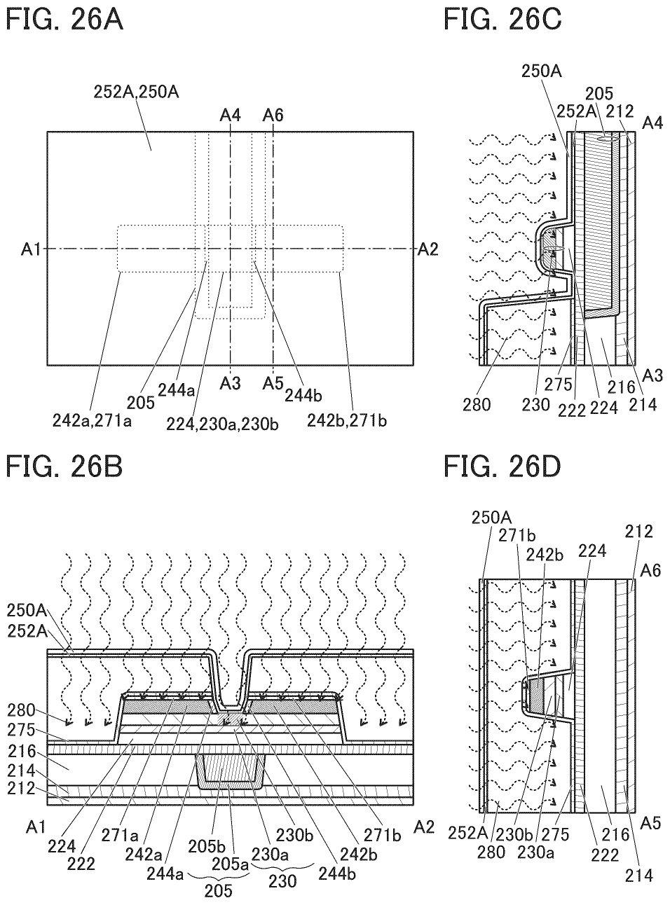

Next, an insulating film 252A is deposited (see FIG. 26A to FIG. 26D). The insulating film 252A can be deposited by a sputtering method, a CVD method, an MBE method, a PLD method, an ALD method, or the like. The insulating film 252A is preferably deposited by an ALD method. As described above, it is preferable to deposit the insulating film 252A to have a small thickness, and an unevenness of the thickness needs to be reduced. In contrast, an ALD method is a deposition method in which a precursor and a reactant (e.g., oxidizer) are alternately introduced, and the thickness can be adjusted with the number of repetition times of the cycle; thus, accurate control of the thickness is possible. Furthermore, as illustrated in FIG. 26B and FIG. 26C, the insulating film 252A needs to be deposited on the bottom surface and the side surface of the opening formed in the insulator 280 and the like so as to have good coverage. In particular, it is preferable that the insulating film 252A be deposited on the top surface and the side surface of the oxide 230 and the side surface of the conductor 242, with good coverage. An atomic layer can be deposited one by one on the bottom surface and the side surface of the opening, whereby the insulating film 252A can be deposited in the opening with good coverage.

When the insulating film 252A is deposited by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffused into the oxide 230b can be reduced.

In this embodiment, aluminum oxide is deposited as the insulating film 252A by a thermal ALD method.

Note that the lengths of the insulator 244a and the insulator 244b in the channel length direction are increased by the deposition of the insulating film 252A in some cases. Note that in the case where the insulator 244a and the insulator 244b are not formed before the deposition of the insulating film 252A, the side surface of the conductor 242a is oxidized during the deposition of the insulating film 252A to form the insulator 244a in some cases. Furthermore, the side surface of the conductor 242b is oxidized to form the insulator 244b in some cases.

Next, an insulating film 250A is deposited (see FIG. 26A to FIG. 26D). Heat treatment may be performed before the deposition of the insulating film 250A; the heat treatment may be performed under reduced pressure, and the insulating film 250A may be successively deposited without exposure to the air. The heat treatment is preferably performed in an oxygen-containing atmosphere. Such treatment can remove moisture and hydrogen adsorbed onto the surface of the insulating film 252A and the like, and further can reduce the moisture concentration and the hydrogen concentration in the oxide 230a and the oxide 230b. The heat treatment is preferably performed at a temperature higher than or equal to 100° C. and lower than or equal to 400° C.

The insulating film 250A can be deposited by a sputtering method, a CVD method, a PECVD method, an MBE method, a PLD method, an ALD method, or the like. The insulating film 250A is preferably deposited by a deposition method using a gas in which hydrogen atoms are reduced or removed. This can reduce the hydrogen concentration in the insulating film 250A. The hydrogen concentration is preferably reduced because the insulating film 250A becomes the insulator 250 that faces the oxide 230b with the insulator 252 with a small thickness therebetween, in a later step.

In this embodiment, silicon oxynitride is deposited for the insulating film 250A by a PECVD method.

Note that the lengths of the insulator 244a and the insulator 244b in the channel length direction are increased by the deposition of the insulating film 250A in some cases. Note that in the case where the insulator 244a and the insulator 244b are not formed before the deposition of the insulating film 250A, the side surface of the conductor 242a is oxidized during the deposition of the insulating film 250A to form the insulator 244a in some cases. Furthermore, the side surface of the conductor 242b is oxidized to form the insulator 244b in some cases.

Next, it is preferable to perform microwave treatment in an atmosphere containing oxygen. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz.

Dotted lines in FIG. 26B to FIG. 26D indicate high-frequency waves such as microwaves or RF, oxygen plasma, oxygen radicals, or the like. The microwave treatment is preferably performed with a microwave treatment apparatus including a power source for generating high-density plasma using microwaves, for example. Here, the frequency of the microwave treatment apparatus is set to greater than or equal to 300 MHz and less than or equal to 300 GHz, preferably greater than or equal to 2.4 GHz and less than or equal to 2.5 GHz, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. A power source may be provided to the microwave treatment apparatus to apply RF to the substrate side. Furthermore, application of RF to the substrate side allows oxygen ions generated by the high-density plasma to be introduced into the oxide 230b efficiently.

The microwave treatment is preferably performed under reduced pressure, and the pressure may be higher than or equal to 10 Pa and lower than or equal to 1000 Pa, preferably higher than or equal to 300 Pa and lower than or equal to 700 Pa. The treatment temperature may be lower than or equal to 750° C., preferably lower than or equal to 500° C., and is approximately 250° C., for example. The oxygen plasma treatment can be followed successively by heat treatment without exposure to the air. For example, the heat treatment may be performed at higher than or equal to 100° C. and lower than or equal to 750° C., preferably higher than or equal to 300° C. and lower than or equal to 500° C.

Furthermore, the microwave treatment is preferably performed using an oxygen gas and an argon gas, for example. Here, the oxygen flow rate ratio (O₂/(O₂+Ar)) is higher than 0% and lower than or equal to 100%, preferably higher than 0% and lower than or equal to 50%, further preferably higher than or equal to 10% and lower than or equal to 40%, or still further preferably higher than or equal to 10% and lower than or equal to 30%. The carrier concentration in the region 230bc can be reduced by thus performing the microwave treatment in an atmosphere containing oxygen. In addition, the carrier concentrations in the region 230ba and the region 230bb can be prevented from being excessively reduced by preventing an excess amount of oxygen from being introduced into the chamber in the microwave treatment.

As illustrated in FIG. 26B to FIG. 26D, the microwave treatment in an atmosphere containing oxygen can convert an oxygen gas into plasma using a high-frequency wave such as the microwave or RF, and apply the oxygen plasma to a region of the oxide 230b that is between the conductor 242a and the conductor 242b. At this time, the region 230bc can be irradiated with the high-frequency wave such as a microwave or RF. In other words, the high-frequency oxygen plasma such as a microwave or RF, or the like can be applied to the region 230bc illustrated in FIG. 8. By the effect of the plasma, the microwave, or the like, V_{O}H in the region 230bc can be divided into an oxygen vacancy (V_{O}) and hydrogen (H). That is, the reaction “V_{O}H→H+V_{O}” occurs in the region 230bc, so that V_{O}H contained in the region 230bc can be reduced. In addition, oxygen radicals generated by the oxygen plasma or oxygen contained in the insulator 250 can be supplied to oxygen vacancies in the region 230bc, thereby further reducing oxygen vacancies and lowering the carrier concentration in the region 230bc. That is, the reaction “V_{O}+O→null” can be promoted. In addition, hydrogen in the region 230bc is drifted (diffused) into distortion formed in the region 230ba and the region 230bb by the effect of compressive stress of the conductor 242a and the conductor 242b. Thus, the hydrogen concentration in the region 230bc can be reduced. As a result, V_{O}H, oxygen vacancies, and hydrogen concentration in the region 230bc can be reduced to lower the carrier concentration. In this manner, the region 230bc can be an i-type or substantially i-type region.

The conductor 242a and the conductor 242b are respectively provided over the region 230ba and the region 230bb illustrated in FIG. 8. Here, the conductor 242 preferably functions as a blocking film preventing the effect caused by the high-frequency wave such as the microwave or RF, the oxygen plasma, or the like in the microwave treatment in an atmosphere containing oxygen. Therefore, the conductor 242 preferably has a function of blocking an electromagnetic wave greater than or equal to 300 MHz and less than or equal to 300 GHz, for example, greater than or equal to 2.4 GHz and less than or equal to 2.5 GHz.

As illustrated in FIG. 26B to FIG. 26D, in the microwave treatment in an oxygen-containing atmosphere, the high-frequency wave such as the microwave or RF, the oxygen plasma, or the like is blocked by the conductor 242a and the conductor 242b and does not affect the region 230ba nor the region 230bb. In addition, the effect can be reduced by the insulator 271 and the insulator 280 that are provided to cover the oxide 230b and the conductor 242. In the region 230ba and the region 230bb, hydrogen and oxygen vacancies diffused from the region 230bc react with each other to form V_{O}H. Hence, a reduction in V_{O}H and supply of an excess amount of oxygen do not occur in the region 230ba or the region 230bb in the microwave treatment, preventing a decrease in carrier concentration. In this manner, the region 230ba and the region 230bb can each be an n-type region.

The effect of the high-frequency wave such as a microwave or RF, the oxygen plasma, or the like is reduced but not blocked by the insulator 244a and the insulator 244b as much as by the conductor 242a and the conductor 242b. Accordingly, the effects on the region 230bd and the region 230be are weaker than those on the region 230bc and stronger than those on the region 230ba and the region 230bb. Thus, the carrier concentrations of the region 230bd and the region 230be due to the microwave treatment are lower than those of the region 230ba and the region 230bb and are not as low as that of the region 230bc.

Furthermore, the insulator 252 having a barrier property against oxygen is provided in contact with the side surfaces of the conductor 242a and the conductor 242b. Thus, supply of excess oxygen to the side surfaces of the conductor 242a and the conductor 242b by the microwave treatment can be inhibited.

The insulator 275 having a barrier property against oxygen is provided above the conductor 242a and the conductor 242b and in contact with the side surface of the conductor 242a and the side surface of the conductor 242b. Thus, oxidation of the top surfaces and the side surfaces of the conductor 242a and the conductor 242b by the microwave treatment can be inhibited. As illustrated in FIG. 26D, the insulator 275 is in contact with the side surface of the oxide 230b in a region overlapping with the conductor 242a or the conductor 242b. Thus, the insulator 275 can inhibit supply of an excess amount of oxygen to the side surface of the oxide 230b in the region, preventing a decrease in carrier concentration.

Microwave treatment is preferably performed in an oxygen-containing atmosphere after deposition of the insulating film 252A or after deposition of the insulating film 250A. By performing the microwave treatment in an oxygen-containing atmosphere through the insulating film 252A or the insulating film 250A in such a manner, oxygen can be efficiently implanted into the region 230bc. In addition, the insulating film 252A is placed to be in contact with the surface of the region 230bc, thereby inhibiting oxygen more than necessary from being implanted into the region 230bc. Furthermore, the insulating film 252A is placed in the vicinity of the side surface of the conductor 242, thereby inhibiting excessive oxidation of the side surface of the conductor 242.

The oxygen implanted into the region 230bc has any of a variety of forms such as an oxygen atom, an oxygen molecule, and an oxygen radical (an O radical, an atom or a molecule having an unpaired electron, or an ion). Note that the oxygen implanted into the region 230bc has any one or more of the above forms, particularly preferably an oxygen radical.

Furthermore, the film quality of the insulator 252 and the insulator 250 can be improved, leading to higher reliability of the transistor 200.

In the above manner, oxygen vacancies and V_{O}H can be selectively removed from the region 230bc of the oxide semiconductor, whereby the region 230bc can be an i-type or substantially i-type region. Furthermore, supply of an excess amount of oxygen to the region 230ba and the region 230bb functioning as the source region and the drain region can be inhibited and the state of the n-type regions before the microwave treatment is performed can be maintained. Furthermore, the region 230bd and the region 230be can function as junction regions or offset regions. As a result, a change in the electrical characteristics of the transistor 200 can be inhibited, and thus a variation in the electrical characteristics of the transistors 200 in the substrate plane can be inhibited.

The microwave treatment is a significantly effective method for making the region 230bc an i-type or substantially i-type region and making the region 230ba and the region 230bb n-type regions. With the microwave treatment, the transistor 200 can be manufactured to be minute with a gate length of 6 nm or even 3 nm.

In the microwave treatment, a thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an atmosphere containing oxygen, an effect equivalent to that of oxygen annealing is sometimes obtained. That is, oxygen vacancies can be repaired (nullified) by the microwave annealing. In the case where hydrogen is contained in the oxide 230b, it is probable that the thermal energy is transmitted to the hydrogen in the oxide 230b and the hydrogen activated by the energy is released from the oxide 230b.

Note that the lengths of the insulator 244a and the insulator 244b in the channel length direction are increased by the microwave treatment in some cases. Note that in the case where the insulator 244a and the insulator 244b are not formed before the microwave treatment, the side surface of the conductor 242a is oxidized during the microwave treatment to form the insulator 244a in some cases. Furthermore, the side surface of the conductor 242b is oxidized to form the insulator 244b in some cases.

Appropriate adjustment of the deposition condition of the insulating film 250A, the microwave treatment condition in an oxygen-containing atmosphere, the amount of oxygen added to the insulator 280 by deposition of the insulator 282, and the like can reduce oxygen vacancies and V_{O}H in the region 230bc and inhibit supply of excess oxygen to the region 230ba and the region 230bb in some cases. In such a case, the insulator 252 is not necessarily provided. This enables simplification of the manufacturing process and the improvement in productivity of the semiconductor device.

The microwave treatment may be performed after the insulating film 252A is deposited. Alternatively, microwave treatment may be performed after the deposition of the insulating film 252A, without the microwave treatment performed after the deposition of the insulating film 250A.

In the case where the insulator 250 has a two-layer structure as illustrated in FIG. 13A, an insulating film to be the insulator 250b may be deposited after the deposition of the above insulating film 250A. The insulating film to be the insulator 250b can be deposited by a sputtering method, a CVD method, an MBE method, a PLD method, an ALD method, or the like. The insulating film to be the insulator 250b is preferably formed using an insulator having a function of inhibiting diffusion of oxygen. With such a structure, oxygen contained in the insulator 250a can be inhibited from being diffused into the conductor 260. That is, a reduction in the amount of oxygen supplied to the oxide 230 can be inhibited. In addition, oxidation of the conductor 260 due to oxygen contained in the insulator 250a can be inhibited. The insulating film to be the insulator 250b can be provided using a material similar to that for the insulator 222. For example, hafnium oxide may be deposited by a thermal ALD method for the insulating film to be the insulator 250b.

Note that in the case where the insulator 250 has a two-layer structure illustrated in FIG. 13A, the microwave treatment is preferably performed after the deposition of the insulating film 250A. Alternatively, microwave treatment may be performed after the deposition of the insulating film to be the insulator 250b, without microwave treatment performed after the deposition of the insulating film 250A.

Heat treatment may be performed while the reduced pressure is maintained after the microwave treatment. Such treatment enables hydrogen in the oxide 230b and the oxide 230a to be removed efficiently. In addition, hydrogen in the insulating film deposited before the microwave treatment among the insulating film 252A, the insulating film 250A, and the insulating film to be the insulator 250b can be removed efficiently. Part of hydrogen is gettered by the conductor 242a and the conductor 242b in some cases. Alternatively, the step of performing microwave treatment and then performing heat treatment with the reduced pressure being maintained may be repeated a plurality of cycles. The repetition of the heat treatment enables hydrogen in the oxide 230b and the oxide 230a to be removed more efficiently. In addition, hydrogen in the insulating film deposited before the microwave treatment among the insulating film 252A, the insulating film 250A, and the insulating film to be the insulator 250b can be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

Furthermore, the microwave treatment improves the film quality of any one or more of the insulating film 252A, the insulating film 250A, and the insulating film to be the insulator 250b, thereby inhibiting diffusion of hydrogen, water, impurities, and the like. Accordingly, hydrogen, water, impurities, and the like can be inhibited from being diffused into the oxide 230b, the oxide 230a, and the like through the insulator 252 in a later step such as deposition of a conductive film to be the conductor 260 or later treatment such as heat treatment.

Note that through the foregoing steps, the insulator 244a is formed on the side surface of the conductor 242a, and the insulator 244b is formed on the side surface of the conductor 242b. In other words, the insulator 244a and the insulator 244b are formed in any one of the step of processing part of the insulator 280 and the like to form the opening reaching the oxide 230b, the step of depositing the insulating film 252A, the step of depositing the insulating film 250A, and the step of performing the microwave treatment. That is, the insulator 244a and the insulator 244b are formed in a self-aligned manner in the manufacturing process of the semiconductor device.

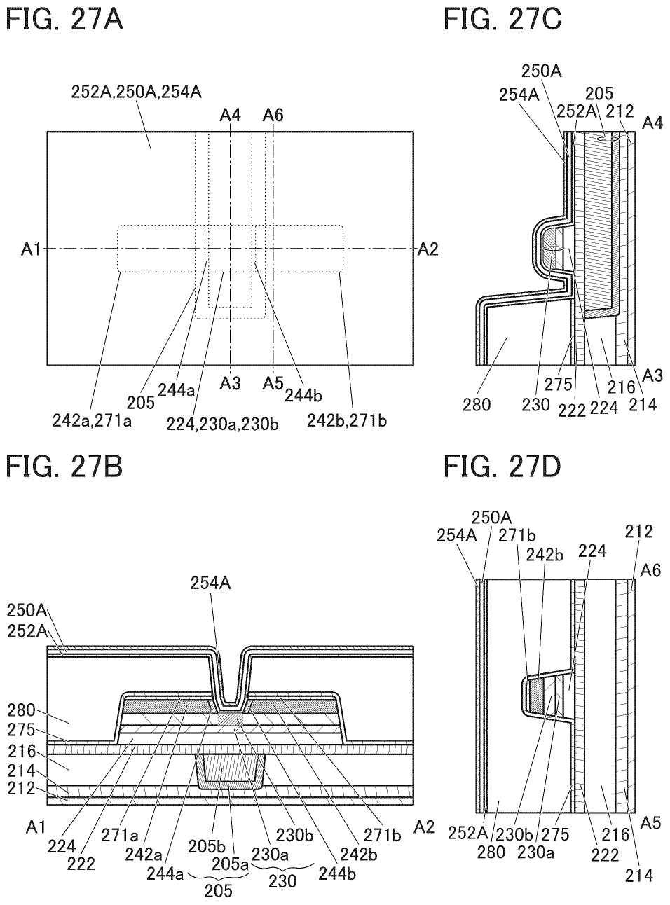

Next, an insulating film 254A is deposited (see FIG. 27A to FIG. 27D). The insulating film 254A can be deposited by a sputtering method, a CVD method, an MBE method, a PLD method, an ALD method, or the like. Like the insulating film 252A, the insulating film 254A is preferably deposited by an ALD method. By an ALD method, the insulating film 254A can be deposited to have a small thickness and good coverage. In this embodiment, for the insulating film 254A, a silicon nitride film is deposited by a PEALD method.

Next, a conductive film to be the conductor 260a and a conductive film to be the conductor 260b are deposited in this order. The conductive film to be the conductor 260a and the conductive film to be the conductor 260b can be deposited by a sputtering method, a CVD method, an MBE method, a PLD method, an ALD method, or the like. In this embodiment, a titanium nitride film is deposited as the conductive film to be the conductor 260a by an ALD method, and a tungsten film is deposited for the conductive film to be the conductor 260b by a CVD method.

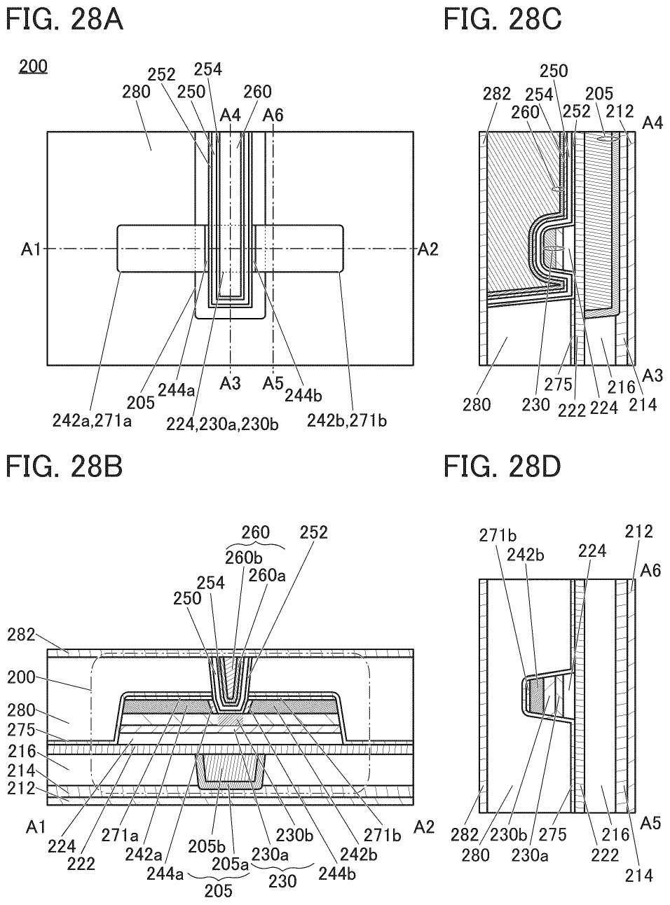

Then, the insulating film 252A, the insulating film 250A, the insulating film 254A, the conductive film to be the conductor 260a, and the conductive film to be the conductor 260b are polished by CMP treatment until the insulator 280 is exposed, whereby the insulator 252, the insulator 250, the insulator 254, and the conductor 260 (the conductor 260a and the conductor 260b) are formed (see FIG. 28A to FIG. 28D). Accordingly, the insulator 252 is placed to cover the opening reaching the oxide 230b. The conductor 260 is placed to fill the opening with the insulator 252, the insulator 250, and the insulator 254 therebetween.

Then, heat treatment may be performed under conditions similar to those for the above heat treatment. In this embodiment, treatment is performed at 400° C. in a nitrogen atmosphere for one hour. The heat treatment can reduce the moisture concentration and the hydrogen concentration in the insulator 250 and the insulator 280. After the heat treatment, the insulator 282 may be deposited successively without exposure to the air.

Next, the insulator 282 is formed over the insulator 252, the insulator 250, the insulator 254, the conductor 260, and the insulator 280 (see FIG. 28A to FIG. 28D). The insulator 282 can be deposited by a sputtering method, a CVD method, an MBE method, a PLD method, an ALD method, or the like. The insulator 282 is preferably deposited by a sputtering method. Since a molecule containing hydrogen is not needed to be used for a deposition gas in the sputtering method, the hydrogen concentration in the insulator 282 can be reduced.

In this embodiment, for the insulator 282, aluminum oxide is deposited by a pulsed DC sputtering method using an aluminum target in an atmosphere containing an oxygen gas. The RF power applied to the substrate is lower than or equal to 1.86 W/cm². The RF power is preferably higher than or equal to 0 W/cm² and lower than or equal to 0.62 W/cm². With low RF power, the amount of oxygen implanted into the insulator 280 can be reduced. The insulator 282 may have a two-layer structure. In this case, the lower layer of the insulator 282 is deposited with RF power applied to the substrate of 0 W/cm², and the upper layer of the insulator 282 is deposited with RF power applied to the substrate of 0.62 W/cm².

The insulator 282 is deposited by a sputtering method in an oxygen-containing atmosphere, whereby oxygen can be added to the insulator 280 during the deposition. Thus, excess oxygen can be contained in the insulator 280. At this time, the insulator 282 is preferably deposited while the substrate is being heated.

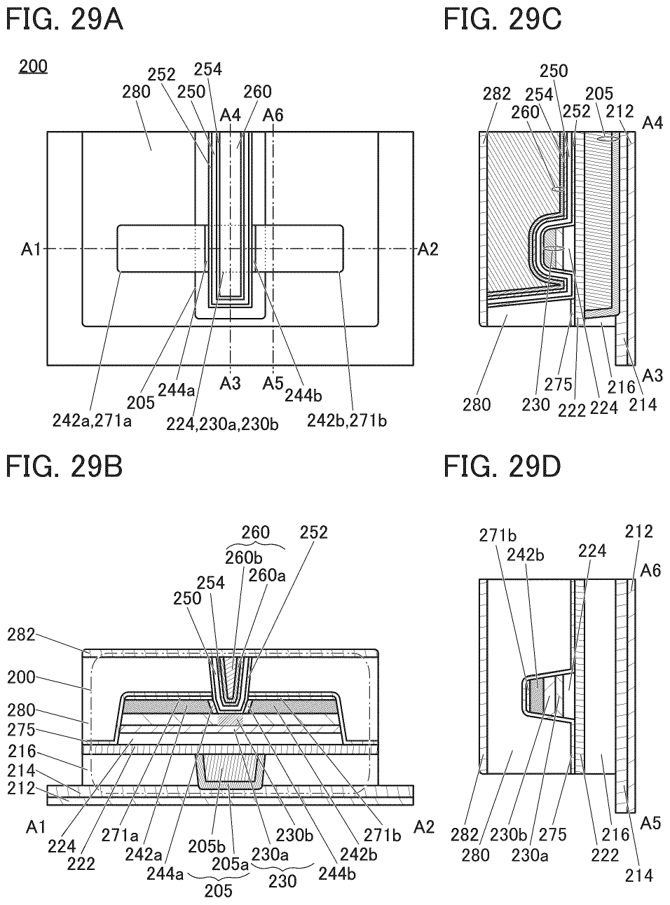

Next, an etching mask is formed over the insulator 282 by a lithography method and part of the insulator 282, part of the insulator 280, part of the insulator 275, part of the insulator 222, and part of the insulator 216 are processed until the top surface of the insulator 214 is exposed (see FIG. 29A to FIG. 29D). Wet etching can be used for the processing; however, dry etching is preferably used for microfabrication.

Next, heat treatment may be performed. The heat treatment is performed at higher than or equal to 250° C. and lower than or equal to 650° C., preferably higher than or equal to 350° C. and lower than or equal to 600° C. The heat treatment is preferably performed at a temperature lower than that of the heat treatment performed after the deposition of the oxide film 230B. Note that the heat treatment is performed in an atmosphere of a nitrogen gas or an inert gas. By the heat treatment, part of oxygen added to the insulator 280 is diffused into the oxide 230 through the insulator 250 and the like.

By the heat treatment, oxygen contained in the insulator 280 and hydrogen bonded to the oxygen can be released to the outside from the side surface of the insulator 280 formed by the processing. Note that the hydrogen bonded to oxygen is released as water. Thus, excess oxygen and hydrogen contained in the insulator 280 can be reduced.

In a region of the oxide 230 that overlaps with the conductor 260, the insulator 252 is provided to be in contact with the top surface and the side surface of the oxide 230. Since the insulator 252 has a barrier property against oxygen, diffusion of an excess amount of oxygen to the oxide 230 can be inhibited. Thus, oxygen can be supplied to the region 230bc and the vicinity thereof, without supply of an excess amount of oxygen. Accordingly, oxygen vacancies and V_{O}H in the region 230bc can be reduced while supply of excess oxygen to the region 230ba and the region 230bb can be inhibited. Thus, the transistor 200 can have favorable electrical characteristics and higher reliability.

On the other hand, in the case where the transistors 200 are integrated at a high density, the volume of the insulator 280 per transistor 200 becomes excessively small in some cases. In this case, the amount of oxygen diffused into the oxide 230 in the heat treatment becomes significantly small. When the oxide 230 is heated while being in contact with the oxide insulator (e.g., the insulator 250) which does not contain sufficient oxygen, oxygen contained in the oxide 230 might be released. However, in the transistor 200 described in this embodiment, the insulator 252 is provided in contact with the top surface and the side surface of the oxide 230 in the region of the oxide 230 that overlaps with the conductor 260. Since the insulator 252 has a barrier property against oxygen, release of the oxygen from the oxide 230 can be reduced also in the heat treatment. Therefore, formation of oxygen vacancies and V_{O}H in the region 230bc can be inhibited. Thus, the transistor 200 can have favorable electrical characteristics and higher reliability.

As described above, in either case of a large or small amount of oxygen supplied from the insulator 280 in the semiconductor device of this embodiment, a transistor having favorable electrical characteristics and high reliability can be formed. Thus, a semiconductor device with a reduced variation in electrical characteristics of the transistors 200 in the substrate plane can be provided.

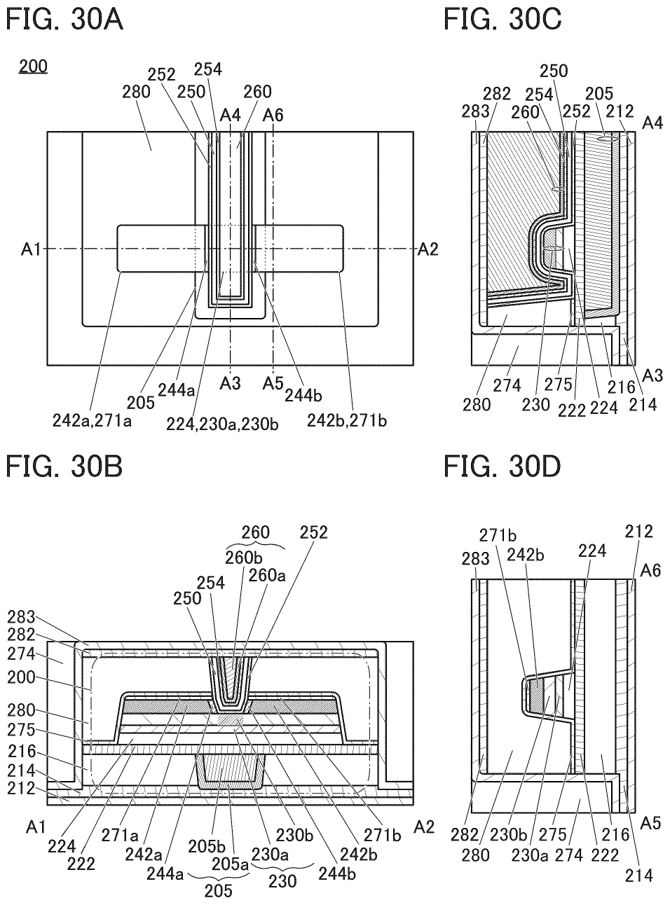

Next, the insulator 283 is formed over the insulator 282 (see FIG. 30A to FIG. 30D). The insulator 283 can be deposited by a sputtering method, a CVD method, an MBE method, a PLD method, an ALD method, or the like. The insulator 283 is preferably deposited by a sputtering method. Since a molecule containing hydrogen is not needed to be used for a deposition gas in the sputtering method, the hydrogen concentration in the insulator 283 can be reduced. The insulator 283 may be a multilayer. For example, silicon nitride may be deposited by a sputtering method and silicon nitride may be deposited over the silicon nitride by an ALD method. Surrounding the transistor 200 by the insulator 283 and the insulator 214 that have a high barrier property can prevent entry of moisture and hydrogen from the outside.

Next, an insulating film to be the insulator 274 is formed over the insulator 283. The insulating film can be deposited by a sputtering method, a CVD method, an MBE method, a PLD method, an ALD method, or the like. In this embodiment, as the insulator film, a silicon oxide film is deposited by a CVD method.

Next, the insulating film to be the insulator 274 is polished by CMP treatment until the insulator 283 is exposed, whereby the top surface of the insulating film is planarized; thus, the insulator 274 is formed (see FIG. 30A to FIG. 30D). The top surface of the insulator 283 is partly removed by the CMP treatment in some cases.

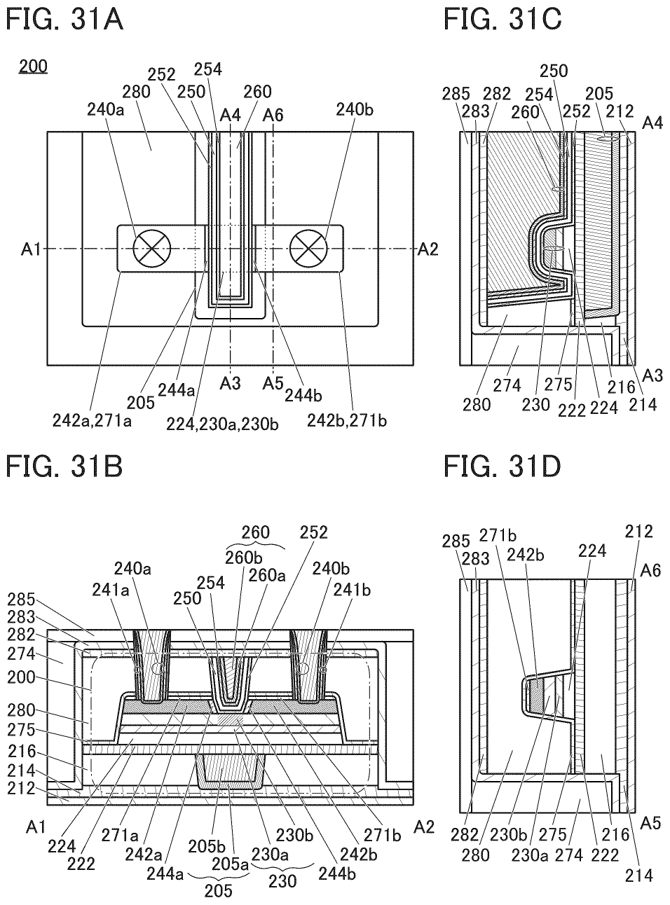

Next, the insulator 285 is formed over the insulator 274 and the insulator 283 (see FIG. 31A to FIG. 31D). The insulator 285 can be deposited by a sputtering method, a CVD method, an MBE method, a PLD method, an ALD method, or the like. The insulator 285 is preferably deposited by a sputtering method. Since a molecule containing hydrogen is not needed to be used for a deposition gas in the sputtering method, the hydrogen concentration in the insulator 285 can be reduced.

In this embodiment, for the insulator 285, silicon oxide is deposited by a sputtering method.

Subsequently, openings reaching the conductor 242 are formed in the insulator 271, the insulator 275, the insulator 280, the insulator 282, the insulator 283, and the insulator 285 (see FIG. 31A and FIG. 31B). The openings can be formed by a lithography method. Note that the openings in the top view in FIG. 31A have a circular shape; however, the shapes of the openings are not limited thereto. For example, the openings in the top view may have an almost circular shape such as an elliptical shape, a polygonal shape such as a tetragonal shape, or a polygonal shape such as a tetragonal shape with rounded corners.

Next, an insulating film to be the insulator 241a and the insulator 241b is deposited and the insulating film is subjected to anisotropic etching, so that the insulator 241a and the insulator 241b are formed (see FIG. 31B). The insulating film can be deposited by a sputtering method, a CVD method, an MBE method, a PLD method, an ALD method, or the like. As the insulating film, an insulating film having a function of inhibiting passage of oxygen is preferably used. For example, preferably, an aluminum oxide film is deposited by an ALD method and a silicon nitride film is deposited thereover by a PEALD method. Silicon nitride is preferable because it has a high blocking property against hydrogen.

As an anisotropic etching for the insulating film to be the insulator 241a and the insulator 241b, a dry etching method may be performed, for example. Providing the insulator 241a and the insulator 241b on the side wall portions of the openings can inhibit passage of oxygen from the outside and can prevent oxidation of the conductor 240a and the conductor 240b to be formed next. Furthermore, impurities such as water and hydrogen contained in the insulator 280 or the like can be prevented from being diffused into the conductor 240a and the conductor 240b.

Next, a conductive film to be the conductor 240a and the conductor 240b is deposited. The conductive film desirably has a stacked-layer structure which includes a conductor having a function of inhibiting passage of impurities such as water and hydrogen. For example, a stacked layer of tantalum nitride, titanium nitride, or the like and tungsten, molybdenum, copper, or the like can be employed. The conductive film can be deposited by a sputtering method, a CVD method, an MBE method, a PLD method, an ALD method, or the like.

Then, part of the conductive film to be the conductor 240a and the conductor 240b is removed by CMP treatment to expose the top surface of the insulator 285. As a result, the conductive film remains only in the openings, so that the conductor 240a and the conductor 240b having flat top surfaces can be formed (see FIG. 31A to FIG. 31D). Note that part of the top surface of the insulator 285 is sometimes removed by the CMP treatment.

Next, a conductive film to be the conductor 246a and the conductor 246b is deposited. The conductive film can be deposited by a sputtering method, a CVD method, an MBE method, a PLD method, an ALD method, or the like.

Next, the conductive film to be the conductor 246a and the conductor 246b is processed by a lithography method to form the conductor 246a in contact with the top surface of the conductor 240a and the conductor 246b in contact with the top surface of the conductor 240b. At this time, part of the insulator 285 in a region where the insulator 285 does not overlap with the conductor 246a or the conductor 246b is sometimes removed.

Through the above process, the semiconductor device including the transistor 200 illustrated in FIG. 6A to FIG. 6D can be manufactured. As illustrated in FIG. 21A to FIG. 31D, the transistor 200 can be manufactured in accordance with the method for manufacturing the semiconductor device described in this embodiment.

### <Microwave Treatment Apparatus>

A microwave treatment apparatus that can be used for the above method for manufacturing the semiconductor device is described below.

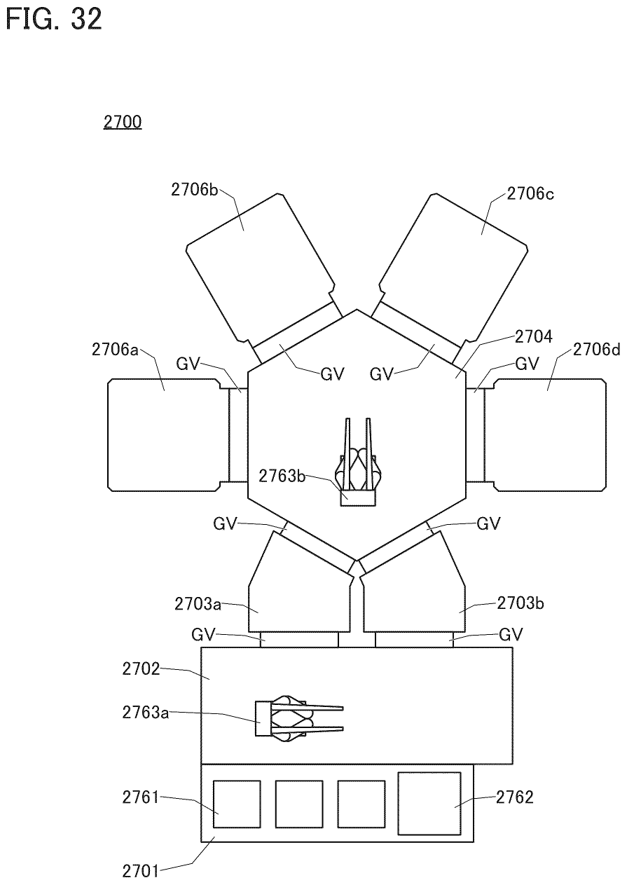

First, a structure of a manufacturing apparatus that hardly allows entry of impurities in manufacturing a semiconductor device or the like is described with reference to FIG. 32 to FIG. 35.

FIG. 32 schematically illustrates a top view of a single wafer multi-chamber manufacturing apparatus 2700. The manufacturing apparatus 2700 includes an atmosphere-side substrate supply chamber 2701 including a cassette port 2761 for storing a substrate and an alignment port 2762 for performing alignment of a substrate; an atmosphere-side substrate transfer chamber 2702 for transferring a substrate from the atmosphere-side substrate supply chamber 2701; a load lock chamber 2703a for carrying in a substrate and switching the pressure inside the chamber from atmospheric pressure to reduced pressure or from reduced pressure to atmospheric pressure; an unload lock chamber 2703b for carrying out a substrate and switching the pressure inside the chamber from reduced pressure to atmospheric pressure or from atmospheric pressure to reduced pressure; a transfer chamber 2704 for transferring a substrate in a vacuum; a chamber 2706a; a chamber 2706b; a chamber 2706c; and a chamber 2706d.

Furthermore, the atmosphere-side substrate transfer chamber 2702 is connected to the load lock chamber 2703a and the unload lock chamber 2703b, the load lock chamber 2703a and the unload lock chamber 2703b are connected to the transfer chamber 2704, and the transfer chamber 2704 is connected to the chamber 2706a, the chamber 2706b, the chamber 2706c, and the chamber 2706d.

Note that gate valves GV are provided in connecting portions between the chambers so that the chambers other than the atmosphere-side substrate supply chamber 2701 and the atmosphere-side substrate transfer chamber 2702 can be each independently kept in a vacuum state. Furthermore, the atmosphere-side substrate transfer chamber 2702 is provided with a transfer robot 2763a, and the transfer chamber 2704 is provided with a transfer robot 2763b. With the transfer robot 2763a and the transfer robot 2763b, a substrate can be transferred inside the manufacturing apparatus 2700.

The back pressure (total pressure) in the transfer chamber 2704 and each of the chambers is, for example, lower than or equal to 1×10⁻⁴ Pa, preferably lower than or equal to 3×10⁻⁵ Pa, further preferably lower than or equal to 1×10⁻⁵ Pa. Furthermore, the partial pressure of a gas molecule (atom) having a mass-to-charge ratio (m/z) of 18 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 28 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 44 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa.

Note that the total pressure and the partial pressure in the transfer chamber 2704 and each of the chambers can be measured using an ionization vacuum gauge, a mass analyzer, or the like. Furthermore, the transfer chamber 2704 and the chambers each desirably have a structure in which the amount of external leakage or internal leakage is small. For example, the leakage rate in the transfer chamber 2704 is less than or equal to 1×10⁰ Pa/min, preferably less than or equal to 5×10⁻¹ Pa/min. Furthermore, the leakage rate in each chamber is less than or equal to 1×10⁻¹ Pa/min, preferably less than or equal to 5×10⁻² Pa/min.

Note that a leakage rate can be derived from the total pressure and partial pressure measured using the ionization vacuum gauge, the mass analyzer, or the like. For example, the leakage rate is preferably derived from the total pressure at the time when 10 minutes have passed from the start of evacuation to a vacuum using a vacuum pump such as a turbo molecular pump and the total pressure at the time when 10 minutes have passed from the operation of closing the valve. Note that the total pressure at the time when 10 minutes have passed from the start of evacuation to a vacuum is preferably an average value of the total pressures measured a plurality of times.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or released gas from an internal member. Measures need to be taken from both aspects of external leakage and internal leakage in order that the leakage rate can be set to less than or equal to the above-described value.

For example, open/close portions of the transfer chamber 2704 and each of the chambers are preferably sealed with a metal gasket. For the metal gasket, metal covered with iron fluoride, aluminum oxide, or chromium oxide is preferably used. The metal gasket achieves higher adhesion than an O-ring and can reduce the external leakage. Furthermore, with the use of passive metal covered with iron fluoride, aluminum oxide, chromium oxide, or the like, the release of gas containing impurities released from the metal gasket is inhibited, so that the internal leakage can be reduced.

Furthermore, for a member of the manufacturing apparatus 2700, aluminum, chromium, titanium, zirconium, nickel, or vanadium, which releases a small amount of gas containing impurities, is used. Furthermore, an alloy containing any of iron, chromium, nickel, and the like covered with the above-described metal, which releases a small amount of gas containing impurities, may be used. The alloy containing any of iron, chromium, nickel, and the like is rigid, resistant to heat, and suitable for processing. Here, when surface unevenness of the member is reduced by polishing or the like to reduce the surface area, the release of gas can be reduced.

Alternatively, the above-described member of the manufacturing apparatus 2700 may be covered with iron fluoride, aluminum oxide, chromium oxide, or the like.

The member of the manufacturing apparatus 2700 is preferably formed using only metal when possible, and in the case where a viewing window formed of quartz or the like is provided, for example, the surface is preferably thinly covered with iron fluoride, aluminum oxide, chromium oxide, or the like to inhibit release of gas.

An adsorbed substance present in the transfer chamber 2704 and each of the chambers does not affect the pressure in the transfer chamber 2704 and each of the chambers because it is adsorbed onto an inner wall or the like; however, it causes a release of gas when the transfer chamber 2704 and each of the chambers are evacuated. Thus, although there is no correlation between the leakage rate and the exhaust rate, it is important that the adsorbed substance present in the transfer chamber 2704 and each of the chambers be desorbed as much as possible and exhaust be performed in advance with the use of a pump having high exhaust capability. Note that the transfer chamber 2704 and each of the chambers may be subjected to baking to promote desorption of the adsorbed substance. By the baking, the desorption rate of the adsorbed substance can be increased about tenfold. The baking is performed at higher than or equal to 100° C. and lower than or equal to 450° C. At this time, when the adsorbed substance is removed while an inert gas is introduced into the transfer chamber 2704 and each of the chambers, the desorption rate of water or the like, which is difficult to desorb simply by exhaust, can be further increased. Note that when the inert gas to be introduced is heated to substantially the same temperature as the baking temperature, the desorption rate of the adsorbed substance can be further increased. Here, a rare gas is preferably used as the inert gas.

Alternatively, treatment for evacuating the transfer chamber 2704 and each of the chambers is preferably performed a certain period of time after a heated inert gas such as a rare gas, heated oxygen, or the like is introduced to increase the pressure in the transfer chamber 2704 and each of the chambers. The introduction of the heated gas can desorb the adsorbed substance in the transfer chamber 2704 and each of the chambers, and impurities present in the transfer chamber 2704 and each of the chambers can be reduced. Note that this treatment is effective when repeated more than or equal to 2 times and less than or equal to 30 times, preferably more than or equal to 5 times and less than or equal to 15 times. Specifically, an inert gas, oxygen, or the like at a temperature higher than or equal to 40° C. and lower than or equal to 400° C., preferably higher than or equal to 50° C. and lower than or equal to 200° C. is introduced, so that the pressure in the transfer chamber 2704 and each of the chambers can be kept to be higher than or equal to 0.1 Pa and lower than or equal to 10 kPa, preferably higher than or equal to 1 Pa and lower than or equal to 1 kPa, further preferably higher than or equal to 5 Pa and lower than or equal to 100 Pa in the time range of 1 minute to 300 minutes, preferably 5 minutes to 120 minutes. After that, the transfer chamber 2704 and each of the chambers are evacuated in the time range of 5 minutes to 300 minutes, preferably 10 minutes to 120 minutes.

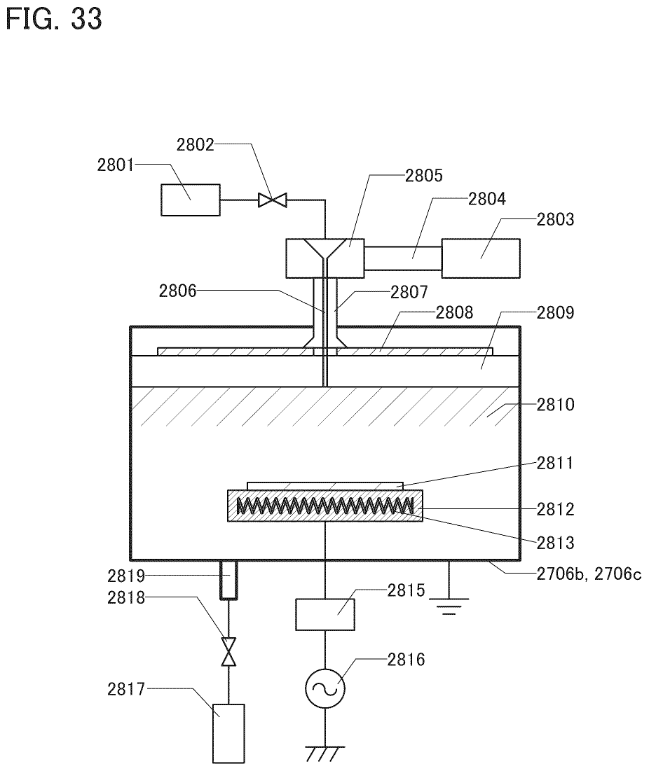

Next, the chamber 2706b and the chamber 2706c are described with reference to a schematic cross-sectional view illustrated in FIG. 33.

The chamber 2706b and the chamber 2706c are chambers in which microwave treatment can be performed on an object, for example. Note that the chamber 2706b is different from the chamber 2706c only in the atmosphere in performing the microwave treatment. The other structures are common and thus collectively described below.

The chamber 2706b and the chamber 2706c each include a slot antenna plate 2808, a dielectric plate 2809, a substrate holder 2812, and an exhaust port 2819. Furthermore, a gas supply source 2801, a valve 2802, a high-frequency generator 2803, a waveguide 2804, a mode converter 2805, a gas pipe 2806, a waveguide 2807, a matching box 2815, a high-frequency power source 2816, a vacuum pump 2817, and a valve 2818 are provided outside the chamber 2706b and the chamber 2706c, for example.

The high-frequency generator 2803 is connected to the mode converter 2805 through the waveguide 2804. The mode converter 2805 is connected to the slot antenna plate 2808 through the waveguide 2807. The slot antenna plate 2808 is placed in contact with the dielectric plate 2809. Furthermore, the gas supply source 2801 is connected to the mode converter 2805 through the valve 2802. Then, gas is transferred to the chamber 2706b and the chamber 2706c through the gas pipe 2806 that runs through the mode converter 2805, the waveguide 2807, and the dielectric plate 2809. Furthermore, the vacuum pump 2817 has a function of exhausting gas or the like from the chamber 2706b and the chamber 2706c through the valve 2818 and the exhaust port 2819. Furthermore, the high-frequency power source 2816 is connected to the substrate holder 2812 through the matching box 2815.

The substrate holder 2812 has a function of holding a substrate 2811. For example, the substrate holder 2812 has a function of an electrostatic chuck or a mechanical chuck for holding the substrate 2811. Furthermore, the substrate holder 2812 has a function of an electrode to which electric power is supplied from the high-frequency power source 2816. Furthermore, the substrate holder 2812 includes a heating mechanism 2813 therein and has a function of heating the substrate 2811.

As the vacuum pump 2817, a dry pump, a mechanical booster pump, an ion pump, a titanium sublimation pump, a cryopump, or a turbomolecular pump can be used, for example. Furthermore, in addition to the vacuum pump 2817, a cryotrap may be used. The use of the cryopump and the cryotrap is particularly preferable because water can be efficiently exhausted.

Furthermore, for example, the heating mechanism 2813 may be a heating mechanism that uses a resistance heater or the like for heating. Alternatively, a heating mechanism that uses heat conduction or heat radiation from a medium such as a heated gas for heating may be used. For example, RTA (Rapid Thermal Annealing) such as GRTA (Gas Rapid Thermal Annealing) or LRTA (Lamp Rapid Thermal Annealing) can be used. In GRTA, heat treatment is performed using a high-temperature gas. An inert gas is used as the gas.

Furthermore, the gas supply source 2801 may be connected to a purifier through a mass flow controller. As the gas, a gas whose dew point is −80° C. or lower, preferably −100° C. or lower is preferably used. For example, an oxygen gas, a nitrogen gas, or a rare gas (an argon gas or the like) is used.

As the dielectric plate 2809, silicon oxide (quartz), aluminum oxide (alumina), or yttrium oxide (yttria) is used, for example. Furthermore, another protective layer may be further formed on a surface of the dielectric plate 2809. For the protective layer, magnesium oxide, titanium oxide, chromium oxide, zirconium oxide, hafnium oxide, tantalum oxide, silicon oxide, aluminum oxide, yttrium oxide, or the like is used. The dielectric plate 2809 is exposed to an especially high density region of high-density plasma 2810 described later; thus, provision of the protective layer can reduce the damage. Consequently, an increase in the number of particles or the like during the treatment can be suppressed.

The high-frequency generator 2803 has a function of generating a microwave at, for example, greater than or equal to 0.3 GHz and less than or equal to 3.0 GHz, greater than or equal to 0.7 GHz and less than or equal to 1.1 GHz, or greater than or equal to 2.2 GHz and less than or equal to 2.8 GHz. The microwave generated by the high-frequency generator 2803 is propagated to the mode converter 2805 through the waveguide 2804. The mode converter 2805 converts the microwave propagated in the TE mode into a microwave in the TEM mode. Then, the microwave is propagated to the slot antenna plate 2808 through the waveguide 2807. The slot antenna plate 2808 is provided with a plurality of slot holes, and the microwave passes through the slot holes and the dielectric plate 2809. Then, an electric field is generated below the dielectric plate 2809, and the high-density plasma 2810 can be generated. In the high-density plasma 2810, ions and radicals based on the gas species supplied from the gas supply source 2801 are present. For example, oxygen radicals are present.

At this time, the quality of a film or the like over the substrate 2811 can be modified by the ions and radicals generated in the high-density plasma 2810. Note that it is preferable in some cases to apply a bias to the substrate 2811 side using the high-frequency power source 2816. As the high-frequency power source 2816, an RF (Radio Frequency) power source with a frequency of 13.56 MHz, 27.12 MHz, or the like is used, for example. The application of a bias to the substrate side allows ions in the high-density plasma 2810 to efficiently reach a deep portion of an opening portion of the film or the like over the substrate 2811.

For example, in the chamber 2706b or the chamber 2706c, oxygen radical treatment using the high-density plasma 2810 can be performed by introducing oxygen from the gas supply source 2801.

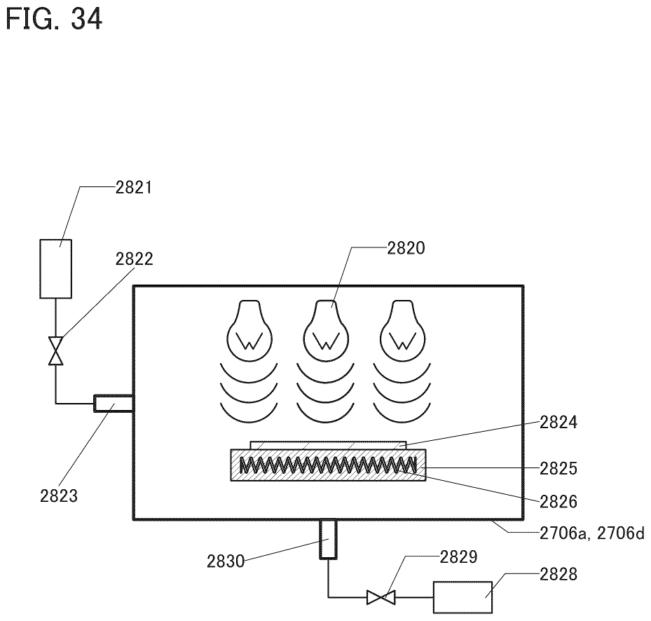

Next, the chamber 2706a and the chamber 2706d are described with reference to a schematic cross-sectional view illustrated in FIG. 34.

The chamber 2706a and the chamber 2706d are chambers in which an object can be irradiated with an electromagnetic wave, for example. Note that the chamber 2706a is different from the chamber 2706d only in the kind of the electromagnetic wave. The other structures have many common portions and thus are collectively described below.

The chamber 2706a and the chamber 2706d each include one or more lamps 2820, a substrate holder 2825, a gas inlet 2823, and an exhaust port 2830. Furthermore, a gas supply source 2821, a valve 2822, a vacuum pump 2828, and a valve 2829 are provided outside the chamber 2706a and the chamber 2706d, for example.

The gas supply source 2821 is connected to the gas inlet 2823 through the valve 2822. The vacuum pump 2828 is connected to the exhaust port 2830 through the valve 2829. The lamp 2820 is placed to face the substrate holder 2825. The substrate holder 2825 has a function of holding a substrate 2824. Furthermore, the substrate holder 2825 includes a heating mechanism 2826 therein and has a function of heating the substrate 2824.

As the lamp 2820, a light source having a function of emitting an electromagnetic wave such as visible light or ultraviolet light may be used, for example. For example, a light source having a function of emitting an electromagnetic wave which has a peak at a wavelength longer than or equal to 10 nm and shorter than or equal to 2500 nm, longer than or equal to 500 nm and shorter than or equal to 2000 nm, or longer than or equal to 40 nm and shorter than or equal to 340 nm may be used.

As the lamp 2820, a light source such as a halogen lamp, a metal halide lamp, a xenon arc lamp, a carbon arc lamp, a high-pressure sodium lamp, or a high-pressure mercury lamp can used, for example.

For example, part or the whole of electromagnetic wave emitted from the lamp 2820 is absorbed by the substrate 2824, so that the quality of a film or the like over the substrate 2824 can be modified. For example, generation or reduction of defects or removal of impurities can be performed. Note that generation or reduction of defects, removal of impurities, or the like can be efficiently performed while the substrate 2824 is heated.

Alternatively, for example, the electromagnetic wave emitted from the lamp 2820 may allow the substrate holder 2825 to generate heat for heating the substrate 2824. In that case, the substrate holder 2825 does not need to include the heating mechanism 2826 therein.

For the vacuum pump 2828, refer to the description of the vacuum pump 2817.

Furthermore, for the heating mechanism 2826, refer to the description of the heating mechanism 2813. Furthermore, for the gas supply source 2821, refer to the description of the gas supply source 2801.

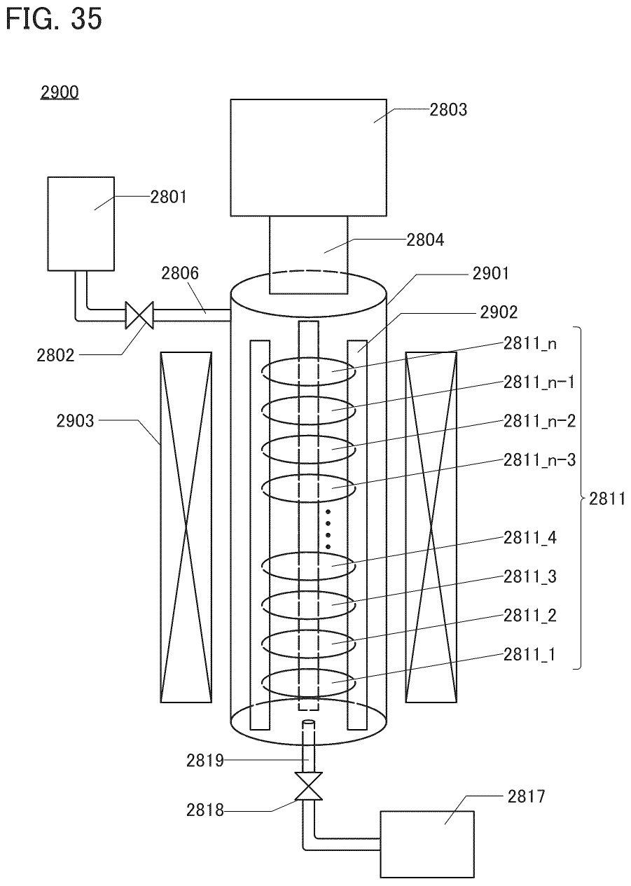

A microwave treatment apparatus that can be used in this embodiment is not limited to the above. A microwave treatment apparatus 2900 illustrated in FIG. 35 can be used. The microwave treatment apparatus 2900 includes a quartz tube 2901, the exhaust port 2819, the gas supply source 2801, the valve 2802, the high-frequency generator 2803, the waveguide 2804, the gas pipe 2806, the vacuum pump 2817, and the valve 2818. Furthermore, the microwave treatment apparatus 2900 includes a substrate holder 2902 that holds a plurality of substrates 2811 (2811_1 to 2811_n, n is an integer greater than or equal to 2) in the quartz tube 2901. The microwave treatment apparatus 2900 may further include a heating means 2903 outside the quartz tube 2901.

The substrate provided in the quartz tube 2901 is irradiated with the microwave generated by the high-frequency generator 2803, through the waveguide 2804. The vacuum pump 2817 is connected to the exhaust port 2819 through the valve 2818 and can adjust the pressure inside the quartz tube 2901. The gas supply source 2801 is connected to the gas pipe 2806 through the valve 2802 and can introduce a desired gas into the quartz tube 2901. The heating means 2903 can heat the substrates 2811 in the quartz tube 2901 to a desired temperature. Alternatively, the heating means 2903 may heat the gas which is supplied from the gas supply source 2801. With the use of the microwave treatment apparatus 2900, the substrates 2811 can be subjected to heat treatment and microwave treatment at the same time. Alternatively, the substrates 2811 can be heated and then subjected to microwave treatment. Alternatively, the substrates 2811 can be subjected to microwave treatment and then heat treatment.

All of the substrate 2811_1 to the substrate 2811_n may be substrates to be treated where a semiconductor device or a storage device is to be formed, or some of the substrates may be dummy substrates. For example, the substrate 2811_1 and the substrate 2811_n may be dummy substrates and the substrate 2811_2 to the substrate 2811_n−1 may be substrates to be treated. Alternatively, the substrate 2811_1, the substrate 2811_2, the substrate 2811_n−1, and the substrate 2811_n may be dummy substrates and the substrate 2811_3 to the substrate 2811_n−2 may be substrates to be treated. A dummy substrate is preferably used, in which case a plurality of substrates to be treated can be uniformly treated at the time of microwave treatment or heat treatment and a variation between the substrates to be treated can be reduced. For example, a dummy substrate is preferably placed over the substrate to be treated which is the closest to the high-frequency generator 2803 and the waveguide 2804, in which case the substrate to be treated is inhibited from being directly exposed to a microwave.

With the use of the above-described manufacturing apparatus, the quality of a film or the like can be modified while the entry of impurities into an object is inhibited.

### Modification Example of Semiconductor Device

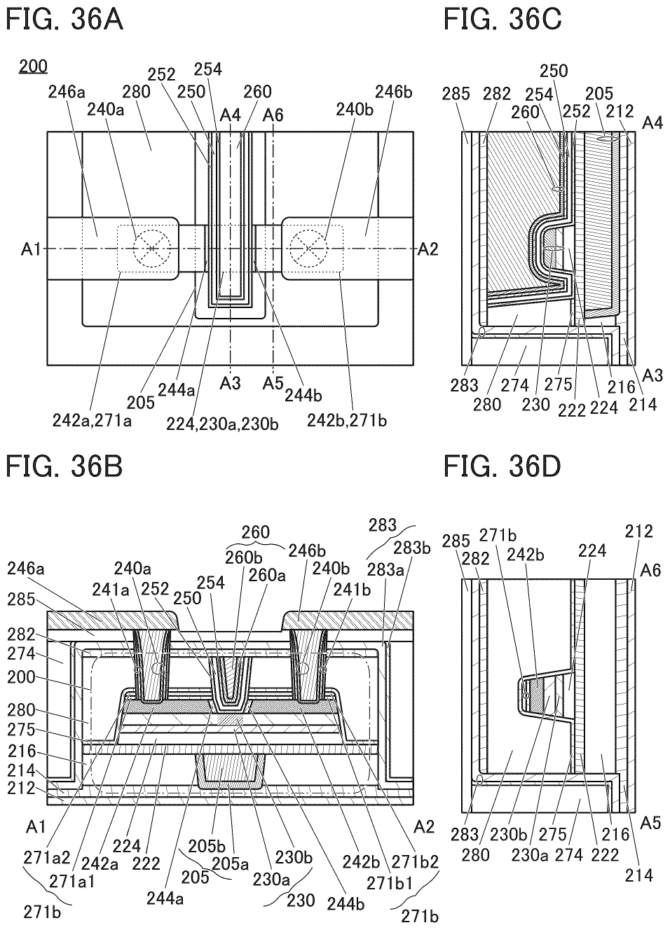

Examples of the semiconductor device of one embodiment of the present invention are described below with reference to FIG. 36A to FIG. 39D.

A of each drawing is a top view of the semiconductor device. Moreover, B of each drawing is a cross-sectional view corresponding to a portion indicated by dashed-dotted line A1-A2 illustrated in A of each drawing. Furthermore, C of each drawing is a cross-sectional view corresponding to a portion indicated by dashed-dotted line A3-A4 in A of each drawing. Furthermore, D of each drawing is a cross-sectional view corresponding to a portion indicated by dashed-dotted line A5-A6 in A of each drawing. Note that for clarity of the drawing, some components are omitted in the top view of A of each drawing.

Note that in the semiconductor device illustrated in A to D of each drawing, components having the same functions as the components included in the semiconductor device described in <Structure example of semiconductor device> are denoted by the same reference numerals. Note that the materials described in detail in <Structure example of semiconductor device> can be used as component materials of the semiconductor devices also in this section.

### Modification Example 1 of Semiconductor Device

A semiconductor device illustrated in FIG. 36A to FIG. 36D is a modification example of the semiconductor device illustrated in FIG. 6A to FIG. 6D. The semiconductor device illustrated in FIG. 36A to FIG. 36D is different from the semiconductor device illustrated in FIG. 6A to FIG. 6D in that the insulator 271 and the insulator 283 each have a stacked-layer structure of two layers.

The insulator 271a includes an insulator 271a1 and an insulator 271a2 over the insulator 271a1. The insulator 271b includes an insulator 271b1 and an insulator 271b2 over the insulator 271b1.

The insulator 271a1 and the insulator 271b1 preferably function as at least a barrier insulating film against oxygen. Thus, the insulator 271a1 and the insulator 271b1 preferably have a function of inhibiting diffusion of oxygen. In this way, oxygen contained in the insulator 280 can be prevented from being diffused into the conductor 242a and the conductor 242b. As a result, the conductor 242a and the conductor 242b can be inhibited from being oxidized by oxygen contained in the insulator 280, so that an increase in resistivity and a reduction in on-state current can be inhibited.

The insulator 271a2 and the insulator 271b2 function as protective layers for making the insulator 271a1 and the insulator 271b1 remain. When a hard mask is removed after the conductive film 242A, the oxide film 230B, and the like are processed into an island shape, an insulating layer to be the insulator 271a1 and the insulator 271b1 might be removed. Thus, an insulating layer to be the insulator 271a2 and the insulator 271b2 is provided between the hard mask and the insulating layer to be the insulator 271a1 and the insulator 271b1, whereby the insulating layer to be the insulator 271a1 and the insulator 271b1 can remain. For example, in the case where tungsten is used for the hard mask, silicon oxide or the like is preferably used for the insulator 271a2 and the insulator 271b2.

The insulator 283 includes an insulator 283a and an insulator 283b over the insulator 283a. The insulator 283a and the insulator 283b are preferably formed using the same material by different methods. For example, silicon nitride may be deposited by a sputtering method as the insulator 283a and silicon nitride may be deposited by an ALD method as the insulator 283b. Since a molecule containing hydrogen is not needed to be used for a deposition gas in the sputtering method, the hydrogen concentration in the insulator 283a can be reduced. Furthermore, in the case where a pinhole, disconnection, or the like is formed in the film deposited by a sputtering method, a portion overlapping with the pinhole, the disconnection, or the like can be filled with the film deposited by an ALD method with excellent coverage.

Note that as illustrated in FIG. 36B, part of the top surface of the insulator 283b is removed in some cases. The boundary between the insulator 283a and the insulator 283b is difficult to clearly detect in some cases.

Without limitation to a stacked-layer structure formed of the same material, the insulator 283a and the insulator 283b may have a stacked-layer structure formed of different materials.

### Modification Example 2 of Semiconductor Device

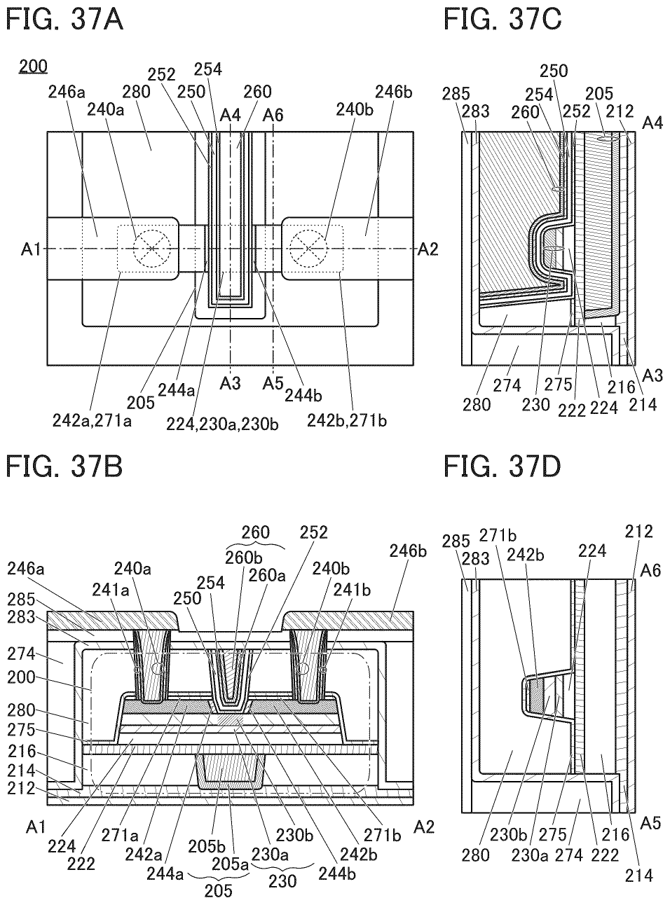

The semiconductor device illustrated in FIG. 37A to FIG. 37D is a modification example of the semiconductor device illustrated in FIG. 6A to FIG. 6D. The semiconductor device illustrated in FIG. 37A to FIG. 37D differs from the semiconductor device illustrated in FIG. 6A to FIG. 6D in that the insulator 282 is not provided. Thus, in the semiconductor device illustrated in FIG. 37A to FIG. 37D, the insulator 283 is in contact with the top surface of the conductor 260, the top surface of the insulator 280, the uppermost portion of the insulator 254, the uppermost portion of the insulator 250, and the uppermost portion of the insulator 252.

For example, in the case where oxygen can be supplied sufficiently to the oxide 230 by the microwave treatment or the like as illustrated in FIG. 26, the region 230bc can be substantially i-type without the insulator 282 for adding oxygen to the insulator 280. In such a case, the structure without the insulator 282 as illustrated in FIG. 37A to FIG. 37D enables simplification of the manufacturing process and the improvement in productivity of the semiconductor device.

### Modification Example 3 of Semiconductor Device

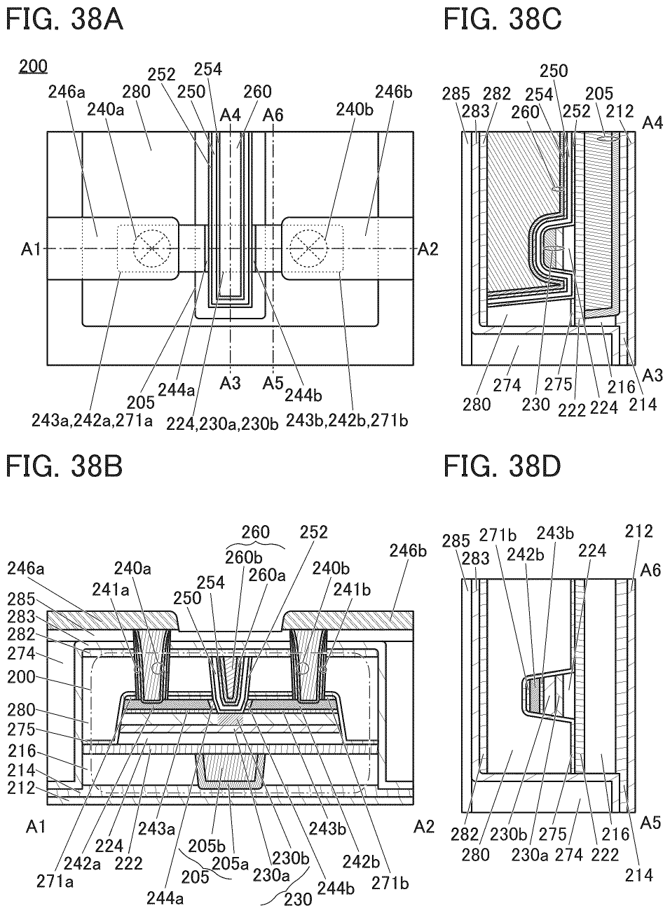

A semiconductor device illustrated in FIG. 38A to FIG. 38D is a modification example of the semiconductor device illustrated in FIG. 6A to FIG. 6D. The semiconductor device illustrated in FIG. 38A to FIG. 38D differs from the semiconductor device illustrated in FIG. 6A to FIG. 6D in that an oxide 243 (an oxide 243a and an oxide 243b) is provided. The oxide 243a is provided between the oxide 230b and the conductor 242a, and the oxide 243b is provided between the oxide 230b and the conductor 242b. The oxide 243a is preferably in contact with the top surface of the oxide 230b and the bottom surface of the conductor 242a. The oxide 243b is preferably in contact with the top surface of the oxide 230b and the bottom surface of the conductor 242b.

The oxide 243 preferably has a function of inhibiting passage of oxygen. The oxide 243 having a function of inhibiting passage of oxygen is preferably placed between the oxide 230b and the conductor 242 functioning as the source electrode or the drain electrode, in which case the electric resistance between the conductor 242 and the oxide 230b is reduced. Such a structure can improve the electrical characteristics, the field-effect mobility, and the reliability of the transistor 200 in some cases.

A metal oxide containing the element M may be used as the oxide 243. In particular, aluminum, gallium, yttrium, or tin is preferably used as the element M. The concentration of the element M in the oxide 243 is preferably higher than that in the oxide 230b. Furthermore, gallium oxide may be used as the oxide 243. A metal oxide such as an In-M-Zn oxide may be used as the oxide 243. Specifically, the atomic ratio of the element M to In in the metal oxide used as the oxide is preferably greater than the atomic ratio of the element M to In in the metal oxide used as the oxide 230b. The thickness of the oxide 243 is preferably greater than or equal to 0.5 nm and less than or equal to 5 nm, further preferably greater than or equal to 1 nm and less than or equal to 3 nm, still further preferably greater than or equal to 1 nm and less than or equal to 2 nm. The oxide 243 preferably has crystallinity. In the case where the oxide 243 has crystallinity, release of oxygen from the oxide 230 can be favorably inhibited. When the oxide 243 has a hexagonal crystal structure, for example, release of oxygen from the oxide 230 can sometimes be inhibited.

### Modification Example 4 of Semiconductor Device

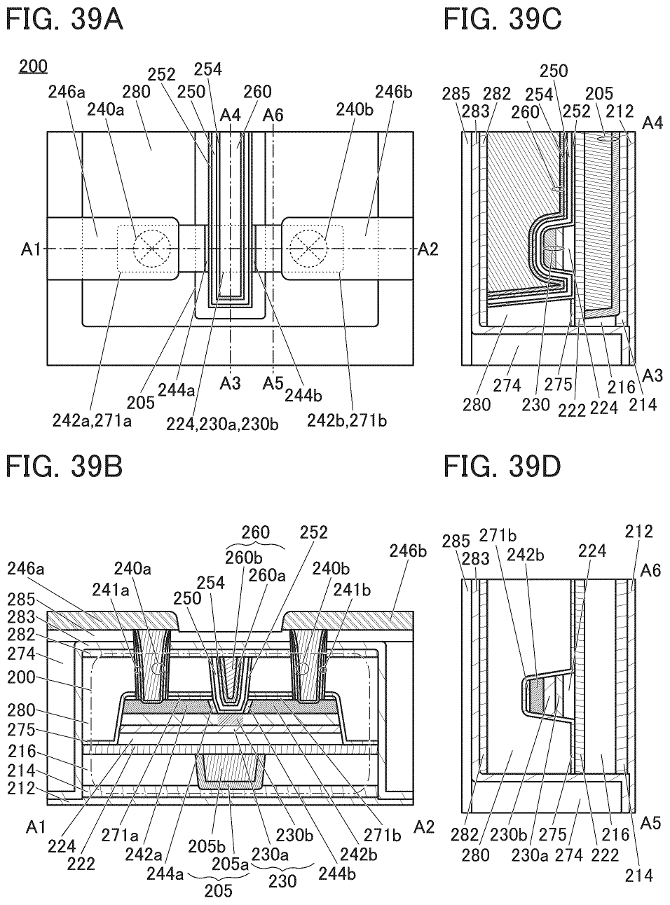

A semiconductor device illustrated in FIG. 39A to FIG. 39D is a modification example of the semiconductor device illustrated in FIG. 6A to FIG. 6D. The semiconductor device illustrated in FIG. 39A to FIG. 39D differs from the semiconductor device illustrated in FIG. 6A to FIG. 6D in that the insulator 283 is in contact with part of the top surface of the insulator 212. Accordingly, the transistor 200 is placed in a region sealed with the insulator 283 and the insulator 212. With the above structure, entry of hydrogen contained in a region outside the sealed region into the sealed region can be inhibited. Although FIG. 39A to FIG. 39D illustrate the transistor 200 having a structure in which the insulator 212 and the insulator 283 are each provided to have a single-layer structure, the present invention is not limited thereto. For example, one or both of the insulator 212 and the insulator 283 may be provided to have a stacked-layer structure of two or more layers.

A change in electrical characteristics of an OS transistor such as the transistor 200 due to exposure to radiation is small, i.e., an OS transistor has high tolerance to radiation; thus, an OS transistor can be suitably used even in an environment where radiation might enter. For example, OS transistors can be suitably used in outer space. Specifically, OS transistors can be used as transistors in semiconductor devices provided in a space shuttle, an artificial satellite, a space probe, and the like. Examples of radiation include X-rays and a neutron beam. Outer space refers to, for example, space at an altitude greater than or equal to 100 km, and outer space in this specification may also include thermosphere, mesosphere, and stratosphere.

Alternatively, for example, OS transistors can be used as transistors included in semiconductor devices provided in working robots in a nuclear power plant and a treatment plant or a disposal plant for radioactive wastes. In particular, OS transistors can be favorably used as transistors included in the semiconductor devices provided in remote control robots that are controlled remotely in demolishment of a reactor facility, taking out of a nuclear fuel or a fuel debris, a field investigation on a space with a large amount of radioactive substance, and the like.

### Application Example of Semiconductor Device

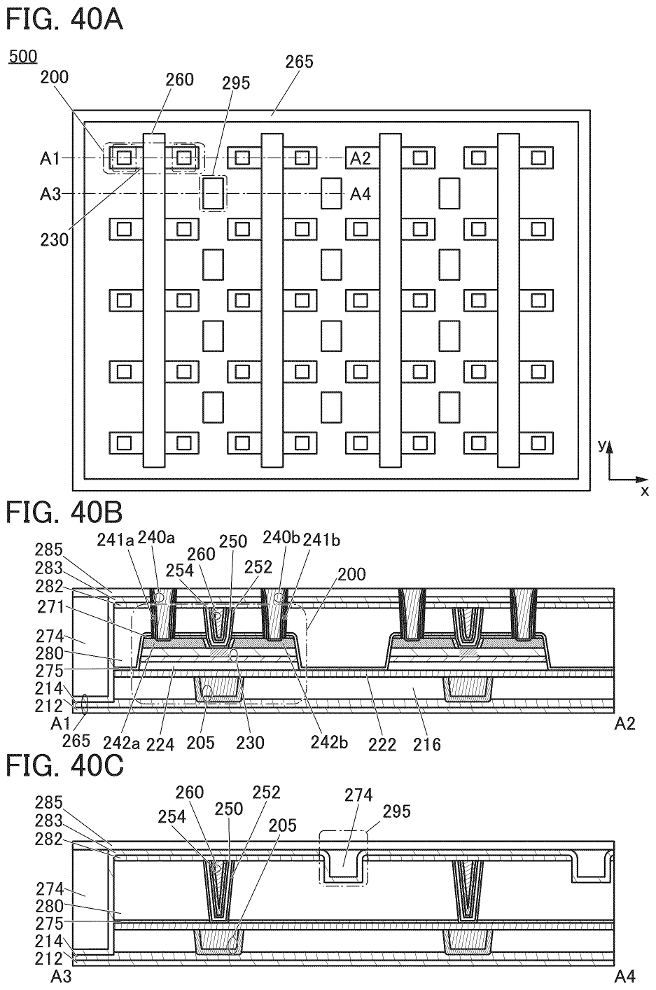

An example of the semiconductor device of one embodiment of the present invention is described below with reference to FIG. 40.

FIG. 40A is a top view of a semiconductor device 500. In FIG. 40A, the x direction is parallel to the channel length direction of the transistor 200, and the y direction is perpendicular to the x direction. FIG. 40B is a cross-sectional view taken along dashed-dotted line A1-A2 in FIG. 40A, which corresponds to a cross-sectional view of the transistor 200 in the channel length direction. FIG. 40C is a cross-sectional view taken along dashed-dotted line A3-A4 in FIG. 40A, which corresponds to a cross-sectional view of an opening region 295 and the vicinity thereof. Note that for clarity of the drawing, some components are not illustrated in the top view in FIG. 40A.

Note that in the semiconductor device illustrated in FIG. 40A to FIG. 40C, components having the same functions as the components included in the semiconductor device described in <Structure example of semiconductor device> are denoted by the same reference numerals. Note that the materials described in detail in <Structure example of semiconductor device> can be used as component materials of the semiconductor devices also in this section.

The semiconductor device 500 illustrated in FIG. 40A to FIG. 40C is a modification example of the semiconductor device illustrated in FIG. 6A to FIG. 6D. The semiconductor device 500 illustrated in FIG. 40A to FIG. 40C differs from the semiconductor device illustrated in FIG. 6A to FIG. 6D in that the opening region 295 is formed in the insulator 282 and the insulator 280. Moreover, a sealing portion 265 is formed to surround a plurality of transistors 200, which is a different point from the semiconductor device illustrated in FIG. 6A to FIG. 6D.

The semiconductor device 500 includes a plurality of transistors 200 and a plurality of opening regions 295 arranged in a matrix. In addition, a plurality of conductors 260 functioning as gate electrodes of the transistors 200 are provided to extend in the y direction. The opening regions 295 are provided in regions not overlapping with the oxide 230 or the conductor 260. The sealing portion 265 is formed so as to surround the plurality of transistors 200, the plurality of conductors 260, and the plurality of opening regions 295. Note that the number, the position, and the size of the transistors 200, the conductors 260, and the opening regions 295 are not limited to those illustrated in FIG. 40 and may be set as appropriate in accordance with the design of the semiconductor device 500.

As illustrated in FIG. 40B and FIG. 40C, the sealing portion 265 is provided to surround the plurality of transistors 200 and the insulator 216, the insulator 222, the insulator 275, the insulator 280, and the insulator 282. In other words, the insulator 283 is provided to cover the insulator 216, the insulator 222, the insulator 275, the insulator 280, and the insulator 282. In the sealing portion 265, the insulator 283 is in contact with the top surface of the insulator 214. Above the sealing portion 265, the insulator 274 is provided between the insulator 283 and the insulator 285. The top surface of the insulator 274 is substantially level with the uppermost surface of the insulator 283. As the insulator 274, an insulator similar to the insulator 280 can be used.

Such a structure enables the plurality of transistors 200 to be surrounded by the insulator 283, the insulator 214, and the insulator 212. One or more of the insulator 283, the insulator 214, and the insulator 212 preferably function as a barrier insulating film against hydrogen. Accordingly, entry of hydrogen contained in the region outside the sealing portion 265 into a region in the sealing portion 265 can be inhibited.

As illustrated in FIG. 40C, the insulator 282 in the opening region 295 has an opening portion. In the opening region 295, the insulator 280 may have a groove to overlap with the opening portion in the insulator 282. The depth of the groove portion of the insulator 280 is less than or equal to the depth at which the top surface of the insulator 275 is exposed and is, for example, approximately greater than or equal to ¼ and less than or equal to ½ of the maximum thickness of the insulator 280.

As illustrated in FIG. 40C, the insulator 283 inside the opening region 295 is in contact with the side surface of the insulator 282, the side surface of the insulator 280, and the top surface of the insulator 280. Part of the insulator 274 is formed in the opening region 295 to fill the depressed portion formed in the insulator 283 in some cases. At this time, the top surface of the insulator 274 formed in the opening region 295 is level with or substantially level with the uppermost surface of the insulator 283, in some cases.

When heat treatment is performed in such a state that the opening region 295 is formed and the insulator 280 is exposed in the opening portion of the insulator 282, part of oxygen contained in the insulator 280 can be diffused outwardly from the opening region 295 while oxygen is supplied to the oxide 230. This enables oxygen to be sufficiently supplied to the region functioning as the channel formation region and its vicinity in the oxide semiconductor layer from the insulator 280 containing oxygen to be released by heating, and also prevents an excess amount of oxygen from being supplied thereto.

At this time, hydrogen contained in the insulator 280 can be bonded to oxygen and released to the outside through the opening region 295. The hydrogen bonded to oxygen is released as water. Thus, the amount of hydrogen contained in the insulator 280 can be reduced, and hydrogen contained in the insulator 280 can be inhibited from entering the oxide 230.

In FIG. 40A, the shape of the opening region 295 in the top view is substantially rectangular; however, the present invention is not limited thereto. For example, the shape of the opening region 295 in the top view can be a rectangular shape, an elliptical shape, a circular shape, a rhombus shape, or a shape obtained by combining any of the above shapes. The area and arrangement interval of the opening regions 295 can be set as appropriate in accordance with the design of the semiconductor device including the transistor 200. For example, in the region where the density of the transistors 200 is low, the area of the opening region 295 may be increased or the arrangement interval of the opening regions 295 may be narrowed. For example, in the region where the density of the transistors 200 is high, the area of the opening region 295 may be decreased, or the arrangement interval of the opening regions 295 may be increased.

According to one embodiment of the present invention, a novel transistor can be provided. A semiconductor device with a small variation in transistor characteristics can be provided. Alternatively, a semiconductor device having favorable electrical characteristics can be provided. Alternatively, a semiconductor device with high reliability can be provided. Alternatively, a semiconductor device with a high on-state current can be provided. Alternatively, a semiconductor device with a high field-effect mobility can be provided. Alternatively, a semiconductor device with favorable frequency characteristics can be provided. Alternatively, a semiconductor device that can be miniaturized or highly integrated can be provided. Alternatively, a semiconductor device with low power consumption can be provided.

At least part of the structure, method, and the like described in this embodiment can be implemented in appropriate combination with any of those in the other embodiments, the other examples, and the like described in this specification.

### Embodiment 3

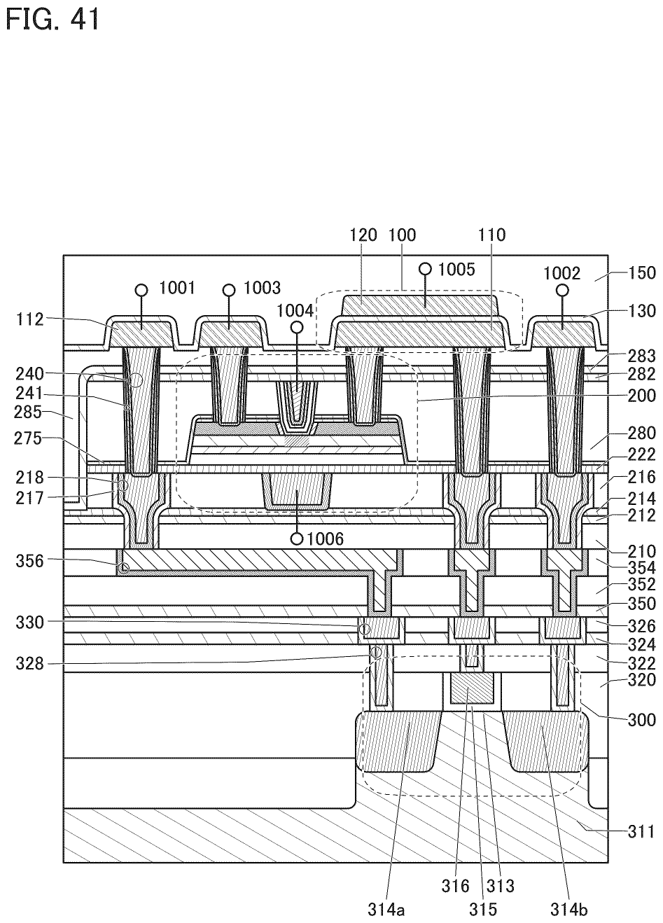

In this embodiment, one embodiment of a semiconductor device is described with reference to FIG. 41 to FIG. 45.

### [Storage Device 1]

FIG. 41 illustrates an example of a semiconductor device (a storage device) of one embodiment of the present invention. In the semiconductor device of one embodiment of the present invention, the transistor 200 is provided above a transistor 300, and a capacitor 100 is provided above the transistor 300 and the transistor 200. The transistor 200 described in the above embodiment can be used as the transistor 200.

The transistor 200 is a transistor in which a channel is formed in a semiconductor layer including an oxide semiconductor. Since the transistor 200 has a low off-state current, a storage device that uses the transistor 200 can retain stored contents for a long time. In other words, such a storage device does not require refresh operation or has extremely low frequency of the refresh operation, which leads to a sufficient reduction in power consumption of the storage device.

In the semiconductor device illustrated in FIG. 41, a wiring 1001 is electrically connected to a source of the transistor 300, and a wiring 1002 is electrically connected to a drain of the transistor 300. In addition, a wiring 1003 is electrically connected to one of the source and the drain of the transistor 200, a wiring 1004 is electrically connected to the first gate of the transistor 200, and a wiring 1006 is electrically connected to the second gate of the transistor 200. A gate of the transistor 300 and the other of the source and the drain of the transistor 200 are electrically connected to one electrode of the capacitor 100, and a wiring 1005 is electrically connected to the other electrode of the capacitor 100.

The storage device illustrated in FIG. 41 can form a memory cell array when arranged in a matrix.

### <Transistor 300>

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 41, the semiconductor region 313 (part of the substrate 311) where a channel is formed has a protruding shape. In addition, the conductor 316 is provided to cover the side surface and the top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 300 illustrated in FIG. 41 is an example and the structure is not limited thereto; an appropriate transistor is used in accordance with a circuit structure or a driving method.

### <Capacitor 100>

The capacitor 100 is provided above the transistor 200. The capacitor 100 includes a conductor 110 functioning as a first electrode, a conductor 120 functioning as a second electrode, and an insulator 130 functioning as a dielectric. Here, for the insulator 130, the insulator that can be used as the insulator 283 described in the above embodiment is preferably used.

For example, a conductor 112 and the conductor 110 provided over the conductor 246 can be formed at the same time. Note that the conductor 112 functions as a plug or a wiring that is electrically connected to the capacitor 100, the transistor 200, or the transistor 300.

Although the conductor 112 and the conductor 110 having a single-layer structure are illustrated in FIG. 41, a stacked-layer structure of two or more layers may be employed without being limited to the single-layer structure. For example, between a conductor having a barrier property and a conductor having high conductivity, a conductor that is highly adhesive to the conductor having a barrier property and the conductor having high conductivity may be formed.

The insulator 130 can be provided as stacked layers or a single layer using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride.

For example, for the insulator 130, a stacked-layer structure of a material with high dielectric strength such as silicon oxynitride and a high permittivity (high-k) material is preferably used. In the capacitor 100 having such a structure, a sufficient capacitance can be ensured owing to the high permittivity (high-k) insulator, and the dielectric strength can be increased owing to the insulator with high dielectric strength, so that the electrostatic breakdown of the capacitor 100 can be inhibited.

Examples of the high permittivity (high-k) material (a material having a high relative permittivity) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with high dielectric strength (a material with a low relative permittivity) include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

### <Wiring Layer>

Wiring layers provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and part of a conductor functions as a plug.

For example, an insulator 320, an insulator 322, an insulator 324, and an insulator 326 are sequentially stacked over the transistor 300 as interlayer films. A conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 function as plugs or wirings.

The insulators functioning as interlayer films may also function as planarization films that cover uneven shapes therebelow. For example, the top surface of the insulator 322 may be planarized by planarization treatment using a chemical mechanical polishing (CMP) method or the like to improve planarity.

A wiring layer may be provided over the insulator 326 and the conductor 330. For example, in FIG. 41, an insulator 350, an insulator 352, and an insulator 354 are stacked sequentially. Furthermore, a conductor 356 is formed in the insulator 350, the insulator 352, and the insulator 354. The conductor 356 functions as a plug or a wiring.

Similarly, a conductor 218, a conductor (the conductor 205) included in the transistor 200, and the like are embedded in an insulator 210, the insulator 212, the insulator 214, and the insulator 216. Note that the conductor 218 has a function of a plug or a wiring that is electrically connected to the capacitor 100 or the transistor 300. In addition, an insulator 150 is provided over the conductor 120 and the insulator 130.

Here, like the insulator 241 described in the above embodiment, an insulator 217 is provided in contact with the side surface of the conductor 218 functioning as a plug. The insulator 217 is provided in contact with an inner wall of an opening formed in the insulator 210, the insulator 212, the insulator 214, and the insulator 216. That is, the insulator 217 is provided between the conductor 218 and each of the insulator 210, the insulator 212, the insulator 214, and the insulator 216. Note that the conductor 205 and the conductor 218 can be formed in parallel; thus, the insulator 217 is sometimes formed in contact with the side surface of the conductor 205.

As the insulator 217, an insulator such as silicon nitride, aluminum oxide, or silicon nitride oxide may be used, for example. Since the insulator 217 is provided in contact with the insulator 210, the insulator 212, the insulator 214, and the insulator 222, entry of impurities such as water and hydrogen into the oxide 230 through the conductor 218 from the insulator 210, the insulator 216, or the like can be inhibited. In particular, silicon nitride is suitable because of its high blocking property against hydrogen. Moreover, oxygen contained in the insulator 210 or the insulator 216 can be prevented from being absorbed by the conductor 218.

The insulator 217 can be formed in a manner similar to that of the insulator 241. For example, silicon nitride is deposited by a PEALD method and an opening reaching the conductor 356 is formed by anisotropic etching.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material with a low relative permittivity is used for the insulator functioning as an interlayer film, parasitic capacitance generated between wirings can be reduced. Thus, a material is preferably selected depending on the function of an insulator.

For example, as the insulator 150, the insulator 210, the insulator 352, the insulator 354, and the like, an insulator with a low relative permittivity is preferably included. For example, the insulator preferably includes silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative permittivity. Examples of the resin include polyester, polyolefin, polyamide (e.g., nylon and aramid), polyimide, polycarbonate, and acrylic.

When a transistor including an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen is used for the insulator 214, the insulator 212, the insulator 350, and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, for the conductor 328, the conductor 330, the conductor 356, the conductor 218, the conductor 112, and the like, a single layer or stacked layers of conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

<Wiring or Plug in Layer Provided with Oxide Semiconductor>

In the case where an oxide semiconductor is used in the transistor 200, an insulator including an excess-oxygen region is provided in the vicinity of the oxide semiconductor in some cases. In that case, an insulator having a barrier property is preferably provided between the insulator including the excess-oxygen region and a conductor provided in the insulator including the excess-oxygen region.

For example, in FIG. 41, the insulator 241 is preferably provided between the insulator 280 containing excess oxygen and the conductor 240. Since the insulator 241 is provided in contact with the insulator 222, the insulator 282, and the insulator 283, the transistor 200 can be sealed with the insulators having a barrier property.

That is, providing the insulator 241 can inhibit excess oxygen contained in the insulator 280 from being absorbed by the conductor 240. In addition, providing the insulator 241 can inhibit diffusion of hydrogen, which is an impurity, into the transistor 200 through the conductor 240.

The insulator 241 is preferably formed using an insulating material having a function of inhibiting diffusion of oxygen and impurities such as water and hydrogen. For example, silicon nitride, silicon nitride oxide, aluminum oxide, hafnium oxide, or the like is preferably used. In particular, silicon nitride is preferable because of its high blocking property against hydrogen. Other than that, a metal oxide such as magnesium oxide, gallium oxide, germanium oxide, yttrium oxide, zirconium oxide, lanthanum oxide, neodymium oxide, or tantalum oxide can be used, for example.

As described in the above embodiment, the transistor 200 may be sealed with the insulator 212, the insulator 214, the insulator 282, and the insulator 283. Such a structure can inhibit entry of hydrogen contained in the insulator 274, the insulator 150, or the like into the insulator 280 or the like.

Here, the conductor 240 penetrates the insulator 283 and the insulator 282, and the conductor 218 penetrates the insulator 214 and the insulator 212; however, as described above, the insulator 241 is provided in contact with the conductor 240, and the insulator 217 is provided in contact with the conductor 218. This can reduce the amount of hydrogen entering the inside of the insulator 212, the insulator 214, the insulator 282, and the insulator 283 through the conductor 240 and the conductor 218. In this manner, the transistor 200 is sealed with the insulator 212, the insulator 214, the insulator 282, the insulator 283, the insulator 241, and the insulator 217, so that impurities such as hydrogen contained in the insulator 274 or the like can be inhibited from entering from the outside.

### <Dicing Line>

A dicing line (sometimes referred to as a scribe line, a dividing line, or a cutting line) which is provided when a large-sized substrate is divided into semiconductor elements so that a plurality of semiconductor devices are each taken as a chip is described below. Examples of a dividing method include the case where a groove (a dicing line) for dividing the semiconductor elements is formed on the substrate first, and then the substrate is cut along the dicing line to divide (split) it into a plurality of semiconductor devices.

Here, for example, as illustrated in FIG. 41, a region where the insulator 283 and the insulator 214 are in contact with each other is preferably designed to overlap with the dicing line. That is, an opening is provided in the insulator 282, the insulator 280, the insulator 275, the insulator 222, and the insulator 216 in the vicinity of a region to be the dicing line that is provided on an outer edge of the memory cell including the plurality of transistors 200.

That is, in the opening provided in the insulator 282, the insulator 280, the insulator 275, the insulator 222, and the insulator 216, the insulator 214 is in contact with the insulator 283.

For example, an opening may be provided in the insulator 282, the insulator 280, the insulator 275, the insulator 222, the insulator 216, and the insulator 214. With such a structure, in the opening provided in the insulator 282, the insulator 280, the insulator 275, the insulator 222, the insulator 216, and the insulator 214, the insulator 212 is in contact with the insulator 283. Here, the insulator 212 and the insulator 283 may be formed using the same material and the same method. When the insulator 212 and the insulator 283 are formed using the same material and the same method, the adhesion therebetween can be increased. For example, silicon nitride is preferably used.

With the structure, the transistors 200 can be surrounded by the insulator 212, the insulator 214, the insulator 282, and the insulator 283. Since at least one of the insulator 212, the insulator 214, the insulator 282, and the insulator 283 has a function of inhibiting diffusion of oxygen, hydrogen, and water, even when the substrate is divided into circuit regions each of which is provided with the semiconductor elements described in this embodiment to be processed into a plurality of chips, entry and diffusion of impurities such as hydrogen and water from the side surface direction of the divided substrate into the transistor 200 can be prevented.

With the structure, excess oxygen in the insulator 280 and the insulator 224 can be prevented from being diffused to the outside. Accordingly, excess oxygen in the insulator 280 and the insulator 224 is efficiently supplied to the oxide where the channel is formed in the transistor 200. The oxygen can reduce oxygen vacancies in the oxide where the channel is formed in the transistor 200. Thus, the oxide where the channel is formed in the transistor 200 can be an oxide semiconductor with a low density of defect states and stable characteristics. That is, the transistor 200 can have a small variation in the electrical characteristics and higher reliability.

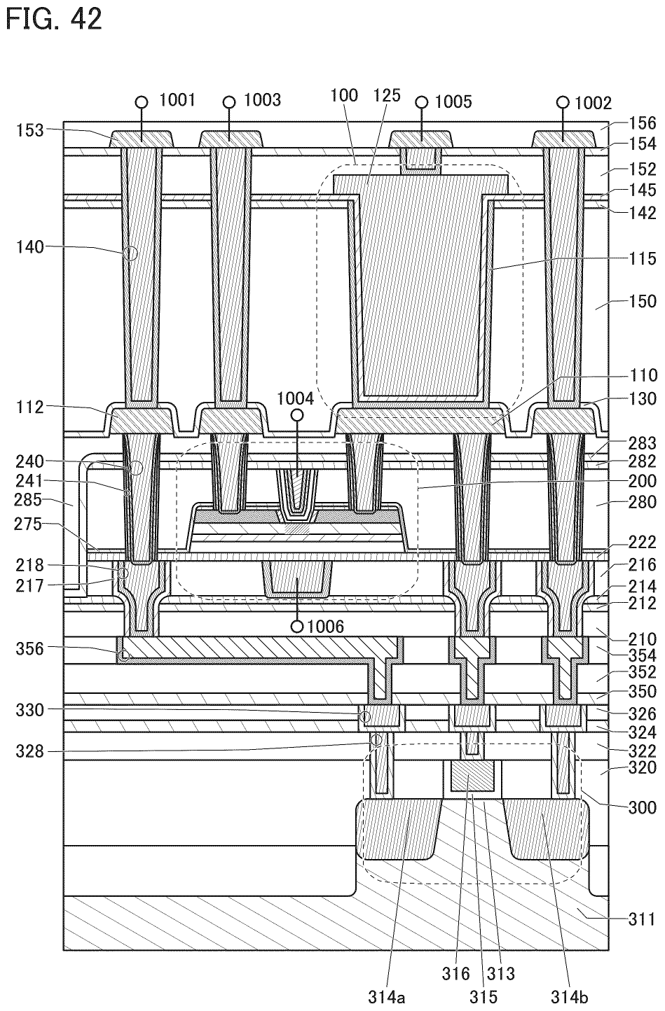

Note that although the capacitor 100 of the storage device illustrated in FIG. 41 has a planar shape, the storage device described in this embodiment is not limited thereto. For example, the capacitor 100 may have a cylindrical shape as illustrated in FIG. 42. Note that the structure below and including the insulator 150 of a storage device illustrated in FIG. 42 is similar to that of the semiconductor device illustrated in FIG. 41.

The capacitor 100 illustrated in FIG. 42 includes the insulator 150 over the insulator 130, an insulator 142 over the insulator 150, a conductor 115 placed in an opening formed in the insulator 150 and the insulator 142, an insulator 145 over the conductor 115 and the insulator 142, a conductor 125 over the insulator 145, and an insulator 152 over the conductor 125 and the insulator 145. Here, at least parts of the conductor 115, the insulator 145, and the conductor 125 are placed in the opening formed in the insulator 150 and the insulator 142.

The conductor 115 functions as a lower electrode of the capacitor 100, the conductor 125 functions as an upper electrode of the capacitor 100, and the insulator 145 functions as a dielectric of the capacitor 100. The capacitor 100 has a structure in which the upper electrode and the lower electrode face each other with the dielectric interposed therebetween on the side surface as well as the bottom surface of the opening in the insulator 150 and the insulator 142; thus, the capacitance per unit area can be increased. Thus, the deeper the opening is, the larger the capacitance of the capacitor 100 can be. Increasing the capacitance per unit area of the capacitor 100 in this manner can promote miniaturization or higher integration of the semiconductor device.

An insulator that can be used as the insulator 280 can be used as the insulator 152. The insulator 142 preferably functions as an etching stopper at the time of forming the opening in the insulator 150 and is formed using an insulator that can be used as the insulator 214.

The shape of the opening formed in the insulator 150 and the insulator 142 when seen from above may be a tetragonal shape, a polygonal shape other than a tetragonal shape, a polygonal shape with rounded corners, or a circular shape including an elliptical shape. Here, the area where the opening and the transistor 200 overlap with each other is preferably large in the top view. Such a structure can reduce the area occupied by the semiconductor device including the capacitor 100 and the transistor 200.

The conductor 115 is placed in contact with the opening formed in the insulator 142 and the insulator 150. The top surface of the conductor 115 is preferably substantially level with the top surface of the insulator 142. Furthermore, the bottom surface of the conductor 115 is in contact with the conductor 110 through an opening in the insulator 130. The conductor 115 is preferably deposited by an ALD method, a CVD method, or the like; for example, a conductor that can be used as the conductor 205 is used.

The insulator 145 is placed to cover the conductor 115 and the insulator 142. The insulator 145 is preferably deposited by an ALD method or a CVD method, for example. The insulator 145 can be provided as stacked layers or a single layer using, for example, silicon oxide, silicon oxynitride, silicon nitride oxide, silicon nitride, zirconium oxide, aluminum oxide, aluminum oxynitride, aluminum nitride oxide, aluminum nitride, hafnium oxide, hafnium oxynitride, hafnium nitride oxide, or hafnium nitride. As the insulator 145, an insulating film in which zirconium oxide, aluminum oxide, and zirconium oxide are stacked in this order can be used, for example.

For the insulator 145, a material with high dielectric strength, such as silicon oxynitride, or a high permittivity (high-k) material is preferably used. Alternatively, a stacked-layer structure of a material with high dielectric strength and a high permittivity (high-k) material may be used.

Examples of the high permittivity (high-k) material (a material having a high relative permittivity) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. The use of such a high-k material can ensure sufficient capacitance of the capacitor 100 even when the insulator 145 has a large thickness. When the insulator 145 has a large thickness, generation of a leakage current between the conductor 115 and the conductor 125 can be inhibited.

Examples of a material with high dielectric strength include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin. For example, it is possible to use an insulating film in which silicon nitride (SiNx) deposited by a PEALD method, silicon oxide (SiOx) deposited by a PEALD method, and silicon nitride (SiNx) deposited by a PEALD method are stacked in this order. Alternatively, an insulating film in which zirconium oxide, silicon oxide deposited by an ALD method, and zirconium oxide are stacked in this order can be used. The use of such an insulator with high dielectric strength can increase the dielectric strength and inhibit electrostatic breakdown of the capacitor 100.

The conductor 125 is placed to fill the opening formed in the insulator 142 and the insulator 150. The conductor 125 is electrically connected to the wiring 1005 through a conductor 140 and a conductor 153. The conductor 125 is preferably deposited by an ALD method, a CVD method, or the like; for example, a conductor that can be used as the conductor 205 is used.

The conductor 153 is provided over an insulator 154 and is covered with an insulator 156. The conductor 153 is formed using a conductor that can be used as the conductor 112, and the insulator 156 is formed using an insulator that can be used as the insulator 152. Here, the conductor 153 is in contact with the top surface of the conductor 140 and functions as a terminal of the capacitor 100, the transistor 200, or the transistor 300.

### [Storage Device 2]

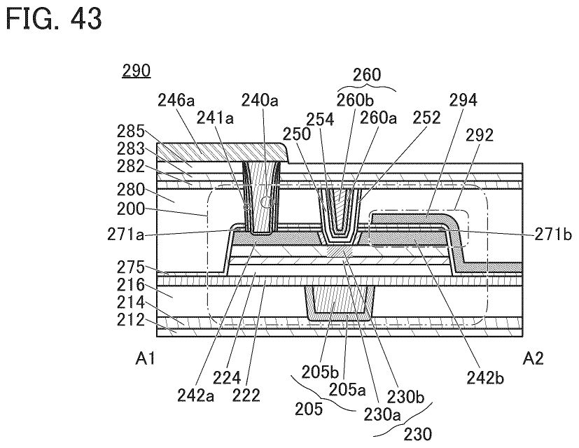

FIG. 43 illustrates an example of a semiconductor device (a storage device) of one embodiment of the present invention.

### Structure Example of Memory Device

FIG. 43 is a cross-sectional view of a semiconductor device including a memory device 290. The memory device 290 illustrated in FIG. 43 includes a capacitor device 292 besides the transistor 200 illustrated in FIG. 6A to FIG. 6D. FIG. 43 corresponds to a cross-sectional view of the transistor 200 in the channel length direction.

The capacitor device 292 includes the conductor 242b; the insulator 271b provided over the conductor 242b; the insulator 275 provided in contact with the top surface of the insulator 271b, the side surface of the insulator 271b, and the side surface of the conductor 242b; and a conductor 294 over the insulator 275. In other words, the capacitor device 292 forms a MIM (Metal-Insulator-Metal) capacitor. Note that one of a pair of electrodes included in the capacitor device 292, i.e., the conductor 242b, can also serve as the source electrode of the transistor 200. The dielectric layer included in the capacitor device 292 can also serve as a protective layer provided in the transistor 200, i.e., the insulator 271 and the insulator 275. Thus, the manufacturing process of the capacitor device 292 can also serve as part of the manufacturing process of the transistor 200, improving the productivity of the semiconductor device. Furthermore, one of a pair of electrodes included in the capacitor device 292, that is, the conductor 242b, also serves as the source electrode or the drain electrode of the transistor 200; therefore, the area in which the transistor and the capacitor device are placed can be reduced.

Note that the conductor 294 is formed using, for example, a material that can be used for the conductor 242.

### Modification Example of Memory Device

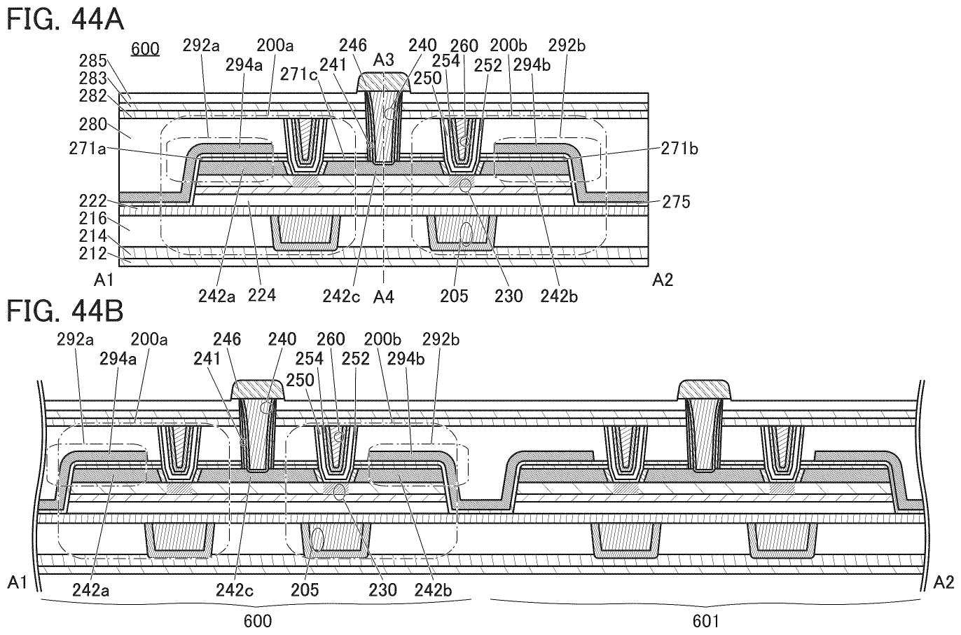

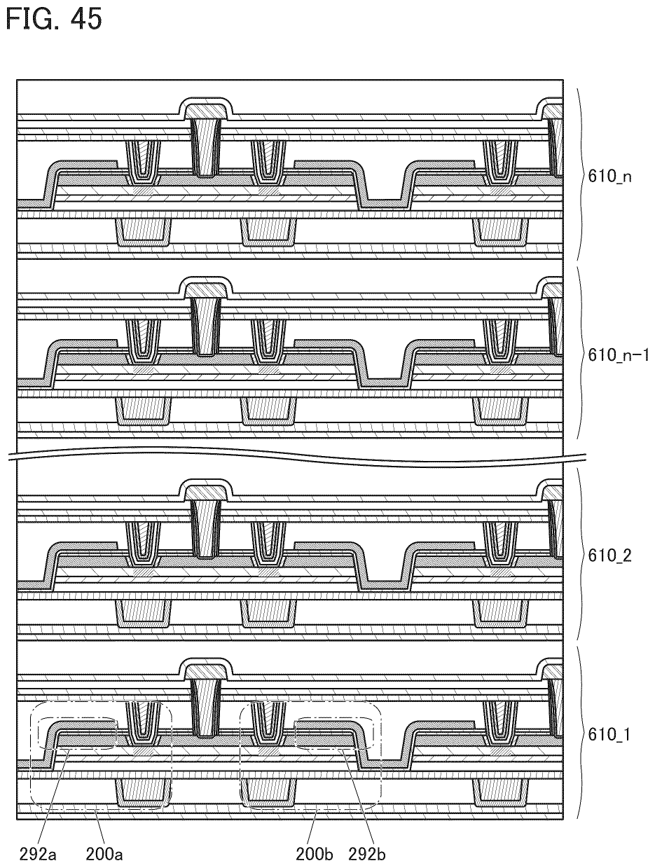

Examples of a semiconductor device of one embodiment of the present invention including the transistor 200 and the capacitor device 292, which are different from the example described above in <Structure example of memory device>, are described below with reference to FIG. 44A, FIG. 44B, and FIG. 45. Note that in the semiconductor devices illustrated in FIG. 44A, FIG. 44B, and FIG. 45, structures having the same function as those included in the semiconductor devices described in the above embodiment and <Structure example of memory device> (see FIG. 43) are denoted by the same reference numerals. Note that the materials described in detail in the above embodiment and <Structure example of memory device> can be used as component materials of the transistor 200 and the capacitor device 292 in this section. The memory devices in FIG. 44A, FIG. 44B, FIG. 45, and the like are, but not limited to, the memory device illustrated in FIG. 43.

### Modification Example 1 of Memory Device

An example of a semiconductor device 600 of one embodiment of the present invention including a transistor 200a, a transistor 200b, a capacitor device 292a, and a capacitor device 292b is described below with reference to FIG. 44A.

FIG. 44A is a cross-sectional view of the semiconductor device 600 including the transistor 200a, the transistor 200b, the capacitor device 292a, and the capacitor device 292b in the channel length direction. Here, the capacitor device 292a includes the conductor 242a; the insulator 271a over the conductor 242a; the insulator 275 in contact with the top surface of the insulator 271a, the side surface of the insulator 271a, and the side surface of the conductor 242a; and a conductor 294a over the insulator 275. The capacitor device 292b includes the conductor 242b; the insulator 271b over the conductor 242b; the insulator 275 in contact with the top surface of the insulator 271b, the side surface of the insulator 271b, and the side surface of the conductor 242b; and a conductor 294b over the insulator 275.

The semiconductor device 600 has a line-symmetric structure with respect to dashed-dotted line A3-A4 as illustrated in FIG. 44A. A conductor 242c serves as one of a source electrode and a drain electrode of the transistor 200a and one of a source electrode and a drain electrode of the transistor 200b. An insulator 271c is provided over the conductor 242c. In addition, the conductor 240 functioning as a plug also connects the conductor 246 functioning as a wiring to the transistor 200a and the transistor 200b. With the above connection structure between the two transistors, the two capacitor devices, the wiring, and the plug, a semiconductor device that can be miniaturized or highly integrated can be provided.

The structure examples of the semiconductor device illustrated in FIG. 44A can be referred to for the structures and the effects of the transistor 200a, the transistor 200b, the capacitor device 292a, and the capacitor device 292b.

### Modification Example 2 of Memory Device

In the above description, the transistor 200a, the transistor 200b, the capacitor device 292a, and the capacitor device 292b are given as examples of components of the semiconductor device; however, the semiconductor device described in this embodiment is not limited thereto. For example, as illustrated in FIG. 44B, a structure may be employed in which the semiconductor device 600 and a semiconductor device having a structure similar to that of the semiconductor device 600 are connected through a capacitor portion. In this specification, the semiconductor device including the transistor 200a, the transistor 200b, the capacitor device 292a, and the capacitor device 292b is referred to as a cell. For the structures of the transistor 200a, the transistor 200b, the capacitor device 292a, and the capacitor device 292b, the above description of the transistor 200a, the transistor 200b, the capacitor device 292a, and the capacitor device 292b can be referred to.

FIG. 44B is a cross-sectional view in which the semiconductor device 600 including the transistor 200a, the transistor 200b, the capacitor device 292a, and the capacitor device 292b, and a cell having a structure similar to that of the semiconductor device 600 are connected through a capacitor portion.

As illustrated in FIG. 44B, the conductor 294b functioning as one electrode of the capacitor device 292b included in the semiconductor device 600 also serves as one electrode of a capacitor device included in a semiconductor device 601 having a structure similar to that of the semiconductor device 600. Although not illustrated, the conductor 294a functioning as one electrode of the capacitor device 292a included in the semiconductor device 600 also serves as one electrode of a capacitor device included in a semiconductor device on the left side of the semiconductor device 600, that is, a semiconductor device adjacent to the semiconductor device 600 in the A1 direction in FIG. 44B. The cell on the right side of the semiconductor device 601, that is, the cell in the A2 direction in FIG. 44B, has a similar structure. That is, a cell array (also referred to as a memory device layer) can be formed. With such a structure of the cell array, space between adjacent cells can be reduced; thus, the projected area of the cell array can be reduced and high integration can be achieved. When matrix arrangement is employed in the cell array illustrated in FIG. 44B, a matrix-shape cell array can be formed.

When the transistor 200a, the transistor 200b, the capacitor device 292a, and the capacitor device 292b are formed to have the structures described in this embodiment as described above, the area of the cell can be reduced and the semiconductor device including a cell array can be miniaturized or highly integrated.

Furthermore, the cell array may have a stacked-layer structure instead of a single-layer structure. FIG. 45 illustrates a cross-sectional view of n layers of cell arrays 610 that are stacked. When a plurality of cell arrays (a cell array 610_1 to a cell array 610_n) are stacked as illustrated in FIG. 45, cells can be integrally placed without increasing the area occupied by the cell arrays. In other words, a 3D cell array can be formed.

At least part of the structure, method, and the like described in this embodiment can be implemented in appropriate combination with any of those in the other embodiments, the other examples, and the like described in this specification.

### Embodiment 4

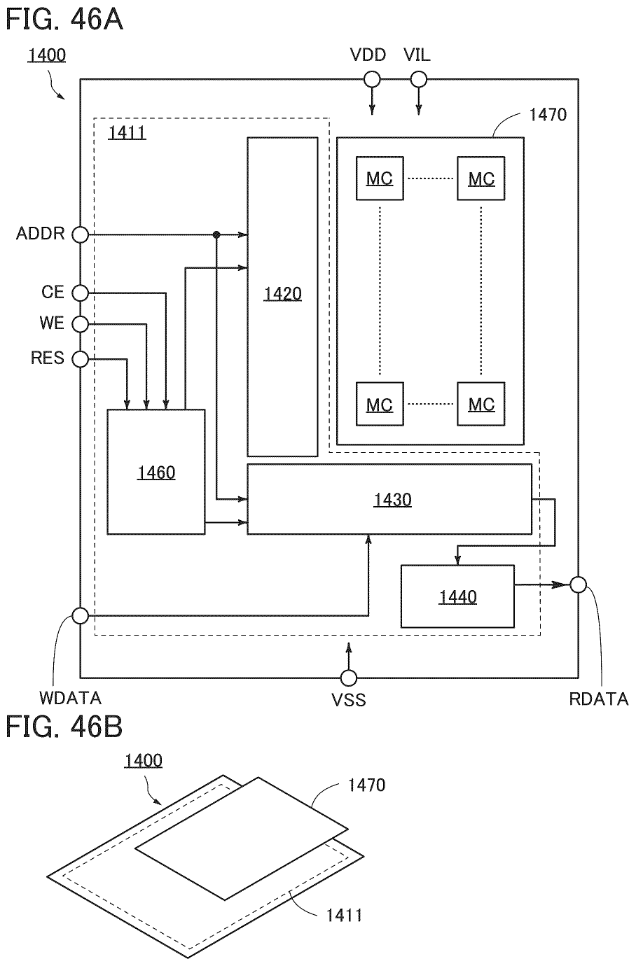

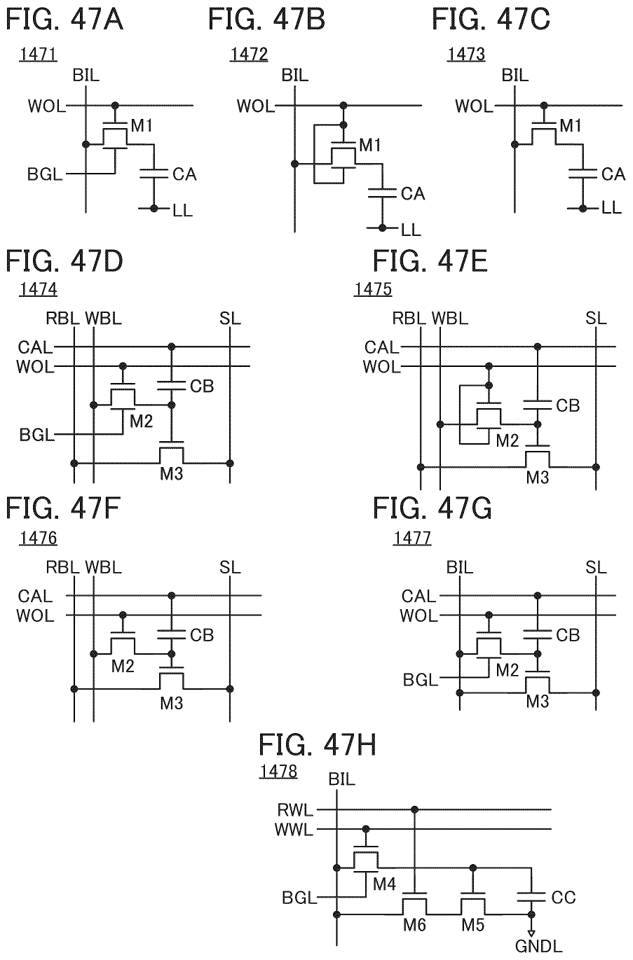

In this embodiment, a storage device including a transistor in which an oxide is used as a semiconductor (hereinafter, sometimes referred to as an OS transistor) and a capacitor (hereinafter, sometimes referred to as an OS memory apparatus) of one embodiment of the present invention is described with reference to FIG. 46A, FIG. 46B, and FIG. 47A to FIG. 47H. The OS memory apparatus is a storage device that includes at least a capacitor and an OS transistor that controls the charging and discharging of the capacitor. Since the OS transistor has an extremely low off-state current, the OS memory apparatus has excellent retention characteristics and thus can function as a nonvolatile memory.

### Structure Example of Storage Device

FIG. 46A illustrates a structure example of the OS memory apparatus. A storage device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the storage device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WE, and RES), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WE, and RES) input from the outside, and generates control signals for the row decoder and the column decoder. The control signal CE is a chip enable signal, the control signal WE is a write enable signal, and the control signal RES is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 46A illustrates an example where the peripheral circuit 1411 and the memory cell array 1470 are formed on the same plane; however, this embodiment is not limited to the example. For example, as illustrated in FIG. 46B, the memory cell array 1470 may be provided to overlap with part of the peripheral circuit 1411. For example, the sense amplifier may be provided below the memory cell array 1470 so that they overlap with each other.

FIG. 47A to FIG. 47H illustrate structure examples of a memory cell that can be used as the memory cell MC.

### [DOSRAM]

FIG. 47A to FIG. 47C illustrate circuit structure examples of a memory cell of a DRAM. In this specification and the like, a DRAM using a memory cell including one OS transistor and one capacitor is referred to as a DOSRAM (Dynamic Oxide Semiconductor Random Access Memory) in some cases. A memory cell 1471 illustrated in FIG. 47A includes a transistor M1 and a capacitor CA. Note that the transistor M1 includes a gate (sometimes referred to as a top gate) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. In the time of data writing and data reading, the wiring LL may be at a ground potential or a low-level potential. The wiring BGL functions as a wiring for applying a potential to the back gate of the transistor M1. When a given potential is applied to the wiring BGL, the threshold voltage of the transistor M1 can be increased or decreased.

Here, a memory cell 1471 illustrated in FIG. 47A corresponds to the storage device illustrated in FIG. 43. That is, the transistor M1 and the capacitor CA correspond to the transistor 200 and the capacitor device 292, respectively.

The circuit structure of the memory cell MC is not limited to that of the memory cell 1471 and can be changed. For example, as in a memory cell 1472 illustrated in FIG. 47B, the back gate of the transistor M1 may be connected not to the wiring BGL but to the wiring WOL in the memory cell MC. Alternatively, for example, the transistor M1 may be a single-gate transistor, that is, a transistor without a back gate in the memory cell MC as in a memory cell 1473 illustrated in FIG. 47C.

In the case where the semiconductor device described in any of the above embodiments is used in the memory cell 1471 and the like, the transistor 200 can be used as the transistor M1, and the capacitor 100 can be used as the capacitor CA. When an OS transistor is used as the transistor M1, the off-state current of the transistor M1 can be extremely low. That is, with the use of the transistor M1, written data can be retained for a long time, and thus the frequency of the refresh operation for the memory cell can be decreased. Alternatively, refresh operation for the memory cell can be unnecessary. In addition, since the transistor M1 has an extremely low off-state current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. This reduces bit line capacitance, which can reduce the storage capacitance of the memory cell.

### [NOSRAM]

FIG. 47D to FIG. 47G each illustrate a circuit structure example of a gain-cell memory cell including two transistors and one capacitor. A memory cell 1474 illustrated in FIG. 47D includes a transistor M2, a transistor M3, and a capacitor CB. Note that the transistor M2 includes a top gate (simply referred to as a gate in some cases) and a back gate. In this specification and the like, a storage device including a gain-cell memory cell using an OS transistor as the transistor M2 is referred to as a NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. The gate of the transistor M2 is connected to the wiring WOL. The back gate of the transistor M2 is connected to the wiring BGL. A second terminal of the capacitor CB is connected to a wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing and data reading, a high-level potential is preferably applied to the wiring CAL. In the time of data retaining, a low-level potential is preferably applied to the wiring CAL. The wiring BGL functions as a wiring for applying a potential to the back gate of the transistor M2. When a given potential is applied to the wiring BGL, the threshold voltage of the transistor M2 can be increased or decreased.

Here, the memory cell 1474 illustrated in FIG. 47D corresponds to the storage device illustrated in FIG. 41 and FIG. 42. That is, the transistor M2, the capacitor CB, the transistor M3, the wiring WBL, the wiring WOL, the wiring BGL, the wiring CAL, the wiring RBL, and the wiring SL correspond to the transistor 200, the capacitor 100, the transistor 300, the wiring 1003, the wiring 1004, the wiring 1006, the wiring 1005, the wiring 1002, and the wiring 1001, respectively.

The circuit structure of the memory cell MC is not limited to that of the memory cell 1474 and can be changed as appropriate. For example, as in a memory cell 1475 illustrated in FIG. 47E, the back gate of the transistor M2 may be connected not to the wiring BGL but to the wiring WOL in the memory cell MC. Alternatively, for example, the transistor M2 may be a single-gate transistor, that is, a transistor without a back gate in the memory cell MC as in a memory cell 1476 illustrated in FIG. 47F. For example, the memory cell MC may have a structure in which the wiring WBL and the wiring RBL are combined into one wiring BIL as in a memory cell 1477 illustrated in FIG. 47G.

In the case where the semiconductor device described in any of the above embodiments is used in the memory cell 1474 and the like, the transistor 200 can be used as the transistor M2, the transistor 300 can be used as the transistor M3, and the capacitor 100 can be used as the capacitor CB. When an OS transistor is used as the transistor M2, the off-state current of the transistor M2 can be extremely low. Consequently, with the use of the transistor M2, written data can be retained for a long time, and thus the frequency of the refresh operation for the memory cell can be decreased. Alternatively, refresh operation for the memory cell can be unnecessary. In addition, since the transistor M2 has an extremely low off-state current, multi-level data or analog data can be retained in the memory cell 1474. The same applies to the memory cell 1475 to the memory cell 1477.

Note that the transistor M3 may be a transistor containing silicon in a channel formation region (hereinafter, sometimes referred to as a Si transistor). The Si transistor may be either an n-channel transistor or a p-channel transistor. A Si transistor has higher field-effect mobility than an OS transistor in some cases. Therefore, a Si transistor may be used as the transistor M3 functioning as a reading transistor. Furthermore, the transistor M2 can be stacked over the transistor M3 when a Si transistor is used as the transistor M3, in which case the area occupied by the memory cell can be reduced, leading to high integration of the storage device.

Alternatively, the transistor M3 may be an OS transistor. When an OS transistor is used as each of the transistor M2 and the transistor M3, the circuit of the memory cell array 1470 can be formed using only n-channel transistors.

FIG. 47H illustrates an example of a gain-cell memory cell including three transistors and one capacitor. A memory cell 1478 illustrated in FIG. 47H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor with a back gate, and the back gate is electrically connected to the wiring BGL. Note that the back gate and the gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors. In this case, the circuit of the memory cell array 1470 can be formed using only n-channel transistors.

In the case where the semiconductor device described in any of the above embodiments is used in the memory cell 1478, the transistor 200 can be used as the transistor M4, the transistors 300 can be used as the transistor M5 and the transistor M6, and the capacitor 100 can be used as the capacitor CC. When an OS transistor is used as the transistor M4, the off-state current of the transistor M4 can be extremely low.

Note that the structures of the peripheral circuit 1411, the memory cell array 1470, and the like described in this embodiment are not limited to the above. The arrangement and functions of these circuits and the wirings, circuit components, and the like connected to the circuits can be changed, removed, or added as needed.

The structure, method, and the like described in this embodiment can be used in an appropriate combination with any of other structures, methods, and the like described in this embodiment or any of structures, methods, and the like described in the other embodiments.

### Embodiment 5

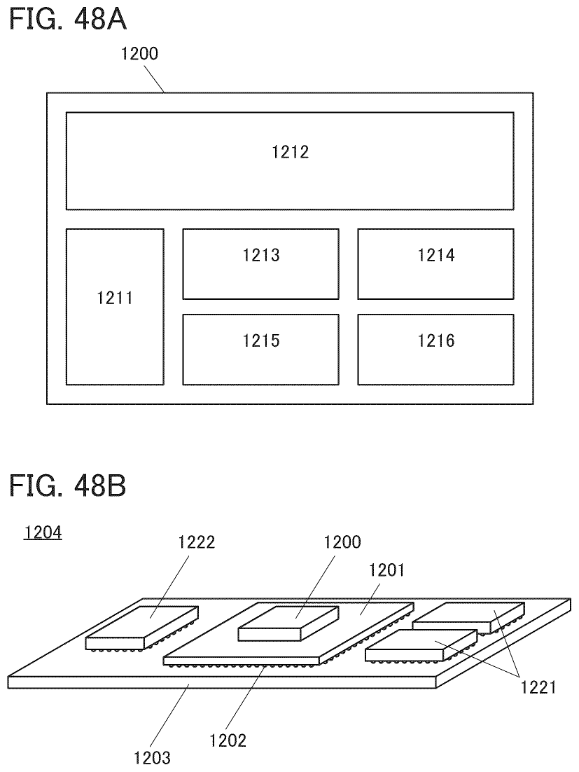

In this embodiment, an example of a chip 1200 on which the semiconductor device of the present invention is mounted is described with reference to FIG. 48A and FIG. 48B. A plurality of circuits (systems) are mounted on the chip 1200. A technique for integrating a plurality of circuits (systems) into one chip is referred to as system on chip (SoC) in some cases.

As illustrated in FIG. 48A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 48B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Storage devices such as DRAMs 1221 and a flash memory 1222 may be provided over the motherboard 1203. For example, the DOSRAM described in the above embodiment can be used as the DRAM 1221. In addition, for example, the NOSRAM described in the above embodiment can be used as the flash memory 1222.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM or the DOSRAM described above can be used as the memory. Moreover, the GPU 1212 is suitable for parallel computation of a number of data and thus can be used for image processing or product-sum operation. When an image processing circuit or a product-sum operation circuit including an oxide semiconductor of the present invention is provided in the GPU 1212, image processing or product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in appropriate combination with any of those in the other embodiments, the other examples, and the like described in this specification.

### Embodiment 6

In this embodiment, examples of electronic components and electronic appliances in which the storage device or the like described in the above embodiment is incorporated are described.

### <Electronic Component>

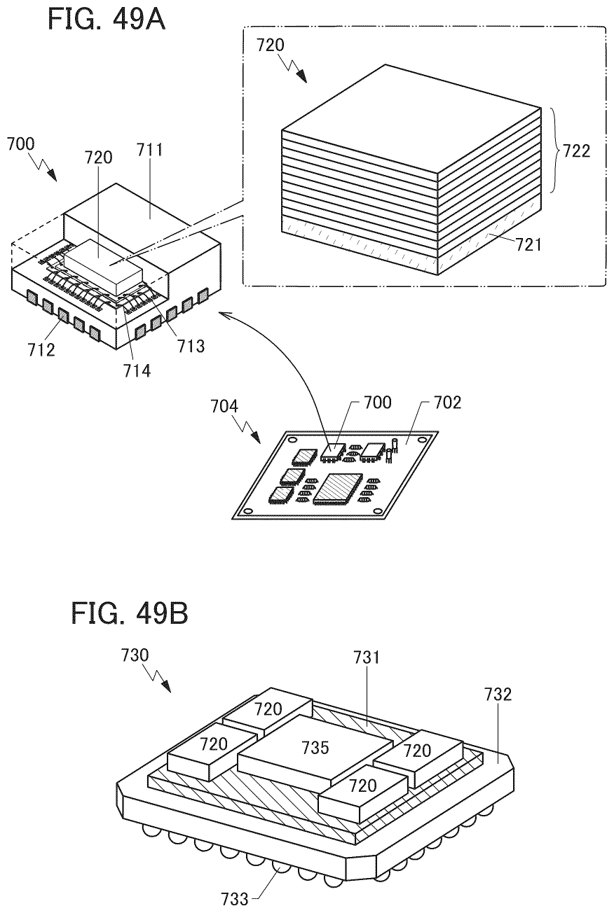

First, examples of an electronic component including a storage device 720 are described with reference to FIG. 49A and FIG. 49B.

FIG. 49A is a perspective view of an electronic component 700 and a substrate (circuit board 704) on which the electronic component 700 is mounted. The electronic component 700 illustrated in FIG. 49A includes the storage device 720 in a mold 711. FIG. 49A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the circuit board 704.

The storage device 720 includes a driver circuit layer 721 and a storage circuit layer 722.

FIG. 49B is a perspective view of an electronic component 730. The electronic component 730 is an example of a SiP (System in package) or an MCM (Multi Chip Module). In the electronic component 730, an interposer 731 is provided over a package substrate 732 (printed circuit board) and a semiconductor device 735 and a plurality of storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Meanwhile, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 720 and the semiconductor device 735 are preferably the same, for example.

An electrode 733 may be provided on the bottom portion of the package substrate 732 to mount the electronic component 730 on another substrate. FIG. 49B illustrates an example where the electrode 733 is formed of a solder ball. Solder balls are provided in a matrix on the bottom portion of the package substrate 732, whereby a BGA (Ball Grid Array) can be achieved. Alternatively, the electrode 733 may be formed of a conductive pin. When conductive pins are provided in a matrix on the bottom portion of the package substrate 732, a PGA (Pin Grid Array) can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of other structures, methods, and the like described in this embodiment or the other embodiments.

### Embodiment 7

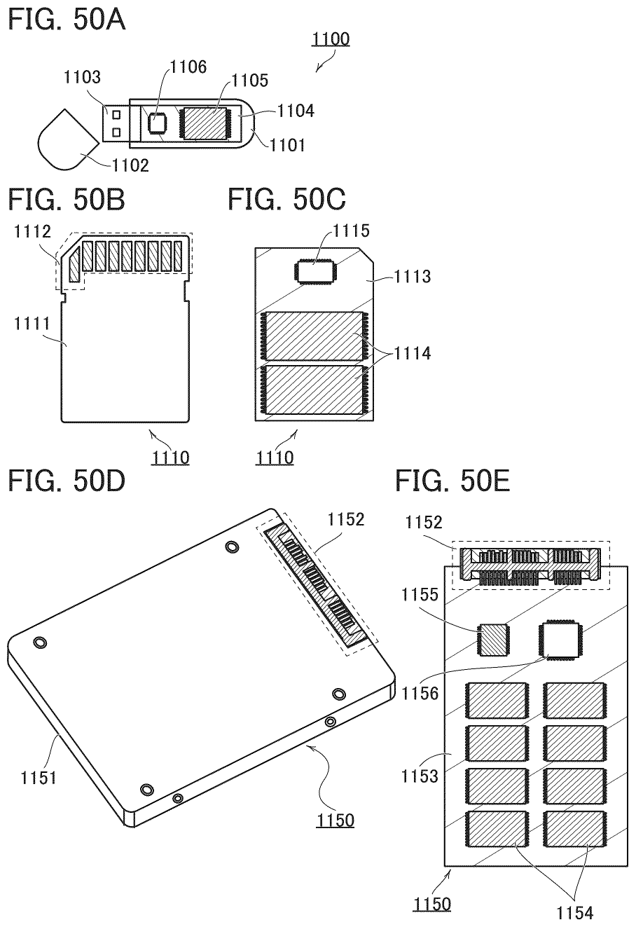

In this embodiment, application examples of the storage device using the semiconductor device described in the above embodiment are described. The semiconductor device described in the above embodiment can be applied to, for example, storage devices of a variety of electronic appliances (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to a variety of removable storage devices such as memory cards (e.g., SD cards), USB memories, and SSDs (solid state drives). FIG. 50A to FIG. 50E schematically illustrate some structure examples of removable storage devices. The semiconductor device described in the above embodiment is processed into a packaged memory chip and used in a variety of storage devices and removable memories, for example.

FIG. 50A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The semiconductor device described in the above embodiment can be incorporated in the memory chip 1105 or the like.

FIG. 50B is a schematic external view of an SD card, and FIG. 50C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The semiconductor device described in the above embodiment can be incorporated in the memory chip 1114 or the like.

FIG. 50D is a schematic external view of an SSD, and FIG. 50E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The semiconductor device described in the above embodiment can be incorporated in the memory chip 1154 or the like.

At least part of the structure, method, and the like described in this embodiment can be implemented in appropriate combination with any of those in the other embodiments, the other examples, and the like described in this specification.

### Embodiment 8

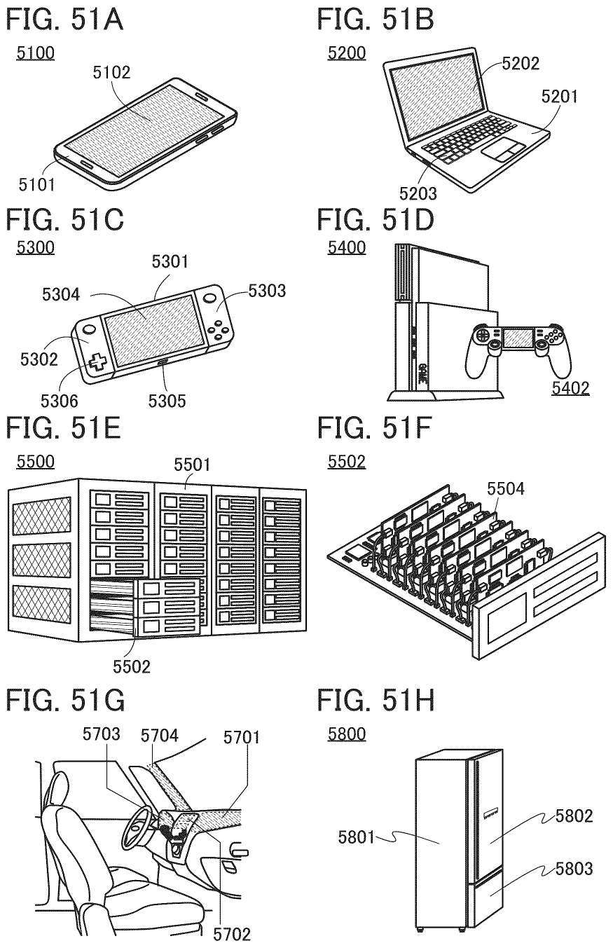

The semiconductor device of one embodiment of the present invention can be used as a processor such as a CPU and a GPU, a storage device, or a chip. FIG. 51A to FIG. 51H illustrate specific examples of electronic appliances including a storage device, a chip, or a processor such as a CPU or a GPU of one embodiment of the present invention.

### <Electronic Appliance and System>

The GPU, the storage device, or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU, the storage device, or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic appliance includes the antenna and a secondary battery, the antenna may be used for contactless power transmission.

The electronic appliance of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic appliance of one embodiment of the present invention can have a variety of functions. For example, the electronic appliance can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 51A to FIG. 51H illustrate examples of electronic appliances.

### [Information Terminal]

FIG. 51A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the contents of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 51B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with the use of the notebook information terminal 5200, novel artificial intelligence can be developed.

Note that although FIG. 51A and FIG. 51B illustrate a smartphone and a notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machines]

FIG. 51C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, a plurality of players can play a game at the same time. The chip described in the above embodiment can be incorporated into the chip provided on a substrate in the housing 5301, the housing 5302 and the housing 5303.

FIG. 51D illustrates a stationary game machine 5400 as an example of a game machine. A controller 5402 is wired or connected wirelessly to the stationary game machine 5400.

Using the GPU, the storage device, or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are illustrated as examples of game machines in FIG. 51C and FIG. 51D, the game machine using the GPU, the storage device, or the chip of one embodiment of the present invention is not limited thereto. Examples of the game machine to which the GPU, the storage device, or the chip of one embodiment of the present invention is applied include an arcade game machine installed in entertainment facilities (a game center, an amusement park, and the like), and a throwing machine for batting practice installed in sports facilities.

### [Large Computer]

The GPU, the storage device, or the chip of one embodiment of the present invention can be used in a large computer.

FIG. 51E is a diagram illustrating a supercomputer 5500 as an example of a large computer. FIG. 51F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip described in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU, the storage device, or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is illustrated as an example of a large computer in FIG. 51E and FIG. 51F, a large computer using the GPU, the storage device, or the chip of one embodiment of the present invention is not limited thereto. Other examples of large computers in which the GPU, the storage device, or the chip of one embodiment of the present invention is usable include a computer that provides service (a server) and a large general-purpose computer (a mainframe).

### [Moving Vehicle]

The GPU, the storage device, or the chip of one embodiment of the present invention can be applied to an automobile, which is a moving vehicle, and the periphery of a driver's seat in the automobile.

FIG. 51G is a diagram illustrating an area around a windshield inside an automobile, which is an example of a moving vehicle. FIG. 51G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an imaging device (not illustrated) provided for the automobile. That is, displaying an image taken by the imaging device provided outside the automobile leads to compensation for the blind spot and an increase in safety. In addition, displaying an image to compensate for a portion that cannot be seen makes it possible for the driver to confirm the safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 51H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described in this embodiment can be implemented in appropriate combination with any of those in the other embodiments, the other examples, and the like described in this specification.

### Embodiment 9

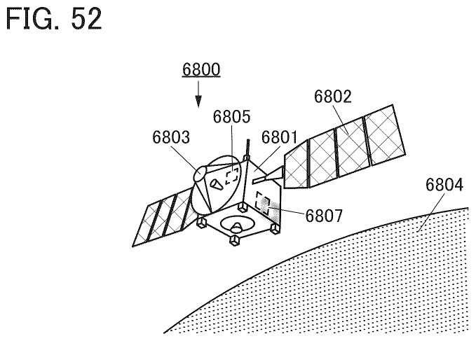

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. In this embodiment, a specific example of using the semiconductor device of one embodiment of the present invention in a device for space will be described with reference to FIG. 52.

FIG. 52 illustrates an artificial satellite 6800 as an example of a device for space. The artificial satellite 6800 includes a body 6801, a solar panel 6802, an antenna 6803, a secondary battery 6805, and a control device 6807. In FIG. 52, a planet 6804 in outer space is illustrated as an example. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-ray's and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

### Example 1

This example describes the influence of providing the insulator 282 on the electrical characteristics of a transistor. Specifically, a sample including a plurality of transistors each provided with the insulator 282 (denoted as Sample 1A) and a sample including a plurality of transistors not provided with the insulator 282 (denoted as Sample 1B) were fabricated, and the electrical characteristics of the transistors were evaluated.

### [Fabrication of Samples]

FIG. 13B can be referred to for a cross-sectional structure of the transistor included in Sample 1A. The transistor included in Sample 1B has a structure in which the insulator 282 is not provided in the transistor illustrated in FIG. 13B. The designed channel length and channel width values of the transistor included in Sample 1A and the transistor included in Sample 1B were 60 nm and 60 nm, respectively. In this example, a designed channel width value refers to a designed apparent channel width value. Thus, a designed channel width value can be rephrased as a designed gate width value.

A fabrication method of Sample 1A and Sample 1B is described below. Embodiment 2 can be referred to for details of the fabrication method. Since Sample 1B has the same structure as Sample 1A except that the insulator 282 is not included, the description except for the insulator 282 is common to Sample 1A and Sample 1B.

As the insulator 212, 60-nm-thick silicon nitride was used. The insulator 212 was deposited by a pulsed DC sputtering method using a silicon target.

As the insulator 214, 40-nm-thick aluminum oxide was used. The insulator 214 was deposited by a pulsed DC sputtering method using an aluminum target.

As the insulator 216, 130-nm-thick silicon oxide was used. The insulator 216 was deposited by a pulsed DC sputtering method using a silicon target.

The insulator 212, the insulator 214, and the insulator 216 were successively deposited without exposure to the air using a multi-chamber sputtering apparatus.

The conductor 205a was formed using a titanium nitride film deposited by a metal CVD method. The conductor 205b was formed using a tungsten film deposited by a metal CVD method.

As the insulator 222, 20-nm-thick hafnium oxide deposited by an ALD method was used.

As the insulator 224, 20-nm-thick silicon oxide deposited by a sputtering method was used.

As the oxide 230a, a 10-nm-thick In—Ga—Zn oxide deposited by a DC sputtering method was used. In the deposition of the oxide 230a, an oxide target with In:Ga:Zn=1:3:4 [atomic ratio] was used.

As the oxide 230b, a 15-nm-thick In—Ga—Zn oxide deposited by a DC sputtering method was used. In the deposition of the oxide 230b, an oxide target with In:Ga:Zn=1:1:1 [atomic ratio] was used.

The conductor 242a and the conductor 242b were formed using a 20-nm-thick tantalum nitride film deposited by a sputtering method. Note that a conductive film to be the conductor 242a and the conductor 242b was deposited using a metal tantalum target under an atmosphere containing nitrogen.

The insulator 271a and the insulator 271b were formed using a 5-nm-thick aluminum oxide film.

As the insulator 275, a stack of 5-nm-thick aluminum oxide deposited by a sputtering method and 5-nm-thick silicon nitride deposited over the aluminum oxide by an ALD method was used.

As the insulator 280, silicon oxide deposited by a sputtering method was used.

The insulator 252 was formed using a 1-nm-thick aluminum oxide film deposited by an ALD method. The insulator 250 was formed using a stacked-layer film of a 5-nm-thick silicon oxide film deposited by a CVD method and a 1.5-nm-thick hafnium oxide film deposited over the silicon oxide film by an ALD method. The insulator 254 was formed using a 1-nm-thick silicon nitride film deposited by an ALD method.

The conductor 260a was formed using a 5-nm-thick titanium nitride film deposited by a metal CVD method. The conductor 260b was formed using a tungsten film deposited by a metal CVD method.

As the insulator 282a and the insulator 282b of Sample 1A, aluminum oxide was used. The insulator 282a and the insulator 282b were deposited by a pulsed DC sputtering method using an aluminum target in an atmosphere containing an oxygen gas. In addition, the insulator 282a was deposited with the RF power applied to the substrate of 1.86 W/cm², and the insulator 282b was deposited with the RF power applied to the substrate of 0.62 W/cm². Meanwhile, Sample 1B was not provided with the insulator 282 as described above.

By the above method, Sample 1A and Sample 1B each including transistors were fabricated.

### [Electrical Characteristics Evaluation]

The electrical characteristics of the transistors included in the fabricated sample were evaluated. Here, the Id-Vg characteristics were measured as the electrical characteristics. The Id-Vg characteristics were measured under the conditions where the drain voltage Vd was 0.1 V or 1.2 V; the source voltage Vs and the back gate voltage Vbg were 0 V; and the top gate voltage Vg was swept from −4 V to +4 V in increments of 0.1 V. The measurement was performed in an environment at room temperature.

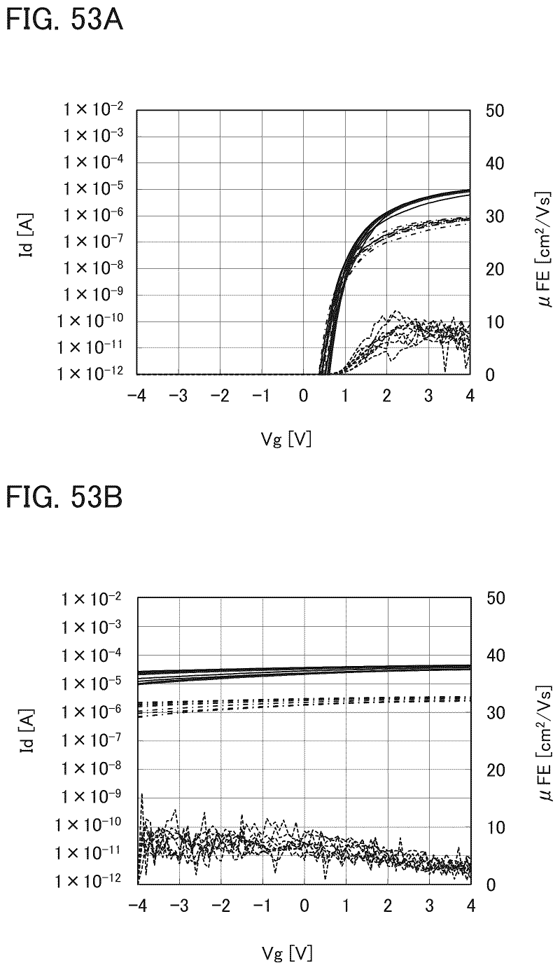

FIG. 53A and FIG. 53B each show the Id-Vg characteristics of the transistors included in the fabricated sample. FIG. 53A shows the Id-Vg characteristics of nine transistors included in Sample 1A, and FIG. 53B shows the Id-Vg characteristics of nine transistors included in Sample 1B. In FIG. 53A and FIG. 53B, the first vertical axis (left vertical axis) represents a drain current Id [A], the second vertical axis (right vertical axis) represents field-effect mobility μFE [cm²/Vs], and the horizontal axis represents a top gate voltage Vg [V]. In FIG. 53A and FIG. 53B, Id in the case where the drain voltage Vd is 1.2 V is denoted by a solid line, Id in the case where the drain voltage Vd is 0.1 V is denoted by a dashed-dotted line, and the field-effect mobility is denoted by a dashed line. The field-effect mobility was calculated from the value measured at the drain voltage Vd set to 1.2 V.

It was found from FIG. 53A that the transistors included in Sample 1A exhibited excellent switching characteristics. Meanwhile, it was found from FIG. 53B that the transistors included in Sample 1B did not exhibit switching characteristics and were always on. Thus, it was confirmed that the transistor exhibiting favorable electrical characteristics was able to be fabricated by providing the insulator 282.

The composition, structure, method, and the like described in this example can be used in combination as appropriate with the compositions, structures, methods, and the like described in the other embodiments and the like.

### Example 2

In this example, samples each including a plurality of transistors illustrated in FIG. 36A to FIG. 36D were fabricated, and the structure of the transistors and the electrical characteristics of the transistors were evaluated.

### [Miniaturization of Transistor]

In this section, miniaturization of a transistor is described. Specifically, samples including transistors each having different gate lengths were fabricated, and the structures of the transistors and the electrical characteristics of the transistors were evaluated.

Here, two samples (Sample 2A and Sample 2B) were fabricated. FIG. 36A to FIG. 36D can be referred to for cross-sectional structures of transistors included in Sample 2A and Sample 2B. The designed channel length and channel width values of the transistor included in Sample 2A were 20 nm and 20 nm, respectively. Sample 2B includes three kinds of transistors with different designed values (a transistor 900A to a transistor 900C). Specifically, the designed channel length value of the transistor 900A was 30 nm, the designed channel length value of the transistor 900B was 25 nm, and the designed channel length value of the transistor 900C was 20 nm. Note that the designed channel width value of each of the transistor 900A to the transistor 900C was 20 nm. In this example, a designed channel width value refers to a designed apparent channel width value. Thus, a designed channel width value can be rephrased as a designed gate width value.

A fabrication method of Sample 2A and Sample 2B is described below. Embodiment 2 can be referred to for details of the fabrication method. Since Sample 2B has the same structure as Sample 2A except for an oxide used as the oxide 230a, the description except for the oxide 230a is common to Sample 2A and Sample 2B.

As the insulator 212, 60-nm-thick silicon nitride was used. The insulator 212 was deposited by a pulsed DC sputtering method using a silicon target.

As the insulator 214, 40-nm-thick aluminum oxide was used. The insulator 214 was deposited by a pulsed DC sputtering method using an aluminum target.

As the insulator 216, 130-nm-thick silicon oxide was used. The insulator 216 was deposited by a pulsed DC sputtering method using a silicon target.

The insulator 212, the insulator 214, and the insulator 216 were successively deposited without exposure to the air using a multi-chamber sputtering apparatus.

The conductor 205a was formed using a titanium nitride film deposited by a metal CVD method. The conductor 205b was formed using a tungsten film deposited by a metal CVD method.

As the insulator 222, 20-nm-thick hafnium oxide deposited by an ALD method was used. As the insulator 224, 20-nm-thick silicon oxide deposited by a sputtering method was used.

As the oxide 230a, a 10-nm-thick In—Ga—Zn oxide deposited by a sputtering method was used. In the deposition of the oxide 230a of Sample 2A, an oxide target with In:Ga:Zn=1:3:4 [atomic ratio] was used. In the deposition of the oxide 230a of Sample 2B, an oxide target with In:Ga:Zn=1:3:2 [atomic ratio] was used.

As the oxide 230b, a 15-nm-thick In—Ga—Zn oxide deposited by a sputtering method was used. In the deposition of the oxide 230b, an oxide target with In:Ga:Zn=1:1:1.2 [atomic ratio] was used.

The conductor 242a and the conductor 242b were formed using a 20-nm-thick tantalum nitride film deposited by a sputtering method. Note that a conductive film to be the conductor 242a and the conductor 242b was deposited using a metal tantalum target under an atmosphere containing nitrogen.

The insulator 271a1 and the insulator 271b1 were formed using a 5-nm-thick silicon nitride film. The insulator 271a2 and the insulator 271b2 were formed using a silicon oxide film. Note that the silicon nitride film and the silicon oxide film were successively deposited without exposure to the air using a multi-chamber sputtering apparatus.

As the insulator 275, 5-nm-thick silicon nitride deposited by an ALD method was used.

As the insulator 280, silicon oxide deposited by a sputtering method was used.

The insulator 252 was formed using a 1-nm-thick aluminum oxide film deposited by an ALD method. The insulator 250 was formed using a 3-nm-thick silicon oxide film deposited by an ALD method. The insulator 254 was formed using a 3-nm-thick silicon nitride film deposited by an ALD method.

The conductor 260a was formed using a 5-nm-thick titanium nitride film deposited by a metal CVD method. The conductor 260b was formed using a tungsten film deposited by a metal CVD method.

As the insulator 282, aluminum oxide was used. The insulator 282 was deposited by a pulsed DC sputtering method using an aluminum target.

By the above method, Sample 2A and Sample 2B each including transistors were fabricated.

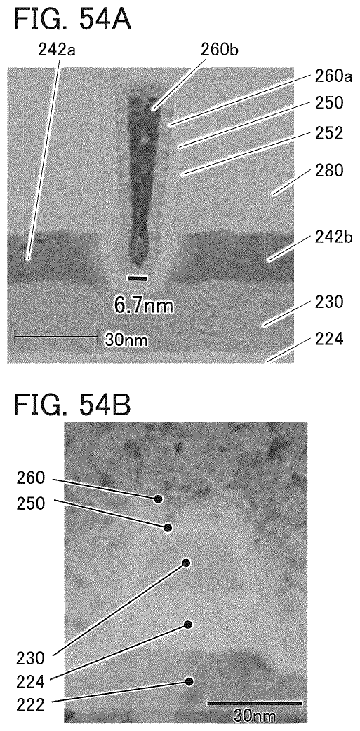

Next, a cross-sectional STEM image of fabricated Sample 2A was taken with “HD-2700” produced by Hitachi High-Technologies Corporation. FIG. 54A shows the cross-sectional STEM image of fabricated Sample 2A in the channel length direction and FIG. 54B shows the cross-sectional STEM image of the fabricated Sample 2A in the channel width direction. Note that in FIG. 54A and FIG. 54B, some components (e.g., the insulator 271 and the insulator 275) are not denoted by reference numerals.

Note that in FIG. 54A and FIG. 54B, the length of each component was measured on the basis of the observation results of the cross-sectional STEM images. As the result of the measurement using FIG. 54A, the gate length of the transistor included in Sample 2A (the width Lg illustrated in FIG. 9A) was 6.7 nm. As the result of the measurement using FIG. 54B, the length of the interface between the oxide 230a and the oxide 230b in the channel width direction (corresponding to the gate width) in Sample 2A was 29.3 nm.

Table 1 shows the gate length and the gate width of the transistor included in Sample 2A. Note that an oxide semiconductor having a CAAC structure is used as the oxide 230b in Sample 2A; thus, the transistor included in Sample 2A can be referred to as a CAAC-OS FET.

As comparative examples, Table 1 also shows the sizes of Si transistors included in a commercial processor. Comparative example 1 shown in Table 1 is a field-effect Si transistor (also referred to as a Si FET) with a 5-nm process node, and Comparative example 2 shown in Table 1 is a field-effect Si transistor with a 7-nm process node.

TABLE 1

| | CAAC-OS | Si FET | |
|---|---|---|---|
| | FET | Comparative | Comparative |
| | Sample 2A | example 1 | example 2 |
| Process node | | 5-nm node | 7-nm node |
| Gate length [nm] | 6.7 | 15 | 19 |
| Gate width [nm] | 29.3 | 115 | 105 |

As shown in Table 1, the transistor fabricated as a prototype in this example was miniaturized to have a gate length and a gate width equivalent to or less than or equal to those of the Si FETs.

For example, in a Si transistor, a semiconductor process node (e.g., a 5-nm node) and the channel length of an actual product do not correspond to each other in many cases. For example, when a transistor is formed with a 5-nm semiconductor process node, the channel length is greater than or equal to 14 nm and less than or equal to 16 nm, a line (L) is greater than or equal to 5 nm and less than or equal to 7 nm, and a space(S) is greater than or equal to 30 nm and less than or equal to 35 nm, in some cases. Note that the line (L) and the space(S) represent the minimum line width of the transistor and the minimum pitch width of the transistor, respectively. Accordingly, the numerical value of the semiconductor process node is a mere indicator which indicates the degree of miniaturization.

Next, the electrical characteristics of the transistors included in fabricated Sample 2B were evaluated. Here, the Id-Vg characteristics were measured as the electrical characteristics. The Id-Vg characteristics were measured under the conditions where the drain voltage Vd was 0.1 V or 1.2 V; the source voltage Vs and the back gate voltage Vbg were 0 V; and the top gate voltage Vg was swept from −4 V to +4 V in increments of 0.1 V. The measurement was performed in an environment at room temperature.

From the measured Id-Vg characteristics, Vth of each of 36 transistors 900A, 36 transistors 900B, and 36 transistors 900C was calculated, and variations in Vth among the transistors 900A, among the transistors 900B, and among the transistors 900C were evaluated.

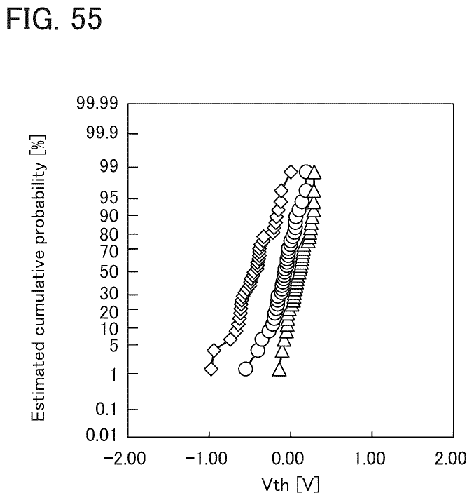

FIG. 55 shows a normal probability plot diagram of Vth. In FIG. 55, the vertical axis represents estimated cumulative probability (%) and the horizontal axis represents Vth [V]. Note that examples of methods for calculating estimated cumulative probability include a median ranking method, an average ranking method, a symmetric sample cumulative distribution method, and a Kaplan-Meier method, and an appropriate method is selected. In this example, the estimated cumulative probability was calculated using a median ranking method.

A triangle plot in FIG. 55 is a normal probability plot of Vth of the transistor 900A, a circle plot in FIG. 55 is a normal probability plot of Vth of the transistor 900B, and a rhombic plot in FIG. 55 is a normal probability plot of Vth of the transistor 900C.

Table 2 shows the gate length (width Lg illustrated in FIG. 9A), the median value of Vth, the standard deviation of Vth, and the like of each of the transistor 900A to the transistor 900C. Note that an oxide semiconductor having a CAAC structure is used as the oxide 230b in Sample 2B; thus, the transistors included in Sample 2B (the transistor 900A, the transistor 900B, and the transistor 900C) can each be referred to as an OS FET or a CAAC-OS FET.

TABLE 2

| | OS FET | | | | | |
|---|---|---|---|---|---|---|
| Transistor | 900A | | 900B | | 900C | |
| Gate length (designed value) | 30 | nm | 25 | nm | 20 | nm |
| Gate length | 18.6 | nm | 11.7 | nm | 7.4 | nm |
| Number of evaluated FETs | 36 | | 36 | | 36 | |
| Median value of Vth | 0.11 | V | −0.07 | V | −0.43 | V |
| Standard deviation of Vth | 121 | mV | 156 | mV | 220 | mV |

According to FIG. 55 and Table 2, in the transistor 900A, the gate length was 18.6 nm, the median value of Vth was 0.11 V, and the standard deviation of Vth was 121 mV. In the transistor 900B, the gate length was 11.7 nm, the median value of Vth was −0.07 V, and the standard deviation of Vth was 156 mV. In the transistor 900C, the gate length was 7.4 nm, the median value of Vth was −0.43 V, and the standard deviation of Vth was 220 mV. Thus, it was found that favorable switching characteristics were obtained from all of the transistor 900A to the transistor 900C.

As described above, it was confirmed that the transistors included in the samples fabricated in this example are miniaturized and exhibit favorable electrical characteristics.

### [High Integration of Transistors]

In this section, high integration of transistors is described. Specifically, samples different from each other in a transistor density were fabricated, and the electrical characteristics of the transistors and the structures of the transistors were evaluated.

Here, two samples (Sample 3A and Sample 3B) were fabricated. A 46.3-Tr/μm² rule was applied to the transistor density (integration density of transistors per unit volume) in Sample 3A, and a 127-Tr/μm² rule was applied to the transistor density in Sample 3B. The designed channel length and channel width values of the transistor included in Sample 3A were 60 nm and 60 nm, respectively, and the designed channel length and channel width values of the transistor included in Sample 3B were 30 nm and 30 nm, respectively. FIG. 36A to FIG. 36D can be referred to for cross-sectional structures of the transistors included in Sample 3A and Sample 3B.

The transistor included in Sample 3A has the same structure as the transistor included in Sample 2A described above. Therefore, the description of Sample 2A can be referred to for the method for fabricating Sample 3A.

The transistor included in Sample 3B is different from the transistor included in Sample 2B in the structure of the insulator 222. Therefore, the description of Sample 2B except for the insulator 222 can be referred to for the method for fabricating Sample 3B.

As the insulator 222 of Sample 3B, a stack of 3-nm-thick silicon nitride deposited by an ALD method and 17-nm-thick hafnium oxide deposited over the silicon nitride by an ALD method was used.

In the above manner, Sample 3A and Sample 3B each including transistors were fabricated. The estimated gate length value and estimated gate width value of the transistor included in fabricated Sample 3A were 46 nm and 80 nm, respectively. The estimated gate length value and estimated gate width value of the transistor included in fabricated Sample 3B were 16 nm and 50 nm, respectively.

Then, the electrical characteristics of the transistors included in the fabricated sample were evaluated. Here, the Id-Vg characteristics were measured as the electrical characteristics. The Id-Vg characteristics were measured under the conditions where the drain voltage Vd was 0.1 V or 1.2 V; the source voltage Vs and the back gate voltage Vbg were 0 V; and the top gate voltage Vg was swept from −4 V to +4 V in increments of 0.1 V. The measurement was performed in an environment at room temperature.

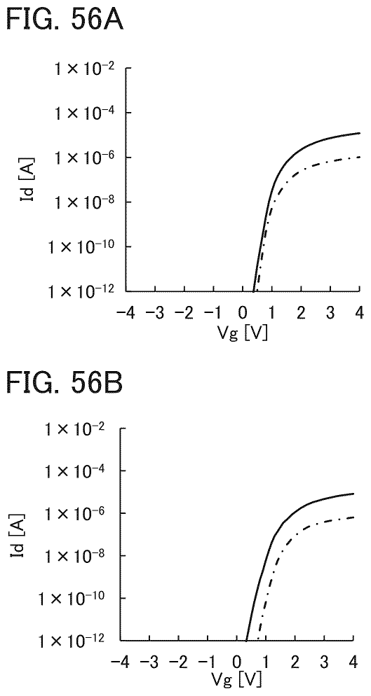

FIG. 56A and FIG. 56B each show the Id-Vg characteristics of the transistor included in the fabricated sample. FIG. 56A shows the Id-Vg characteristics of the transistor included in Sample 3A, and FIG. 56B shows the Id-Vg characteristics of the transistor included in Sample 3B. In FIG. 56A and FIG. 56B, the vertical axis represents a drain current Id [A] and the horizontal axis represents a top gate voltage Vg [V]. In FIG. 56A and FIG. 56B, Id in the case where the drain voltage Vd is 1.2 V is denoted by a solid line and Id in the case where the drain voltage Vd is 0.1 V is denoted by a dashed-dotted line.

It was found from FIG. 56A and FIG. 56B that favorable switching characteristics are obtained from the transistor included in Sample 3A and the transistor included in Sample 3B.

Next, plan-view observation was performed on the fabricated samples. Note that the plan-view observation was performed on the thin-sliced samples with a scanning transmission electron microscope (STEM). As an apparatus for the observation, HD-2700 produced by Hitachi High-Technologies Corporation was used.

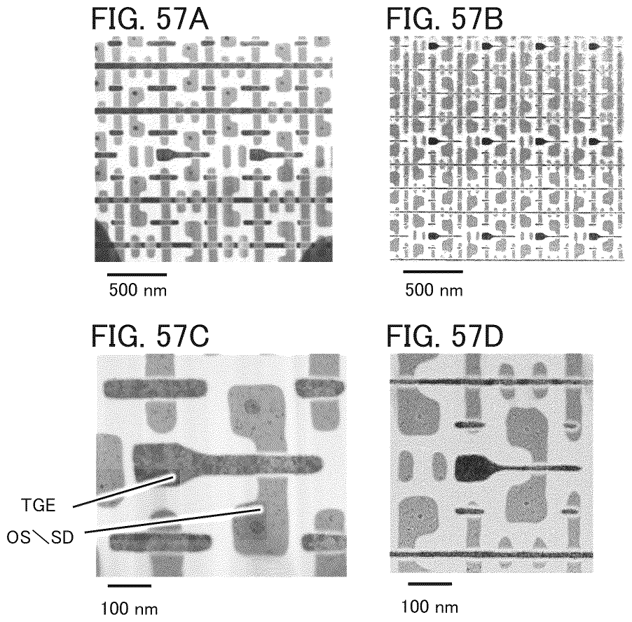

FIG. 57A to FIG. 57D show plan-view STEM images of the fabricated samples. FIG. 57A is a plan-view STEM image in which an overall view of Sample 3A can be observed, and FIG. 57B is a plan-view STEM image in which an overall view of Sample 3B can be observed. FIG. 57C is a plan-view STEM image of the vicinity of a channel formation region of the transistor included in Sample 3A, and FIG. 57D is a plan-view STEM image of the vicinity of a channel formation region of the transistor included in Sample 3B. In FIG. 57C, TGE represents a top gate electrode, which corresponds to the conductor 260 described in Embodiment 2. In FIG. 57C, OS\SD represents a stack of an oxide semiconductor (OS) and a source electrode and a drain electrode (SD), which corresponds to the island-shaped stack of the oxide 230 and the conductor 242a and the conductor 242b described in Embodiment 2.

It was confirmed from FIG. 57C and FIG. 57D that by reducing the contact area, the distance size (pitch) between the conductors 260 functioning as gate electrodes, or the like, the 127-Tr/μm² density rule was satisfied.

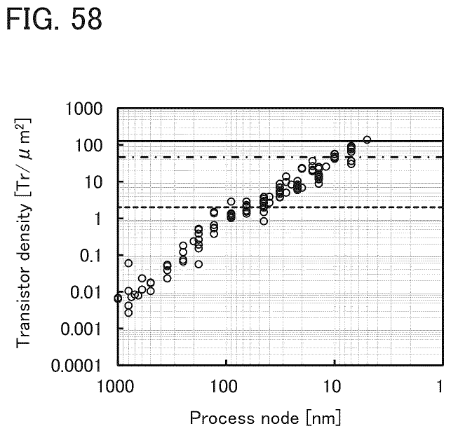

Here, FIG. 58 shows the relationship between the process node and the transistor density of the commercial processor. A graph shown in FIG. 58 is a log-log graph in which the vertical axis represents the transistor density [Tr/μm²] and the horizontal axis represents the process node [nm]. The dotted line shown in FIG. 58 represents a transistor density of 2.0 Tr/μm², the dashed-dotted line shown in FIG. 58 represents a transistor density of 46.3 Tr/μm², and the solid line shown in FIG. 58 represents a transistor density of 127 Tr/μm².

It was found from FIG. 58 that the samples fabricated in this example were able to be miniaturized to an approximately 10-nm node. Note that the process node and the transistor density of Comparative example 1 described above are 5 nm and 138 μm², respectively. The process node and the transistor density of Comparative example 2 described above are 7 nm and 65 Tr/μm², respectively.

The composition, structure, method, and the like described in this example can be used in combination as appropriate with the compositions, structures, methods, and the like described in the other embodiments and the like.

### REFERENCE NUMERALS

10: substrate, 11: region, 12: region, 13: region, 100: capacitor, 110: conductor, 112: conductor, 115: conductor, 120: conductor, 125: conductor, 130: insulator, 140: conductor, 142: insulator, 145: insulator, 150: insulator, 152: insulator, 153: conductor, 154: insulator, 156: insulator, 200a: transistor, 200b: transistor, 200d: dummy element, 200: transistor, 205a: conductor, 205b: conductor, 205: conductor, 210: insulator, 212: insulator, 214: insulator, 216: insulator, 217: insulator, 218: conductor, 222: insulator, 224A: insulating film, 224: insulator, 230a: oxide, 230A: oxide film, 230b: oxide, 230B: oxide film, 230ba: region, 230bb: region, 230bc: region, 230bd: region, 230be: region, 230d: oxide, 230: oxide, 240a: conductor, 240b: conductor, 240: conductor, 241a: insulator, 241b: insulator, 241: insulator, 242a: conductor, 242A: conductive film, 242b: conductor, 242B: conductive layer, 242c: conductor, 242: conductor, 243a: oxide, 243b: oxide, 243: oxide, 244a: insulator, 244b: insulator, 246a: conductor, 246b: conductor, 246: conductor, 250a: insulator, 250A: insulating film, 250b: insulator, 250: insulator, 252A: insulating film, 252: insulator, 254A: insulating film, 254: insulator, 256: insulator, 260a: conductor, 260b: conductor, 260d: conductor, 260: conductor, 265: sealing portion, 271a: insulator, 271A: insulating film, 271b: insulator, 271B: insulating layer, 271c: insulator, 271: insulator, 274: insulator, 275: insulator, 280: insulator, 282a: insulator, 282b: insulator, 282: insulator, 283a: insulator, 283b: insulator, 283: insulator, 285: insulator, 290: memory device, 292a: capacitor device, 292b: capacitor device, 292: capacitor device, 294a: conductor, 294b: conductor, 294: conductor, 295: opening region, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 500: semiconductor device, 600: semiconductor device, 601: semiconductor device, 610_1: cell array, 610_n: cell array, 610: cell array, 700: electronic component, 702: printed circuit board, 704: circuit board, 711: mold, 712: land, 713: electrode pad, 714: wire, 720: storage device, 721: driver circuit layer, 722: storage circuit layer, 730: electronic component, 731: interposer, 732: package substrate, 733: electrode, 735: semiconductor device, 900A: transistor, 900B: transistor, 900C: transistor, 1001: wiring, 1002: wiring, 1003: wiring, 1004: wiring, 1005: wiring, 1006: wiring, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 1400: storage device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1476: memory cell, 1477: memory cell, 1478: memory cell, 2700: manufacturing apparatus, 2701: atmosphere-side substrate supply chamber, 2702: atmosphere-side substrate transfer chamber, 2703a: load lock chamber, 2703b: unload lock chamber, 2704: transfer chamber, 2706a: chamber, 2706b: chamber, 2706c: chamber, 2706d: chamber, 2761: cassette port, 2762: alignment port, 2763a: transfer robot, 2763b: transfer robot, 2801: gas supply source, 2802: valve, 2803: high-frequency generator, 2804: waveguide, 2805: mode converter, 2806: gas pipe, 2807: waveguide, 2808: slot antenna plate, 2809: dielectric plate, 2810: high-density plasma, 2811_1: substrate, 2811_2: substrate, 2811_3: substrate, 2811_n: substrate, 2811: substrate, 2812: substrate holder, 2813: heating mechanism, 2815: matching box, 2816: high-frequency power source, 2817: vacuum pump, 2818: valve, 2819: exhaust port, 2820: lamp, 2821: gas supply source, 2822: valve, 2823: gas inlet, 2824: substrate, 2825: substrate holder, 2826: heating mechanism, 2828: vacuum pump, 2829: valve, 2830: exhaust port, 2900: microwave treatment apparatus, 2901: quartz tube, 2902: substrate holder, 2903: heating means, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door

1. A semiconductor device comprising:
a first transistor comprising a first oxide;
a second transistor comprising a second oxide; and
a third oxide,
wherein the first oxide comprises a channel formation region of the first transistor,
wherein the second oxide comprises a channel formation region of the second transistor,
wherein the third oxide comprises the same material as the first oxide and the second oxide,
wherein the third oxide is separated from the first oxide and the second oxide,
wherein in a top view, the third oxide is positioned between the first oxide and the second oxide,
wherein the third oxide is positioned in the same layer as the first oxide and the second oxide, and
wherein the third oxide is not configured to be a channel formation region of any transistor.

2. The semiconductor device according to claim 1,
wherein a gate electrode of the first transistor comprises a region with a width greater than or equal to 1 nm and less than or equal to 20 nm in a cross-sectional view of the first transistor in a channel length direction, and
wherein a gate electrode of the second transistor comprises a region with a width greater than or equal to 1 nm and less than or equal to 20 nm in a cross-sectional view of the second transistor in a channel length direction.

3. A semiconductor device comprising:
a circuit,
wherein the circuit comprises a transistor and a first region comprising the transistor,
wherein the transistor comprises a first oxide in a channel formation region,
wherein a second oxide is provided in the first region,
wherein the second oxide comprises the same material as the first oxide,
wherein the second oxide is separated from the first oxide,
wherein the first region is shaped into a square in a top view so as to comprise at least the channel formation region of the transistor,
wherein an area of the first region and an area occupied by one transistor converted from a transistor density of the circuit are equal to each other,
wherein the first region overlaps with at least part of the first oxide and the second oxide in the top view, and
wherein the second oxide is not configured to be a channel formation region of any transistor.

4. The semiconductor device according to claim 3,
wherein a gate electrode of the transistor comprises a region with a width greater than or equal to 1 nm and less than or equal to 20 nm in a cross-sectional view of the transistor in a channel length direction.

5. A semiconductor device comprising:
a circuit,
wherein the circuit comprises a transistor and a first region comprising the transistor,
wherein the transistor comprises a first conductor configured to be a gate electrode and an oxide comprising a channel formation region,
wherein a second conductor not overlapping with the oxide is provided in the first region,
wherein the second conductor comprises the same material as the first conductor,
wherein the second conductor is separated from the first conductor,
wherein the first region is shaped into a square in a top view so as to comprise at least the channel formation region of the transistor,
wherein an area of the first region and an area occupied by one transistor converted from a transistor density of the circuit are equal to each other,
wherein the first region overlaps with at least part of the first conductor and the second conductor in the top view, and
wherein the second conductor is not configured to be a gate electrode of any transistor.

6. The semiconductor device according to claim 5,
wherein the first conductor comprises a region with a width greater than or equal to 1 nm and less than or equal to 20 nm in a cross-sectional view of the transistor in a channel length direction.

7. The semiconductor device according to claim 3,
wherein the transistor density of the circuit is higher than or equal to 1 Tr/μm² and lower than or equal to 1000 Tr/μm².

8. The semiconductor device according to claim 6,
wherein the transistor density of the circuit is higher than or equal to 1 Tr/μm² and lower than or equal to 1000 Tr/μm².
